(19) United States
(12) Patent Application Publication
(10) Pub. No.: US 2023/0200097 A1
(43) Pub. Date: Jun. 22, 2023

(54) ORGANIC PHOTODETECTOR AND ELECTRONIC APPARATUS INCLUDING THE SAME

(71) Applicant: Samsung Display Co., Ltd., Yongin-si (KR)

(72) Inventors: Youngeun CHOI, Yongin-si (KR); Dongkyu SEO, Yongin-si (KR); Junyong SHIN, Yongin-si (KR); Seokgyu YOON, Yongin-si (KR); Daeho LEE, Yongin-si (KR); Byungseok LEE, Yongin-si (KR); Jaeyong LEE, Yongin-si (KR); Jinsoo JUNG, Yongin-si (KR); Kunwook CHO, Yongin-si (KR); Minsoo CHOI, Yongin-si (KR)

(73) Assignee: Samsung Display Co., Ltd., Yongin-si (KR)

(21) Appl. No.: 18/082,815

(22) Filed: Dec. 16, 2022

(30) Foreign Application Priority Data
Dec. 17, 2021 (KR) 10-2021-0182202

(51) Int. Cl. H10K 39/34; H10K 30/20; H10K 30/80; H10K 39/00; H10K 50/15; H10K 85/30; H10K 85/60

(52) U.S. Cl. CPC H10K 39/34; H10K 30/20; H10K 30/865; H10K 39/501; H10K 50/15; H10K 85/311; H10K 85/322; H10K 85/371; H10K 85/625; H10K 85/631; H10K 85/6574; H10K 85/6576; H10K 85/6572; H10K 85/615; H10K 85/622; H10K 85/657; H10K 85/626; B82Y 30/00

(57) ABSTRACT

Provided are an organic photodetector and an electronic apparatus including the same. The organic photodetector includes a first electrode, a second electrode facing the first electrode, an auxiliary layer arranged between the first electrode and the second electrode, and an activation layer arranged between the first electrode and the activation layer. The auxiliary layer includes a compound having a refractive index of about 2.2 or more.

### CROSS-REFERENCE TO RELATED APPLICATION(S)

This application claims priority to and benefits of Korean Patent Application No. 10-2021-0182202 under 35 U.S.C. § 119, filed on Dec. 17, 2021, in the Korean Intellectual Property Office (KIPO), the entire contents of which are incorporated herein by reference.

### BACKGROUND

### 1. Technical Field

The disclosure relates to an organic photodetector and an electronic apparatus including the same.

### 2. Description of the Related Art

Photoelectric devices are devices that convert light to an electrical signal and include a photodiode and a phototransistor. Photoelectric devices may be applied to an image sensor, a solar cell, an organic light-emitting device, and the like.

In the case of silicon, which is mainly used in photodiodes, as the size of pixels decreases, an absorption region may decrease, thus deteriorating sensitivity. Accordingly, organic materials that may replace silicon are being studied.

As organic materials have a large extinction coefficient and may selectively absorb light in a specific wavelength region according to the molecular structure thereof, organic materials may replace photodiodes and color filters simultaneously, which may facilitate improvements in sensitivity and high integration.

Organic photodetectors including the organic materials may be employed in, for example, a display apparatus and an image sensor.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Provided are an organic photodetector with improved light detection efficiency, and an electronic apparatus including the same.

Additional aspects will be set forth in part in the description which follows and, in part, will be apparent from the description, or may be learned by practice of the embodiments of the disclosure.

According to embodiments,

provided is an organic photodetector that may include a first electrode,

a second electrode facing the first electrode,

an activation layer arranged between the first electrode and the second electrode, and

an auxiliary layer arranged between the first electrode and the activation layer,

wherein the auxiliary layer may include a compound having a refractive index of about 2.2 or more.

The activation layer may include a p-type semiconductor layer and an n-type semiconductor layer. The p-type semiconductor layer may include a p-type semiconductor, the n-type semiconductor layer may include a n-type semiconductor, and the p-type semiconductor layer and the n-type semiconductor layer may form a PN junction.

The activation layer may include a p-type semiconductor and an n-type semiconductor, and the activation layer may be a mixed layer in which the p-type semiconductor and the n-type semiconductor are mixed.

The p-type semiconductor may include boron subphthalocyanine chloride (SubPc), copper(II) phthalocyanine (CuPc), tetraphenyldibenzoperiflanthene (DBP), or a combination thereof.

The n-type semiconductor may include C60 fullerene, C70 fullerene, or a combination thereof.

A thickness of the activation layer may be in a range of about 20 nm and about 100 nm.

The activation layer may directly contact the auxiliary layer.

A thickness of the auxiliary layer may be in a range of about 1 nm and about 20 nm.

The compound may include an organic material.

The compound may include an amine group-containing compound.

The refractive index may be in a range of about 2.2 and about 3.0.

The organic photodetector may further include a hole transport region between the first electrode and the auxiliary layer; and an electron transport region between the activation layer and the second electrode. The hole transport region may include a hole injection layer, a hole transport layer, an electron blocking layer, or a combination thereof. The electron transport region may include a buffer layer, a hole blocking layer, an electron transport layer, an electron injection layer, or a combination thereof.

The hole transport region may include the hole transport layer.

A thickness of the hole transport layer may be in a range of about 80 nm and about 150 nm.

The hole transport layer may directly contact the auxiliary layer.

Each of the activation layer and the hole transport layer may be directly contact the auxiliary layer.

According to embodiments, provided is an electronic apparatus that may include the organic photodetector.

In an embodiment, the electronic apparatus may further include a light-emitting device.

According to embodiments, provided is an electronic apparatus that may include a substrate including a light detection region and an emission region,

an organic photodetector arranged on the light detection region, and

a light-emitting device arranged on the emission region,

wherein the organic photodetector may include a first pixel electrode, a counter electrode facing the first pixel electrode, and a first common layer, an auxiliary layer, an activation layer, and a second common layer, which may be sequentially arranged between the first pixel electrode and the counter electrode,

the light-emitting device may include a second pixel electrode, the counter electrode facing the second pixel electrode, and the first common layer, an emission layer, and the second common layer, which may be sequentially arranged between the second pixel electrode and the counter electrode,

the first pixel electrode, the auxiliary layer, and the activation layer may be arranged in correspondence with the light detection region,

the second pixel electrode and the emission layer may be arranged in correspondence with the emission region, and

the first common layer, the second common layer, and the counter electrode may be arranged throughout the light detection region and the emission region.

The first common layer may include a hole transport layer.

### BRIEF DESCRIPTION OF THE DRAWINGS

The above and other aspects and features of the disclosure will be more apparent by describing in detail embodiments thereof with reference to the accompanying drawings, in which:

FIGS. 1 and 2 are each a schematic cross-sectional view of an organic photodetector according to an embodiment;

FIGS. 3 and 4 are each a schematic cross-sectional view of an electronic apparatus according to an embodiment; and

FIGS. 5 and 6 are each a view of an example of an electronic apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The expression “(the auxiliary layer) includes a compound having a refractive index of 2.2 or more” used herein may be construed as the meaning that “(the auxiliary layer) may include the compound having a refractive index of 2.2 or more or two or more different compounds having a refractive index of 2.2 or more”.

The term “interlayer” as used herein refers to a single layer and/or all of multiple of layers arranged between a first electrode and a second electrode of a light-emitting device.

According to embodiments, provided is an organic photodetector that may include: a first electrode;

a second electrode facing the first electrode;

an activation layer arranged between the first electrode and the second electrode; and

an auxiliary layer arranged between the first electrode and the activation layer,

wherein the auxiliary layer may include a compound having a refractive index of about 2.2 or more.

In an embodiment, in the organic photodetector, the first electrode may be an anode, and the second electrode may be a cathode.

The activation layer is a layer that may generate excitons by receiving light from the outside and divide the generated excitons to holes and electrons.

In an embodiment, in the organic photodetector, the activation layer may include a p-type semiconductor layer and an n-type semiconductor layer. The p-type semiconductor layer may include a p-type semiconductor and the n-type semiconductor layer may include an n-type semiconductor, and

the p-type semiconductor layer and the n-type semiconductor layer may form a PN junction.

In an embodiment, the activation layer in the organic photodetector may include a p-type semiconductor and an n-type semiconductor, and

the activation layer may be a mixed layer in which the p-type semiconductor and the n-type semiconductor are mixed. The p-type semiconductor and the n-type semiconductor may be co-deposited to form the activation layer.

The p-type semiconductor may be a compound that acts as an electron donor that supplies electrons. In an embodiment, the p-type semiconductor may include boron subphthalocyanine chloride (SubPc), copper(II) phthalocyanine (CuPc), tetraphenyldibenzoperiflanthene (DBP), or any combination thereof, but embodiments are not limited thereto.

The n-type semiconductor may include a compound that acts as an electron acceptor that accepts electrons. In an embodiment, the n-type semiconductor may include C60 fullerene, C70 fullerene, or any combination thereof, but embodiments are not limited thereto.

Since the p-type semiconductor acts as an electron donor, and the n-type semiconductor acts as an electron acceptor, excitons may be efficiently divided into holes and electrons by photo-induced charge separation occurring at an interface between the p-type semiconductor layer and the n-type semiconductor layer. Since the activation layer is divided into the p-type semiconductor layer and the n-type semiconductor layer, capture and migration of holes and electrons generated at the interface may be facilitated.

In an embodiment, a thickness of the activation layer in the organic photodetector may be in a range of about 20 nm and about 100 nm. In an embodiment, a thickness of the activation layer may be in a range of about 20 nm and about 50 nm. In an embodiment, a thickness of the activation layer may be in a range of about 40 nm and about 80 nm.

The photodetector may include an auxiliary layer arranged between the first electrode and the activation layer.

In an embodiment, the activation layer in the organic photodetector may be in contact (e.g., directly contact) with the auxiliary layer.

In an embodiment, a thickness of the auxiliary layer in the organic photodetector may be in a range of about 1 nm and about 20 nm. In an embodiment, a thickness of the auxiliary layer may be in a range of about 1 nm and about 10 nm.

In an embodiment, the auxiliary layer in the organic photodetector may be a single layer and/or multiple layers, but embodiments are not limited thereto.

The auxiliary layer in the photodetector may include a compound having a refractive index of about 2.2 or more.

In an embodiment, the compound in the organic photodetector may include an organic material.

In an embodiment, the compound in the organic photodetector may include an amine group-containing compound.

In an embodiment, the compound may include a triphenylamine group-containing compound.

In an embodiment, the amine group-containing compound may include a compound represented by Formula 201 below, a compound represented by Formula 202 below, or any combination thereof. Formulae 201 and 202 are respectively the same as described in the specification.

In an embodiment, the amine group-containing compound may be at least one of Compounds 1 to 84 below:

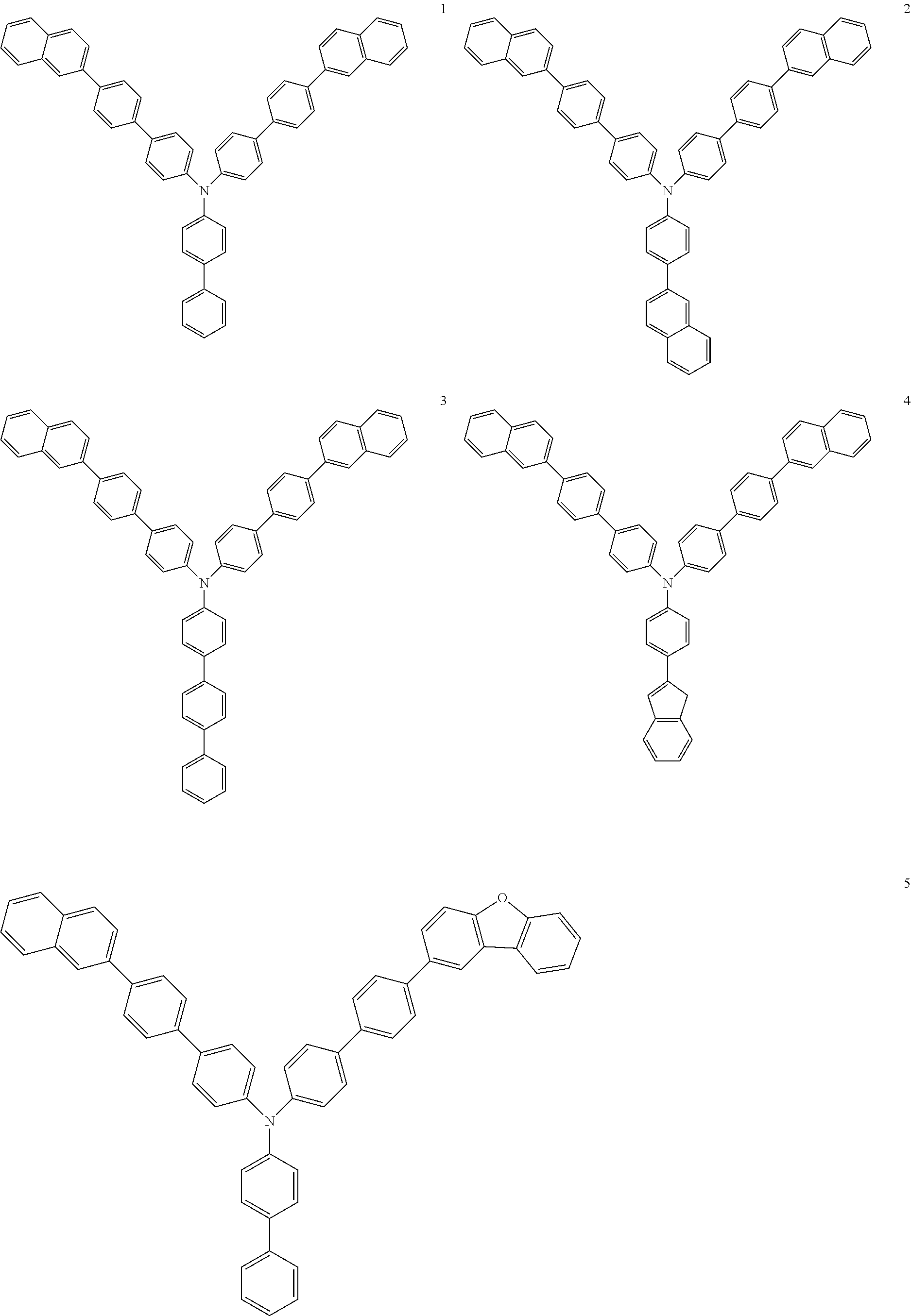

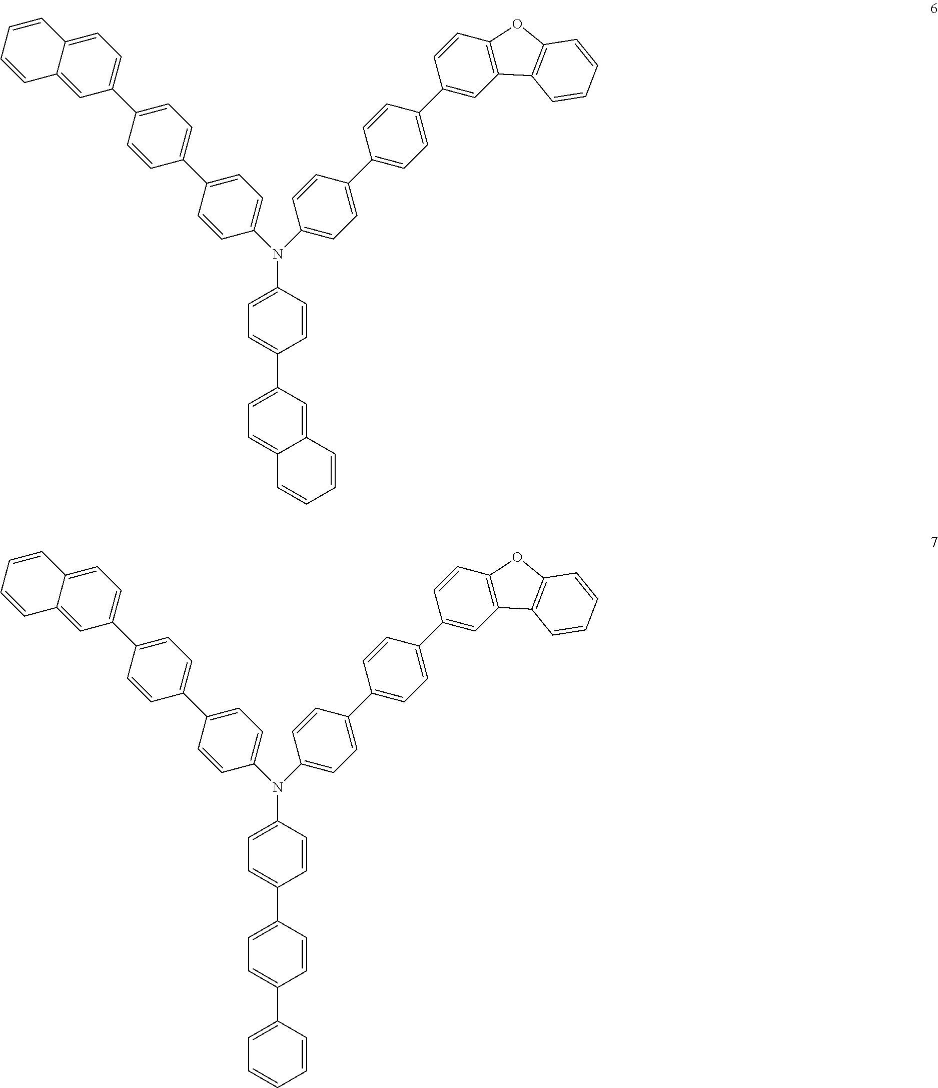 [SMILES: c1ccc2cc(-c3ccc(-c4ccc(N(c5ccc(-c6ccc(-c7ccc8oc9ccccc9c8c7)cc6)cc5)c5ccc(-c6ccc7ccccc7c6)cc5)cc4)cc3)ccc2c1 ; c1ccc(-c2ccc(-c3ccc(N(c4ccc(-c5ccc(-c6ccc7ccccc7c6)cc5)cc4)c4ccc(-c5ccc(-c6ccc7oc8ccccc8c7c6)cc5)cc4)cc3)cc2)cc1]

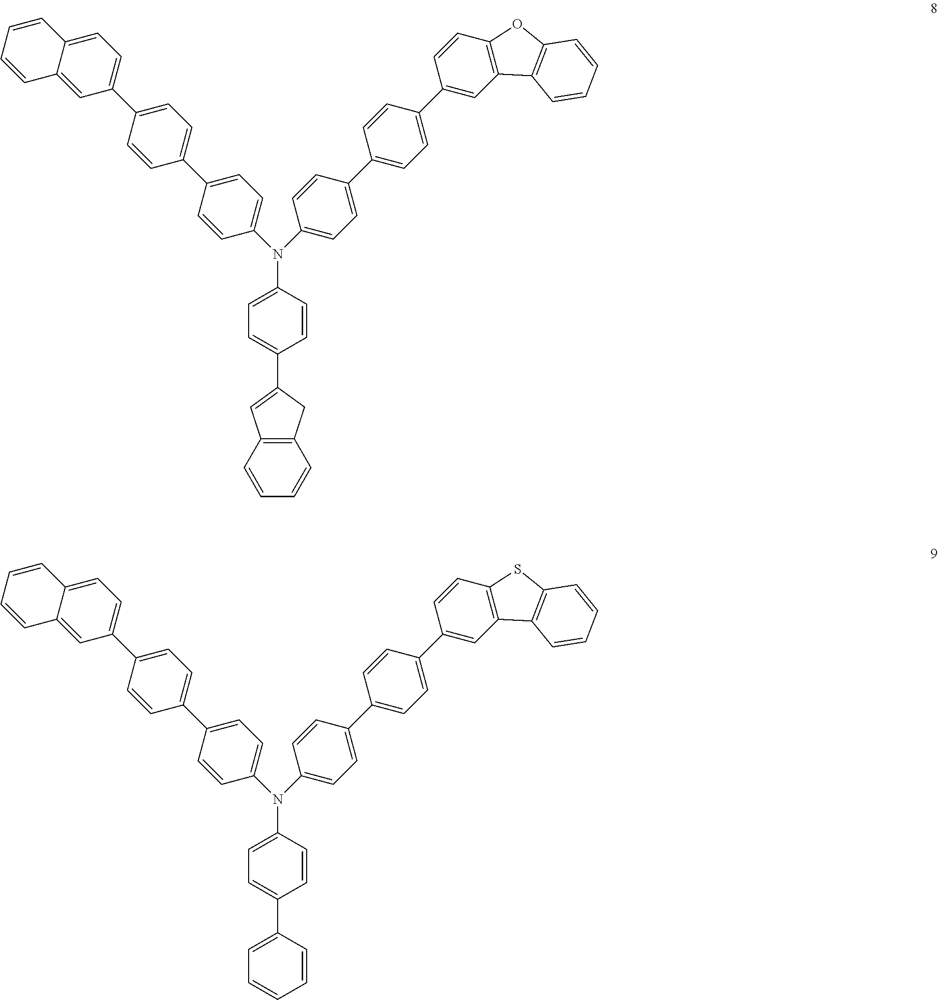 [SMILES: C1=C(c2ccc(N(c3ccc(-c4ccc(-c5ccc6ccccc6c5)cc4)cc3)c3ccc(-c4ccc(-c5ccc6oc7ccccc7c6c5)cc4)cc3)cc2)Cc2ccccc21 ; c1ccc(-c2ccc(N(c3ccc(-c4ccc(-c5ccc6ccccc6c5)cc4)cc3)c3ccc(-c4ccc(-c5ccc6sc7ccccc7c6c5)cc4)cc3)cc2)cc1]

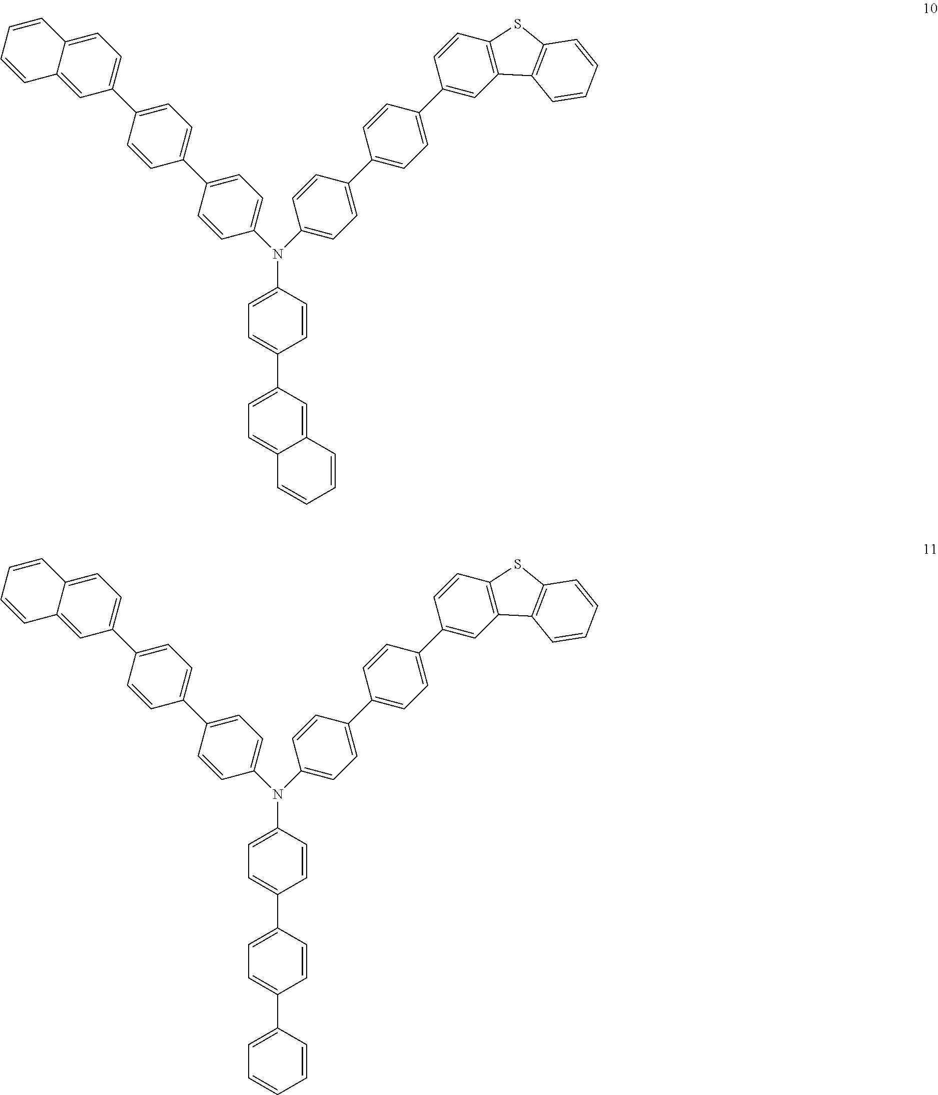 [SMILES: c1ccc2cc(-c3ccc(-c4ccc(N(c5ccc(-c6ccc(-c7ccc8sc9ccccc9c8c7)cc6)cc5)c5ccc(-c6ccc7ccccc7c6)cc5)cc4)cc3)ccc2c1 ; c1ccc(-c2ccc(-c3ccc(N(c4ccc(-c5ccc(-c6ccc7ccccc7c6)cc5)cc4)c4ccc(-c5ccc(-c6ccc7sc8ccccc8c7c6)cc5)cc4)cc3)cc2)cc1]

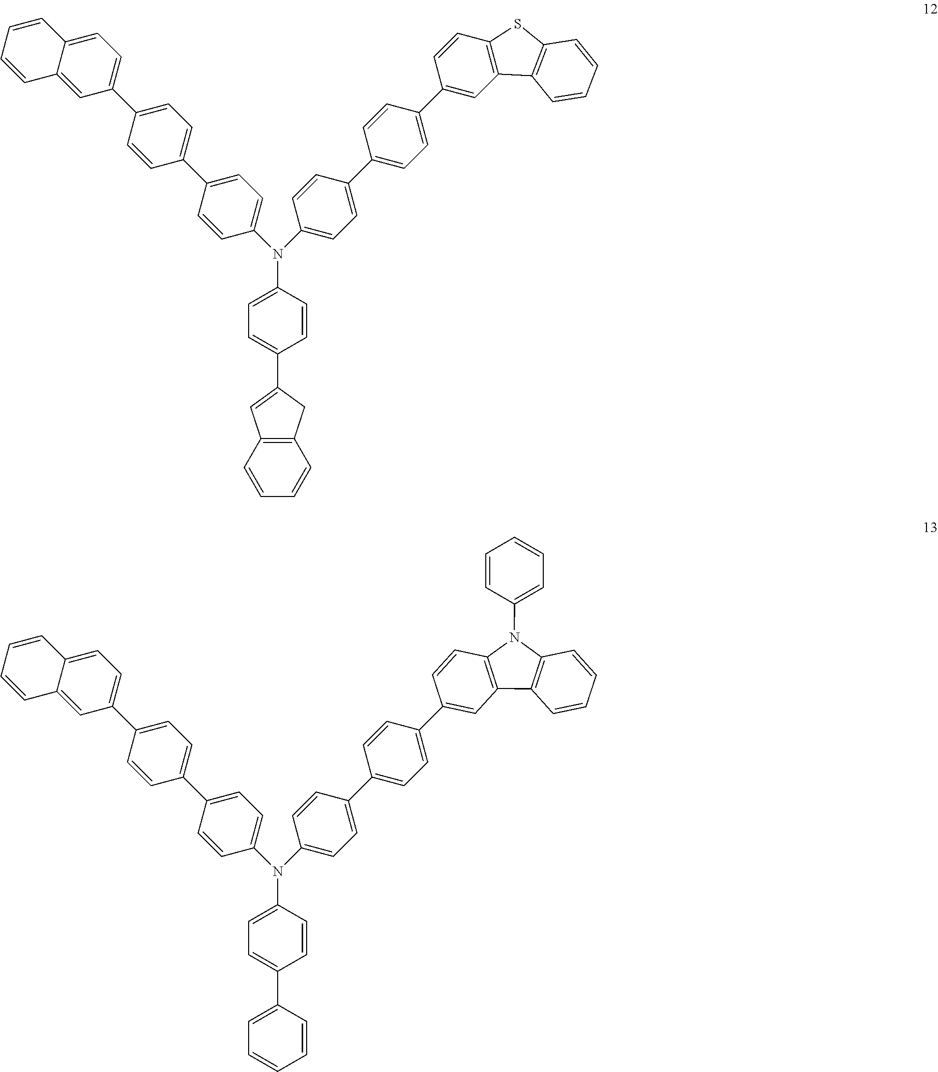 [SMILES: C1=C(c2ccc(N(c3ccc(-c4ccc(-c5ccc6ccccc6c5)cc4)cc3)c3ccc(-c4ccc(-c5ccc6sc7ccccc7c6c5)cc4)cc3)cc2)Cc2ccccc21 ; c1ccc(-c2ccc(N(c3ccc(-c4ccc(-c5ccc6ccccc6c5)cc4)cc3)c3ccc(-c4ccc(-c5ccc6c(c5)c5ccccc5n6-c5ccccc5)cc4)cc3)cc2)cc1]

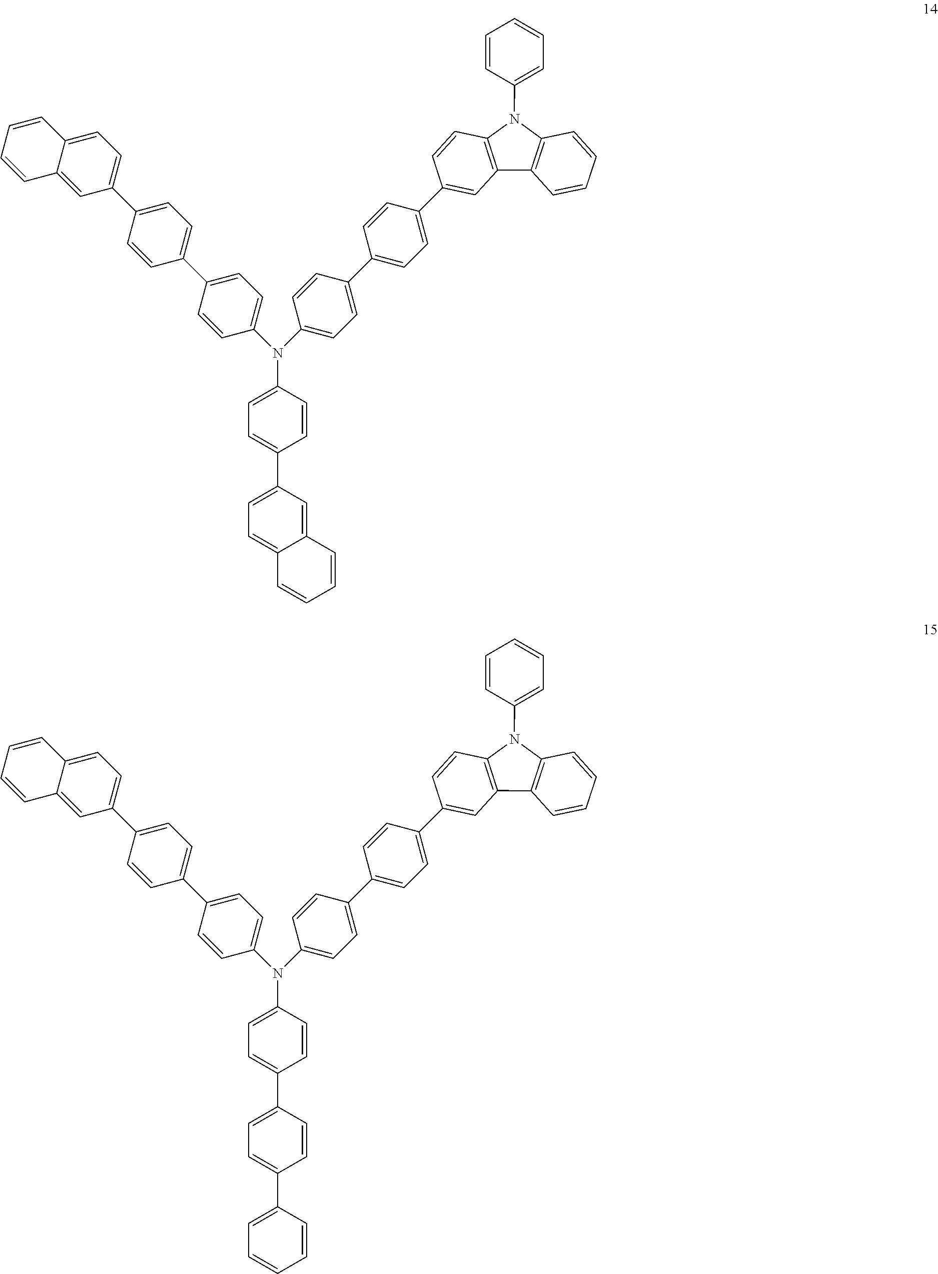 [SMILES: c1ccc(-n2c3ccccc3c3cc(-c4ccc(-c5ccc(N(c6ccc(-c7ccc(-c8ccc9ccccc9c8)cc7)cc6)c6ccc(-c7ccc8ccccc8c7)cc6)cc5)cc4)ccc32)cc1 ; c1ccc(-c2ccc(-c3ccc(N(c4ccc(-c5ccc(-c6ccc7ccccc7c6)cc5)cc4)c4ccc(-c5ccc(-c6ccc7c(c6)c6ccccc6n7-c6ccccc6)cc5)cc4)cc3)cc2)cc1]

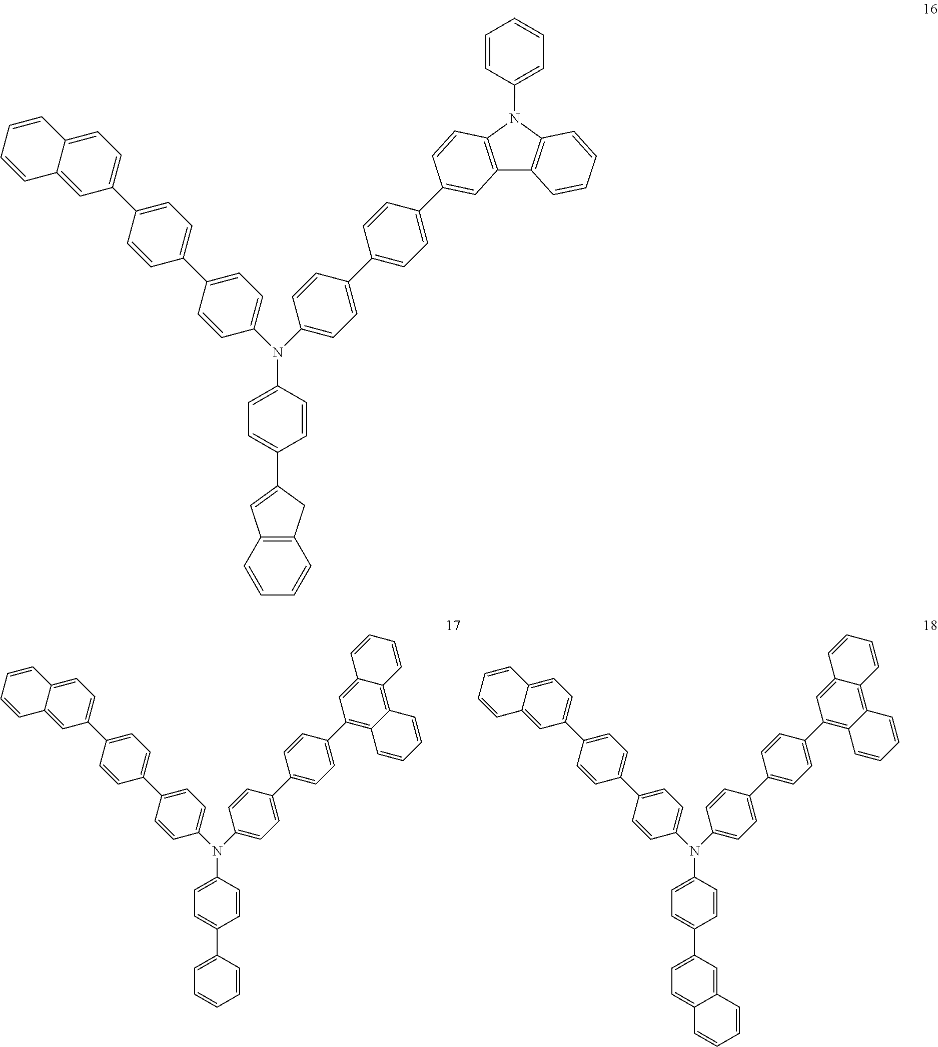 [SMILES: C1=C(c2ccc(N(c3ccc(-c4ccc(-c5ccc6ccccc6c5)cc4)cc3)c3ccc(-c4ccc(-c5ccc6c(c5)c5ccccc5n6-c5ccccc5)cc4)cc3)cc2)Cc2ccccc21 ; c1ccc(-c2ccc(N(c3ccc(-c4ccc(-c5ccc6ccccc6c5)cc4)cc3)c3ccc(-c4ccc(-c5cc6ccccc6c6ccccc56)cc4)cc3)cc2)cc1 ; c1ccc2cc(-c3ccc(-c4ccc(N(c5ccc(-c6ccc(-c7cc8ccccc8c8ccccc78)cc6)cc5)c5ccc(-c6ccc7ccccc7c6)cc5)cc4)cc3)ccc2c1]

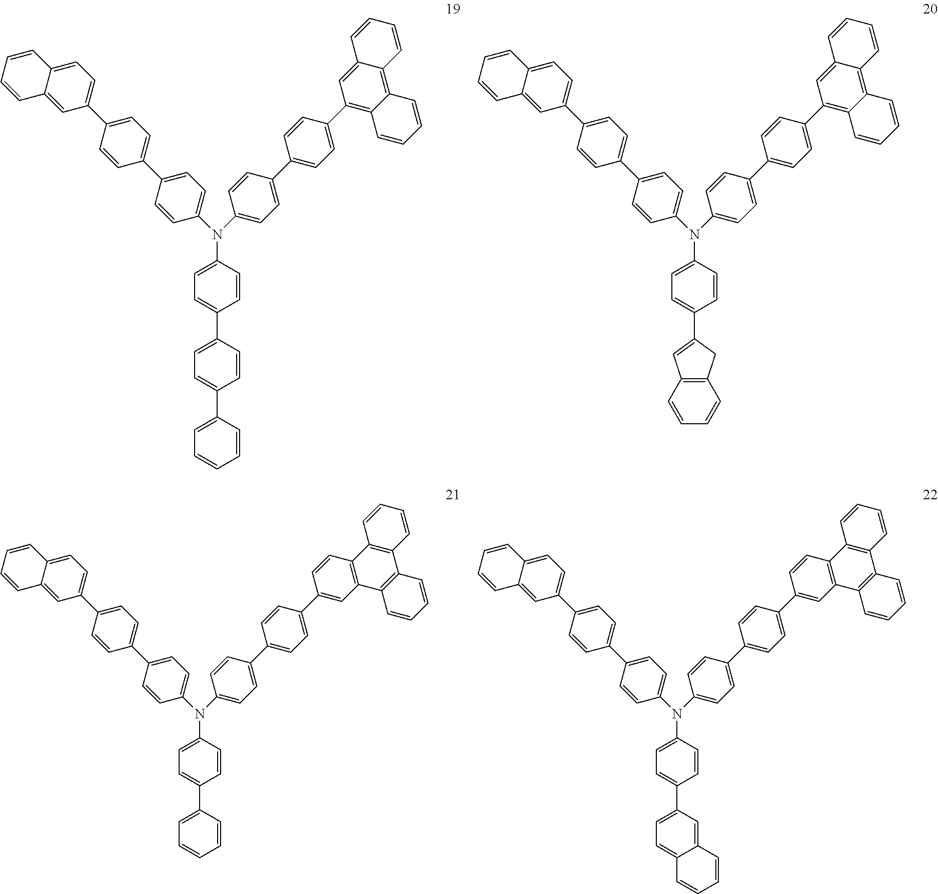 [SMILES: c1ccc(-c2ccc(-c3ccc(N(c4ccc(-c5ccc(-c6ccc7ccccc7c6)cc5)cc4)c4ccc(-c5ccc(-c6cc7ccccc7c7ccccc67)cc5)cc4)cc3)cc2)cc1 ; C1=C(c2ccc(N(c3ccc(-c4ccc(-c5ccc6ccccc6c5)cc4)cc3)c3ccc(-c4ccc(-c5cc6ccccc6c6ccccc56)cc4)cc3)cc2)Cc2ccccc21 ; c1ccc(-c2ccc(N(c3ccc(-c4ccc(-c5ccc6ccccc6c5)cc4)cc3)c3ccc(-c4ccc(-c5ccc6c7ccccc7c7ccccc7c6c5)cc4)cc3)cc2)cc1 ; c1ccc2cc(-c3ccc(-c4ccc(N(c5ccc(-c6ccc(-c7ccc8c9ccccc9c9ccccc9c8c7)cc6)cc5)c5ccc(-c6ccc7ccccc7c6)cc5)cc4)cc3)ccc2c1]

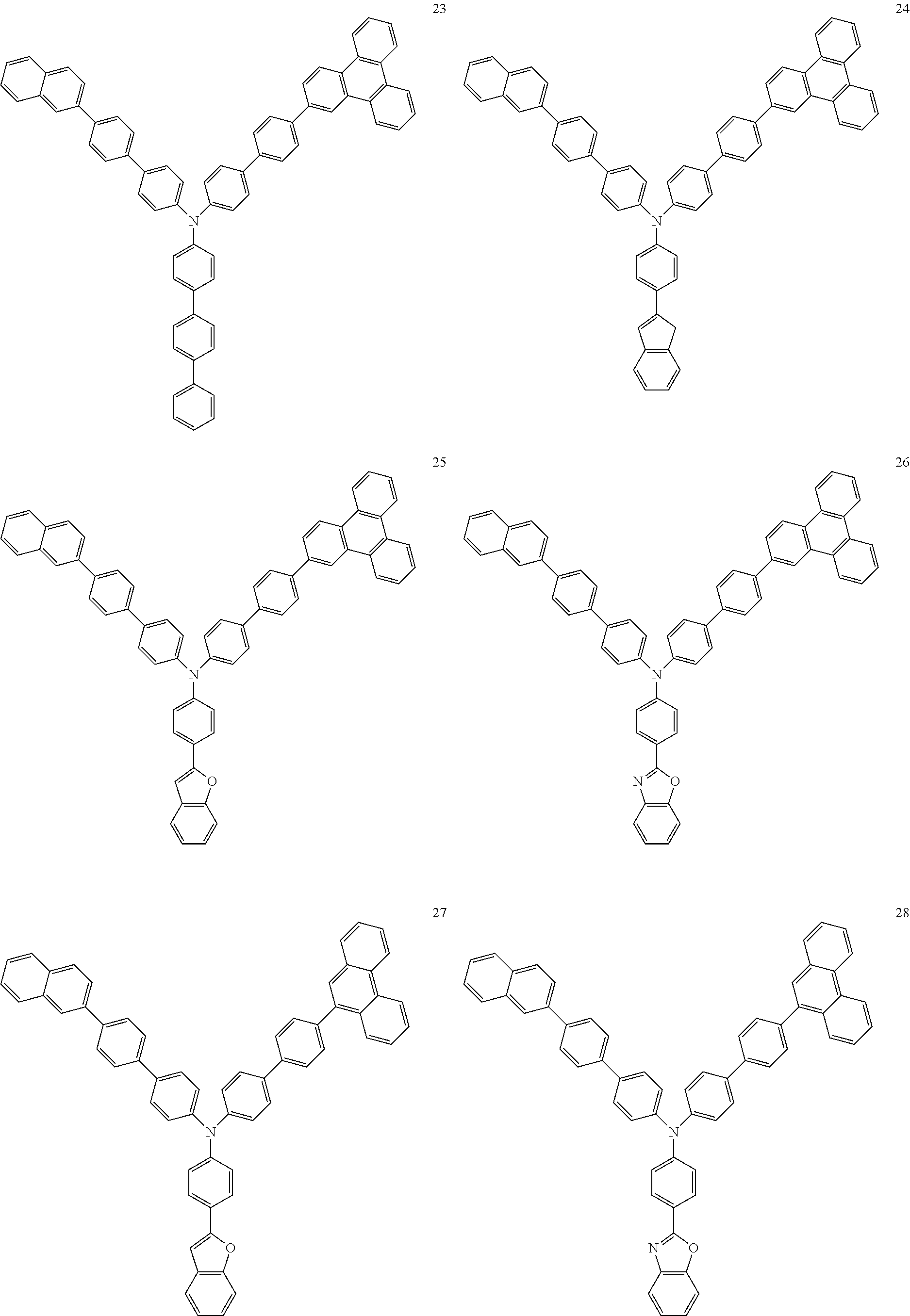

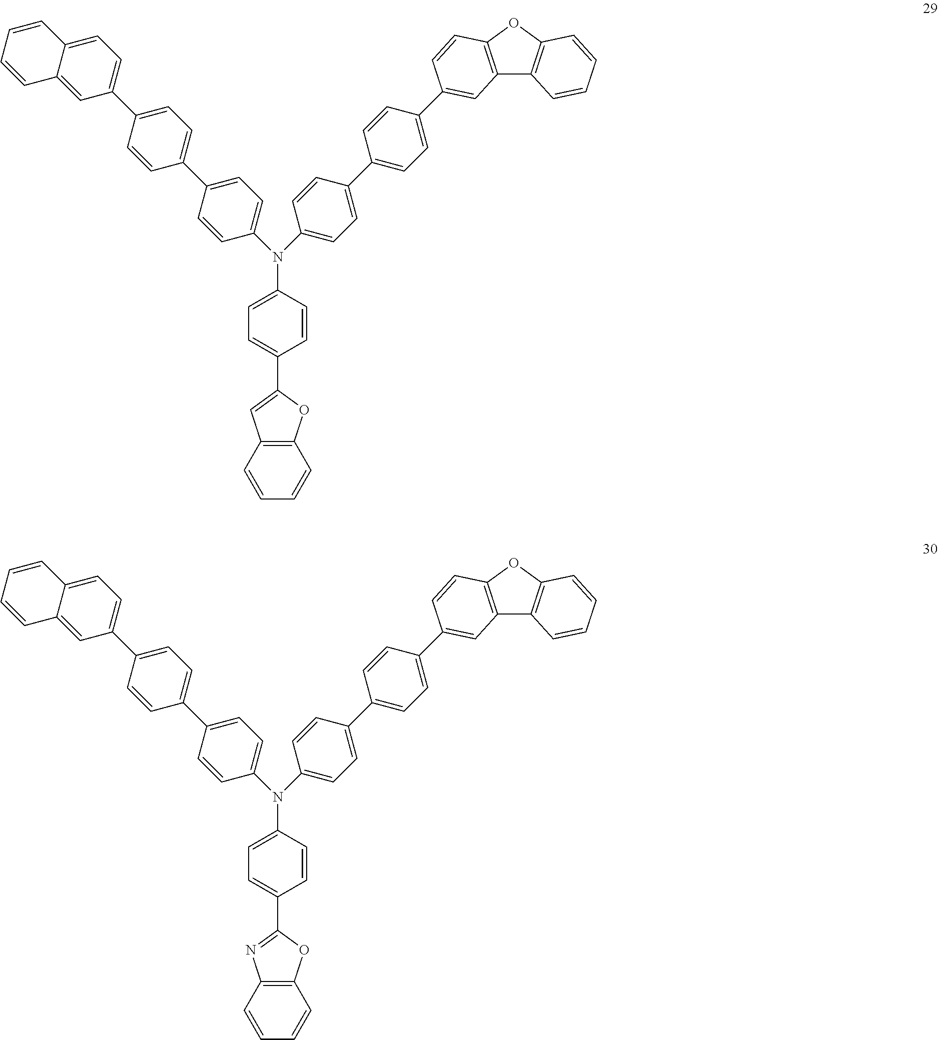 [SMILES: c1ccc2cc(-c3ccc(-c4ccc(N(c5ccc(-c6ccc(-c7ccc8oc9ccccc9c8c7)cc6)cc5)c5ccc(-c6cc7ccccc7o6)cc5)cc4)cc3)ccc2c1 ; c1ccc2cc(-c3ccc(-c4ccc(N(c5ccc(-c6ccc(-c7ccc8oc9ccccc9c8c7)cc6)cc5)c5ccc(-c6nc7ccccc7o6)cc5)cc4)cc3)ccc2c1]

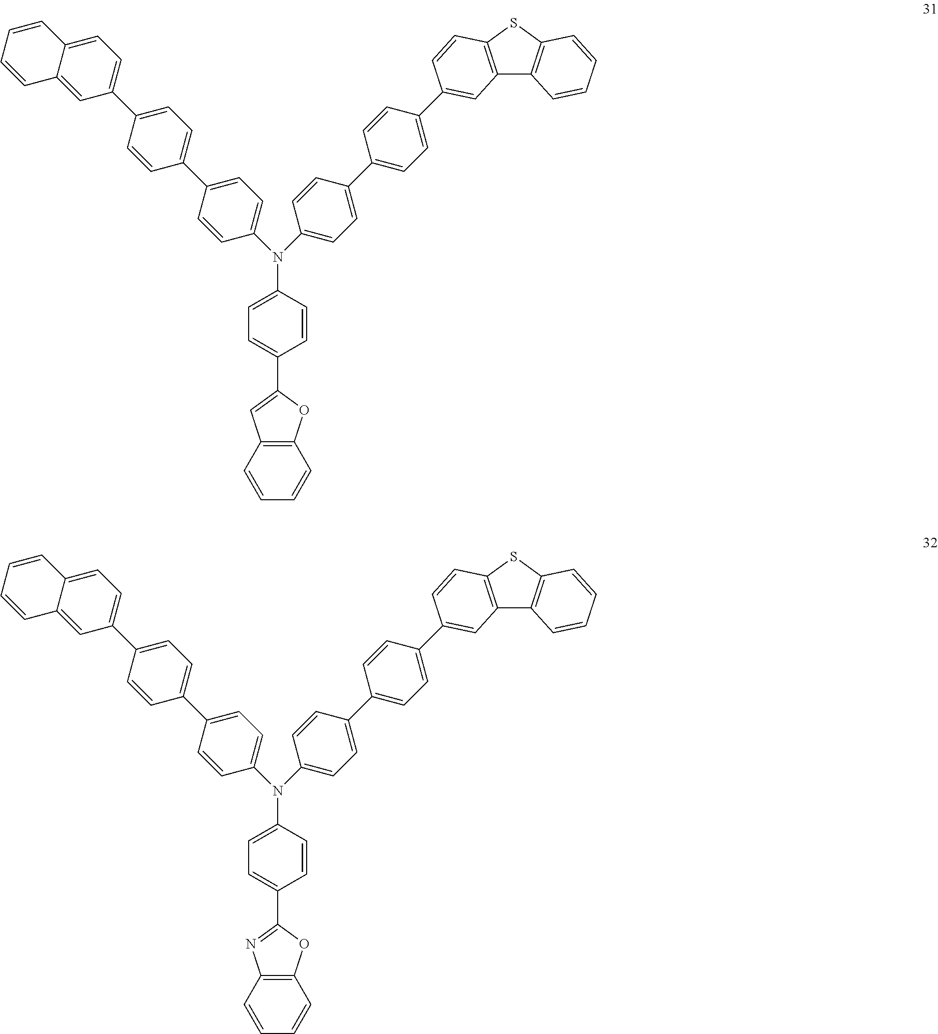 [SMILES: c1ccc2cc(-c3ccc(-c4ccc(N(c5ccc(-c6ccc(-c7ccc8sc9ccccc9c8c7)cc6)cc5)c5ccc(-c6cc7ccccc7o6)cc5)cc4)cc3)ccc2c1 ; c1ccc2cc(-c3ccc(-c4ccc(N(c5ccc(-c6ccc(-c7ccc8sc9ccccc9c8c7)cc6)cc5)c5ccc(-c6nc7ccccc7o6)cc5)cc4)cc3)ccc2c1]

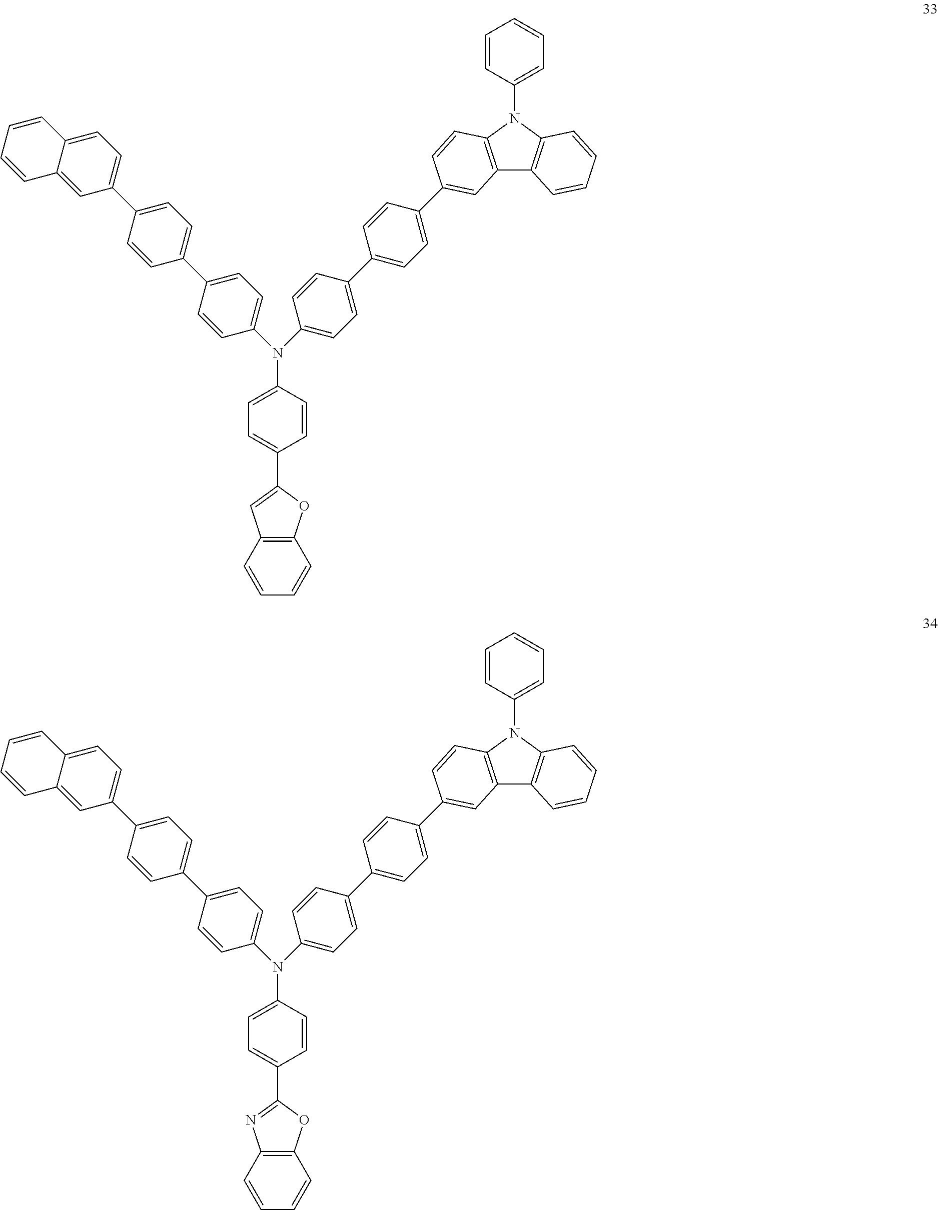 [SMILES: c1ccc(-n2c3ccccc3c3cc(-c4ccc(-c5ccc(N(c6ccc(-c7ccc(-c8ccc9ccccc9c8)cc7)cc6)c6ccc(-c7cc8ccccc8o7)cc6)cc5)cc4)ccc32)cc1 ; c1ccc(-n2c3ccccc3c3cc(-c4ccc(-c5ccc(N(c6ccc(-c7ccc(-c8ccc9ccccc9c8)cc7)cc6)c6ccc(-c7nc8ccccc8o7)cc6)cc5)cc4)ccc32)cc1]

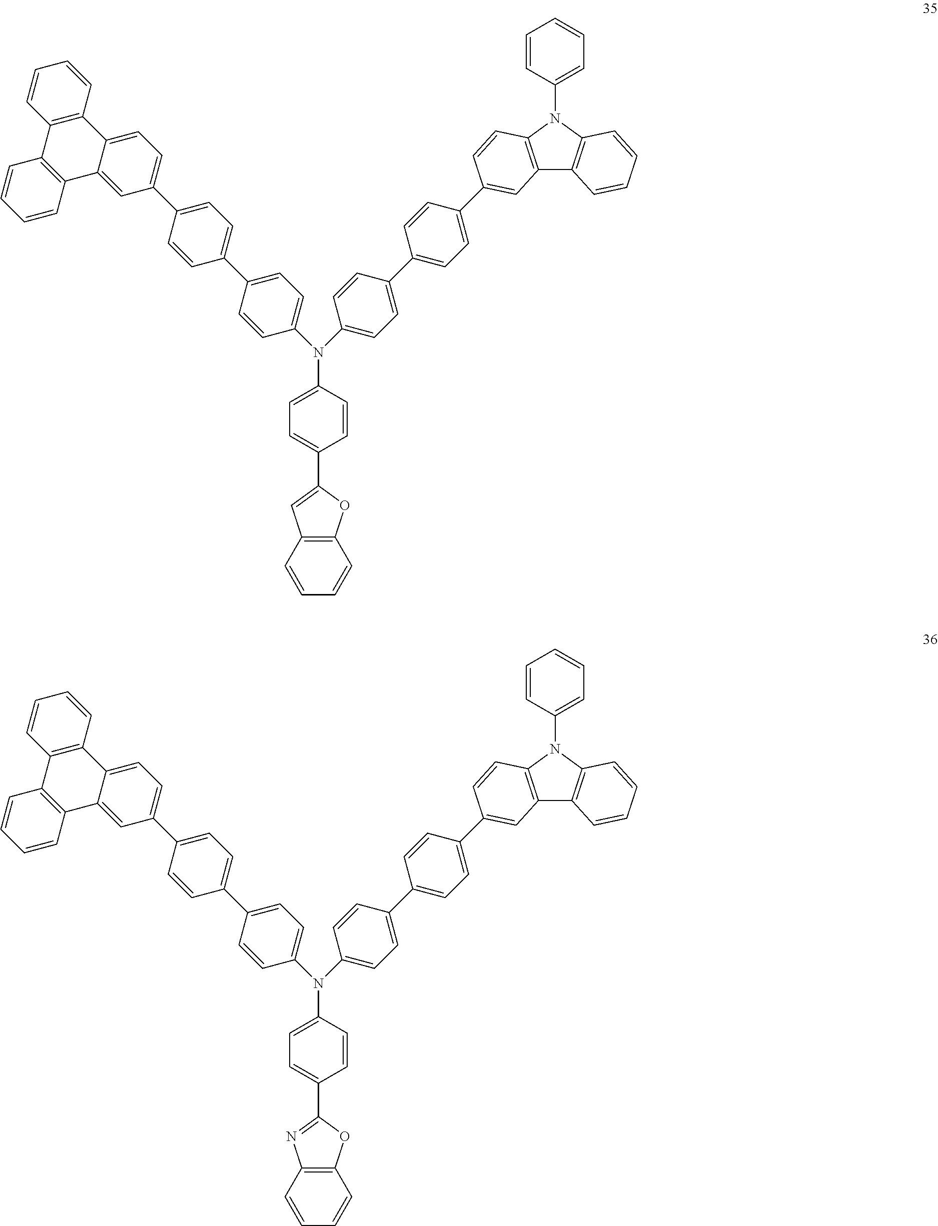 [SMILES: c1ccc(-n2c3ccccc3c3cc(-c4ccc(-c5ccc(N(c6ccc(-c7ccc(-c8ccc9c%10ccccc%10c%10ccccc%10c9c8)cc7)cc6)c6ccc(-c7cc8ccccc8o7)cc6)cc5)cc4)ccc32)cc1 ; c1ccc(-n2c3ccccc3c3cc(-c4ccc(-c5ccc(N(c6ccc(-c7ccc(-c8ccc9c%10ccccc%10c%10ccccc%10c9c8)cc7)cc6)c6ccc(-c7nc8ccccc8o7)cc6)cc5)cc4)ccc32)cc1]

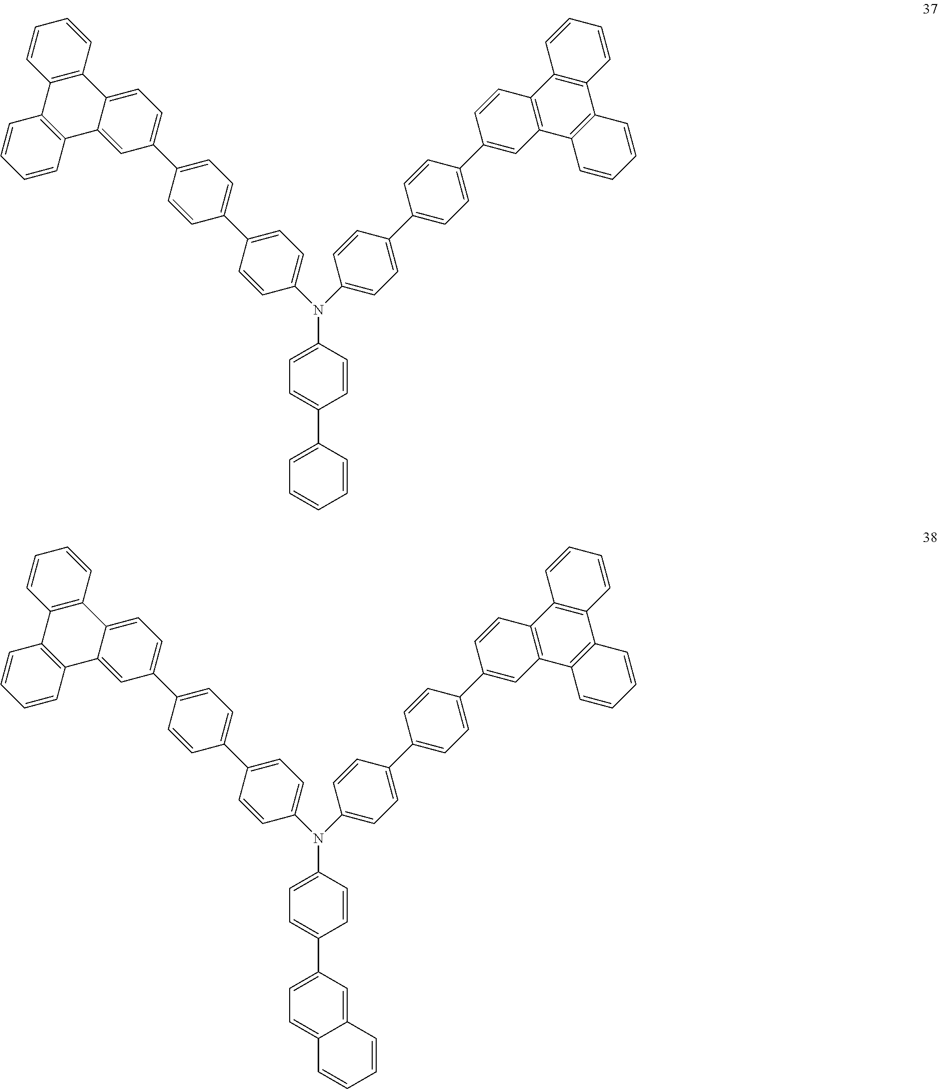 [SMILES: c1ccc(-c2ccc(N(c3ccc(-c4ccc(-c5ccc6c7ccccc7c7ccccc7c6c5)cc4)cc3)c3ccc(-c4ccc(-c5ccc6c7ccccc7c7ccccc7c6c5)cc4)cc3)cc2)cc1 ; c1ccc2cc(-c3ccc(N(c4ccc(-c5ccc(-c6ccc7c8ccccc8c8ccccc8c7c6)cc5)cc4)c4ccc(-c5ccc(-c6ccc7c8ccccc8c8ccccc8c7c6)cc5)cc4)cc3)ccc2c1]

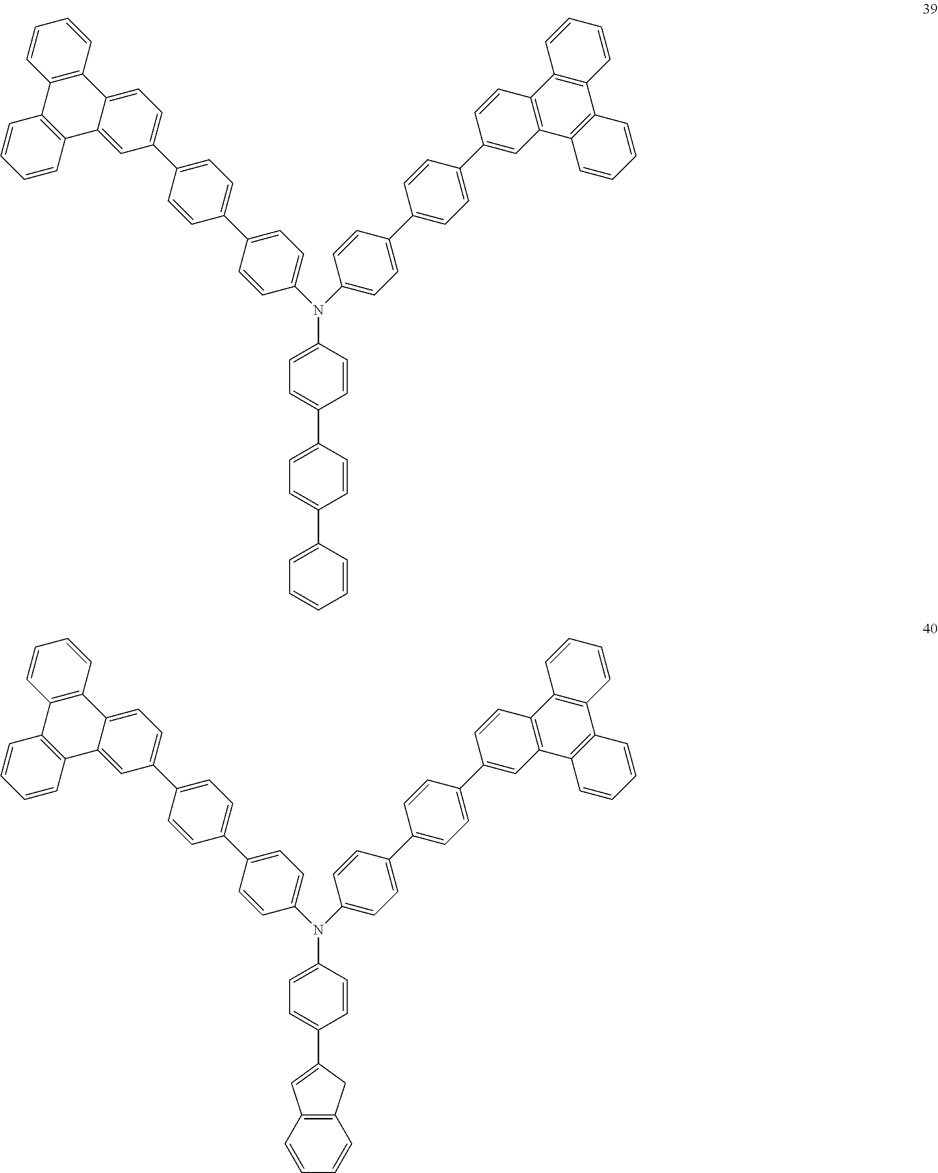 [SMILES: c1ccc(-c2ccc(-c3ccc(N(c4ccc(-c5ccc(-c6ccc7c8ccccc8c8ccccc8c7c6)cc5)cc4)c4ccc(-c5ccc(-c6ccc7c8ccccc8c8ccccc8c7c6)cc5)cc4)cc3)cc2)cc1 ; C1=C(c2ccc(N(c3ccc(-c4ccc(-c5ccc6c7ccccc7c7ccccc7c6c5)cc4)cc3)c3ccc(-c4ccc(-c5ccc6c7ccccc7c7ccccc7c6c5)cc4)cc3)cc2)Cc2ccccc21]

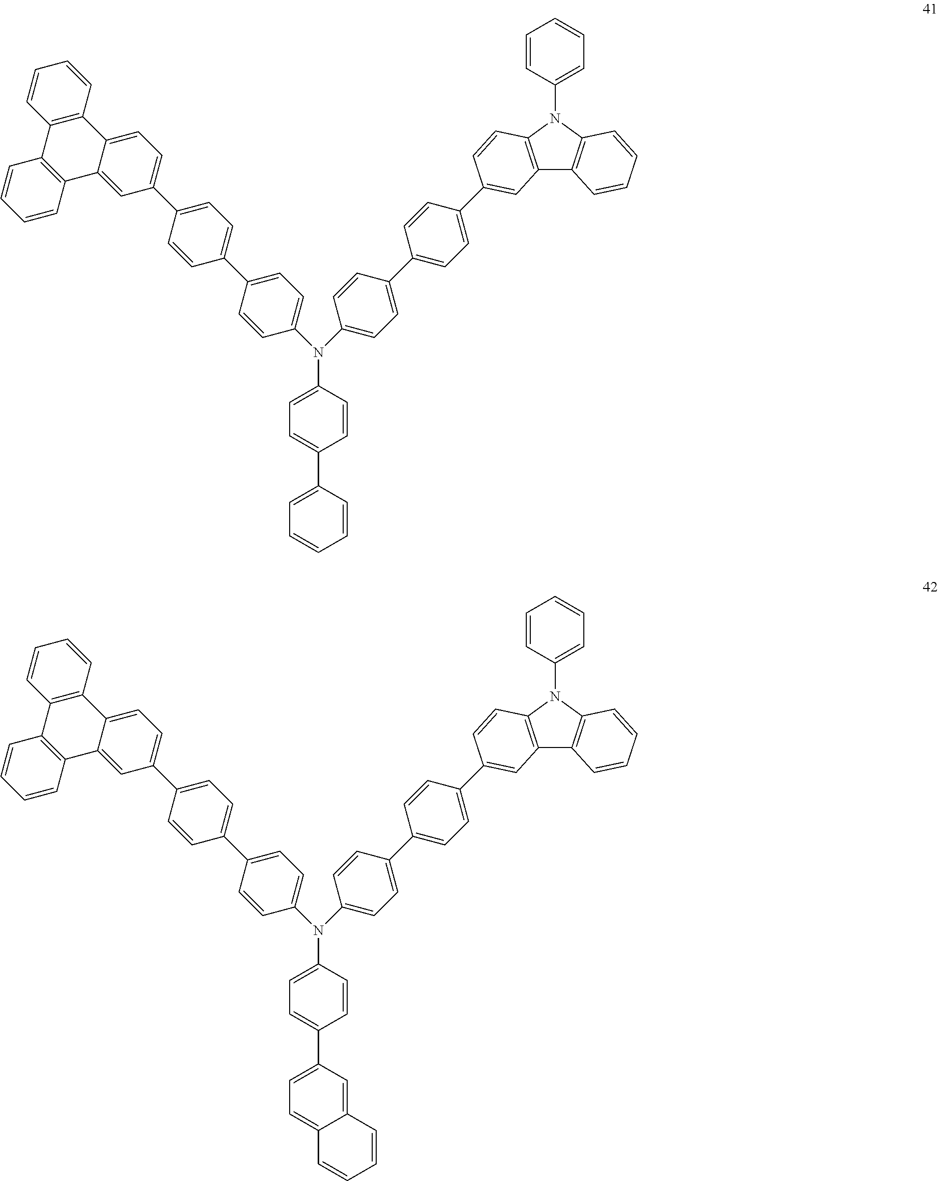 [SMILES: c1ccc(-c2ccc(N(c3ccc(-c4ccc(-c5ccc6c7ccccc7c7ccccc7c6c5)cc4)cc3)c3ccc(-c4ccc(-c5ccc6c(c5)c5ccccc5n6-c5ccccc5)cc4)cc3)cc2)cc1 ; c1ccc(-n2c3ccccc3c3cc(-c4ccc(-c5ccc(N(c6ccc(-c7ccc(-c8ccc9c%10ccccc%10c%10ccccc%10c9c8)cc7)cc6)c6ccc(-c7ccc8ccccc8c7)cc6)cc5)cc4)ccc32)cc1]

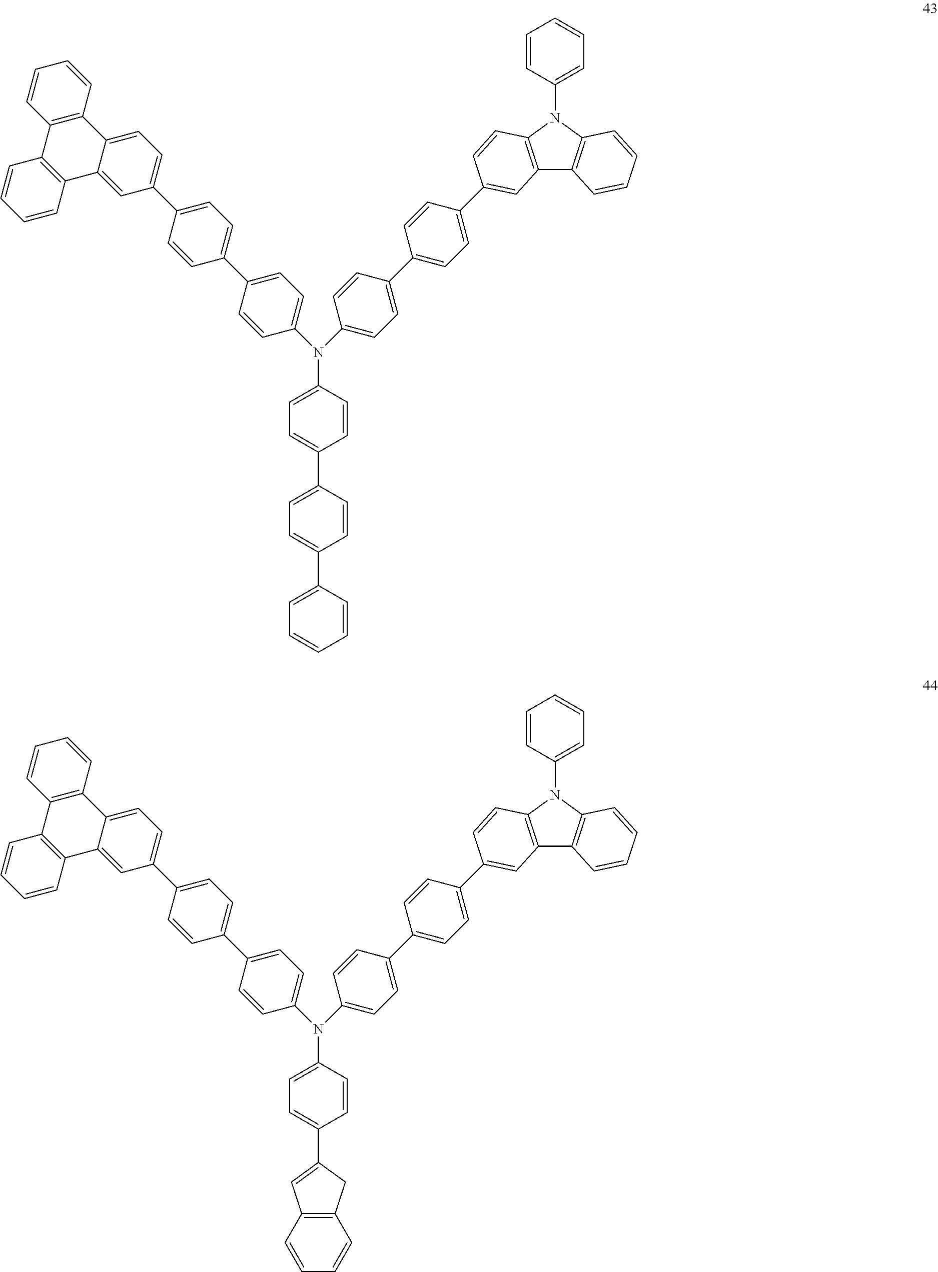 [SMILES: c1ccc(-c2ccc(-c3ccc(N(c4ccc(-c5ccc(-c6ccc7c8ccccc8c8ccccc8c7c6)cc5)cc4)c4ccc(-c5ccc(-c6ccc7c(c6)c6ccccc6n7-c6ccccc6)cc5)cc4)cc3)cc2)cc1 ; C1=C(c2ccc(N(c3ccc(-c4ccc(-c5ccc6c7ccccc7c7ccccc7c6c5)cc4)cc3)c3ccc(-c4ccc(-c5ccc6c(c5)c5ccccc5n6-c5ccccc5)cc4)cc3)cc2)Cc2ccccc21]

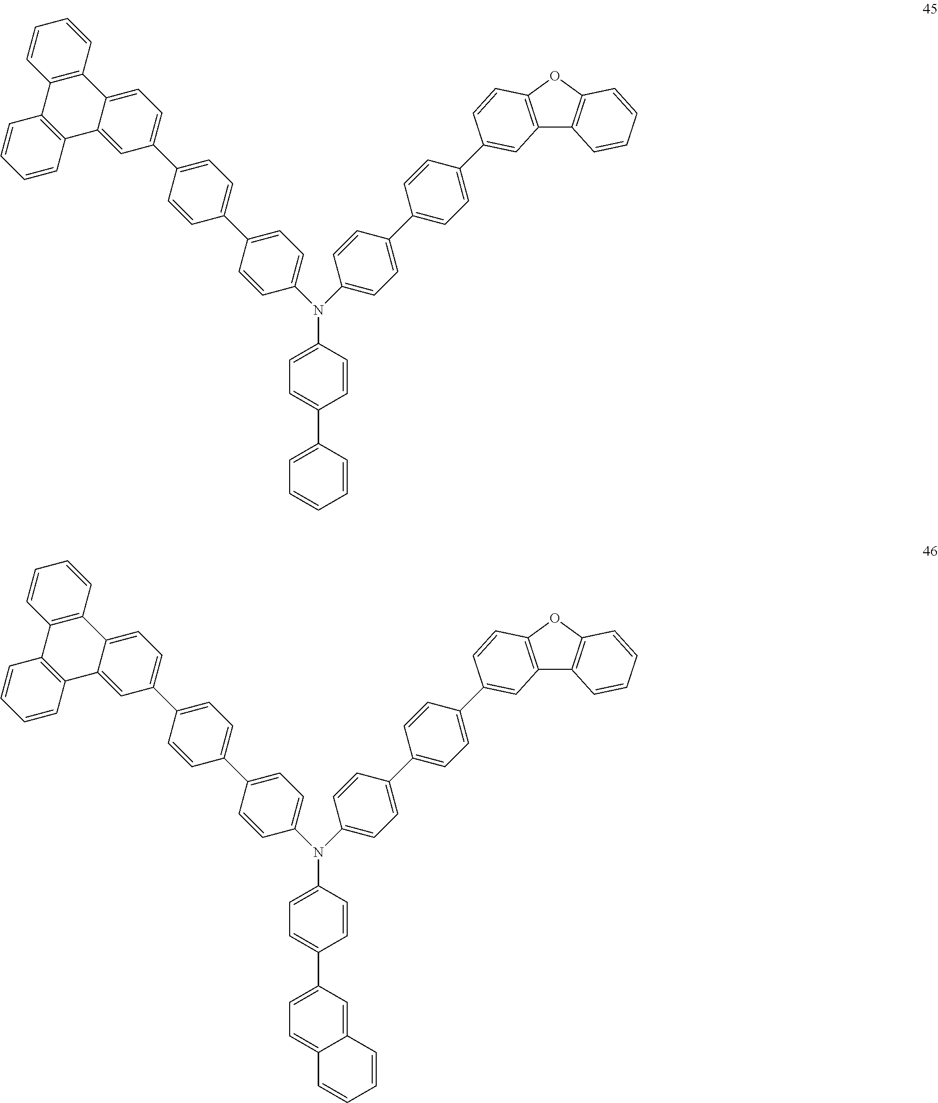 [SMILES: c1ccc(-c2ccc(N(c3ccc(-c4ccc(-c5ccc6oc7ccccc7c6c5)cc4)cc3)c3ccc(-c4ccc(-c5ccc6c7ccccc7c7ccccc7c6c5)cc4)cc3)cc2)cc1 ; c1ccc2cc(-c3ccc(N(c4ccc(-c5ccc(-c6ccc7oc8ccccc8c7c6)cc5)cc4)c4ccc(-c5ccc(-c6ccc7c8ccccc8c8ccccc8c7c6)cc5)cc4)cc3)ccc2c1]

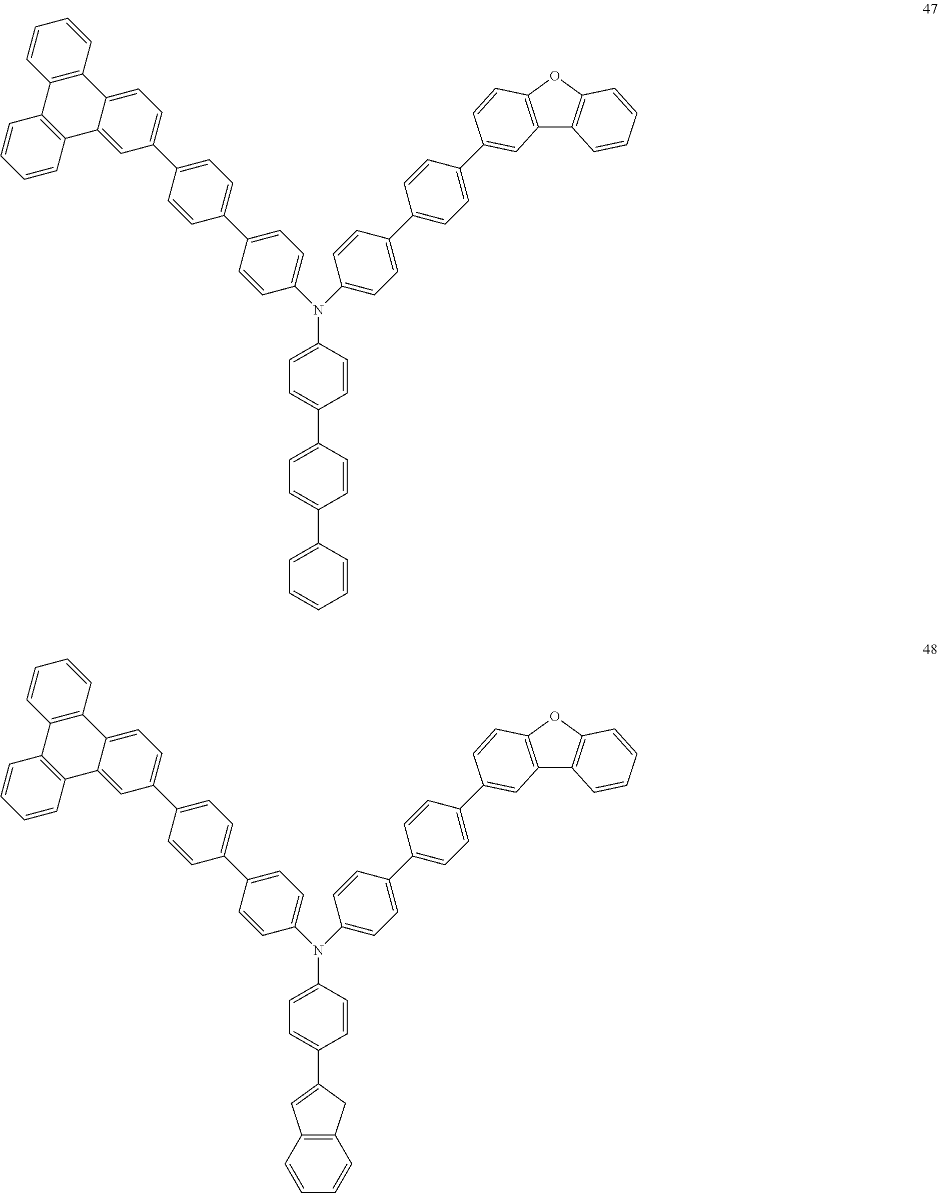 [SMILES: c1ccc(-c2ccc(-c3ccc(N(c4ccc(-c5ccc(-c6ccc7oc8ccccc8c7c6)cc5)cc4)c4ccc(-c5ccc(-c6ccc7c8ccccc8c8ccccc8c7c6)cc5)cc4)cc3)cc2)cc1 ; C1=C(c2ccc(N(c3ccc(-c4ccc(-c5ccc6oc7ccccc7c6c5)cc4)cc3)c3ccc(-c4ccc(-c5ccc6c7ccccc7c7ccccc7c6c5)cc4)cc3)cc2)Cc2ccccc21]

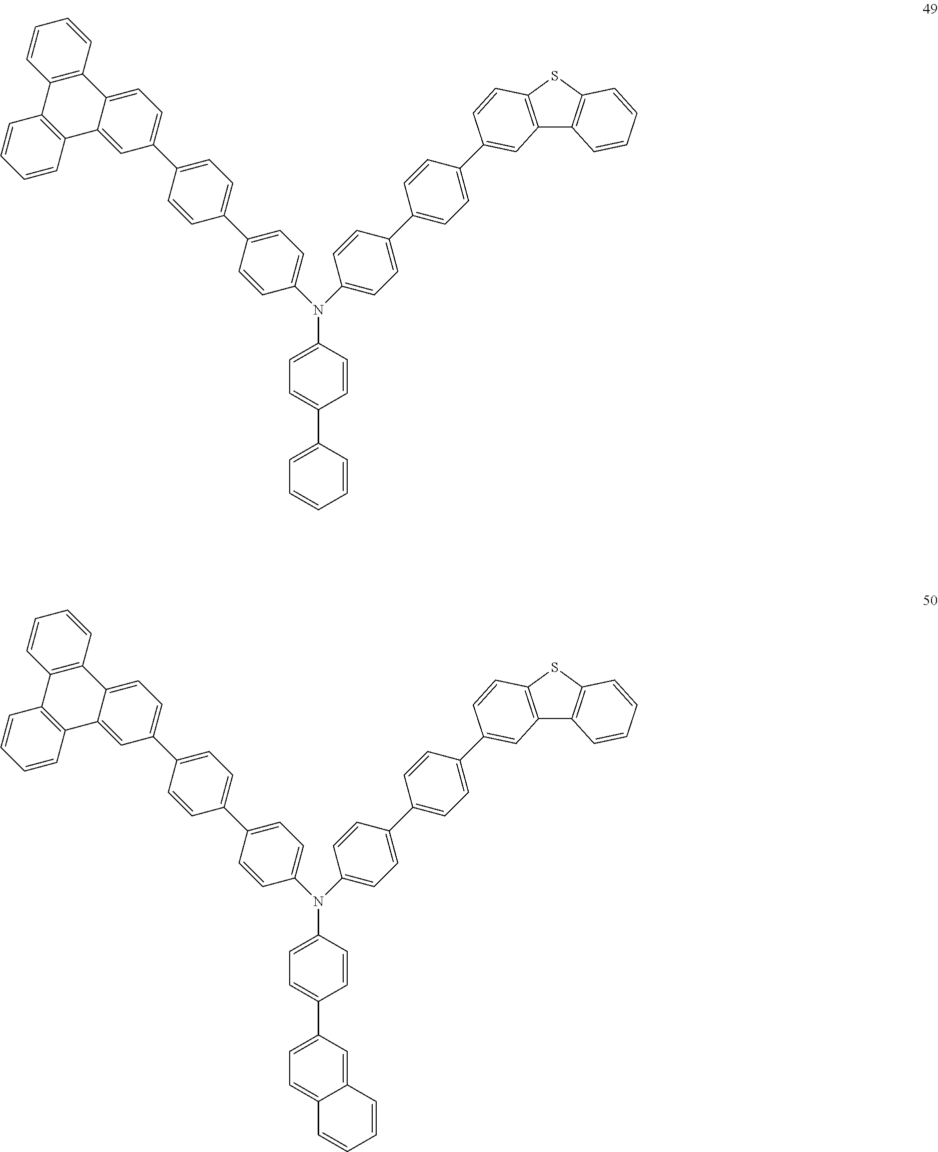 [SMILES: c1ccc(-c2ccc(N(c3ccc(-c4ccc(-c5ccc6sc7ccccc7c6c5)cc4)cc3)c3ccc(-c4ccc(-c5ccc6c7ccccc7c7ccccc7c6c5)cc4)cc3)cc2)cc1 ; c1ccc2cc(-c3ccc(N(c4ccc(-c5ccc(-c6ccc7sc8ccccc8c7c6)cc5)cc4)c4ccc(-c5ccc(-c6ccc7c8ccccc8c8ccccc8c7c6)cc5)cc4)cc3)ccc2c1]

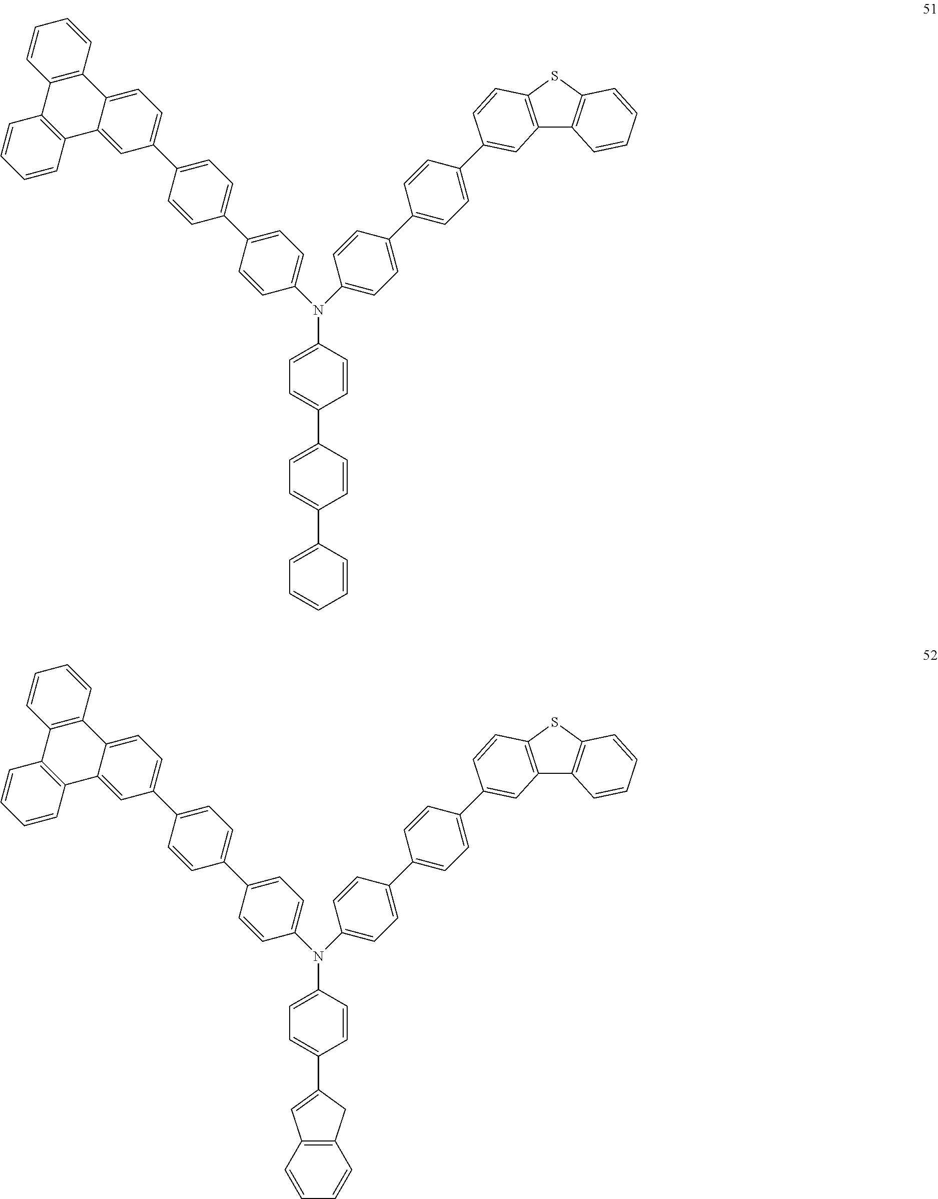 [SMILES: c1ccc(-c2ccc(-c3ccc(N(c4ccc(-c5ccc(-c6ccc7sc8ccccc8c7c6)cc5)cc4)c4ccc(-c5ccc(-c6ccc7c8ccccc8c8ccccc8c7c6)cc5)cc4)cc3)cc2)cc1 ; C1=C(c2ccc(N(c3ccc(-c4ccc(-c5ccc6sc7ccccc7c6c5)cc4)cc3)c3ccc(-c4ccc(-c5ccc6c7ccccc7c7ccccc7c6c5)cc4)cc3)cc2)Cc2ccccc21]

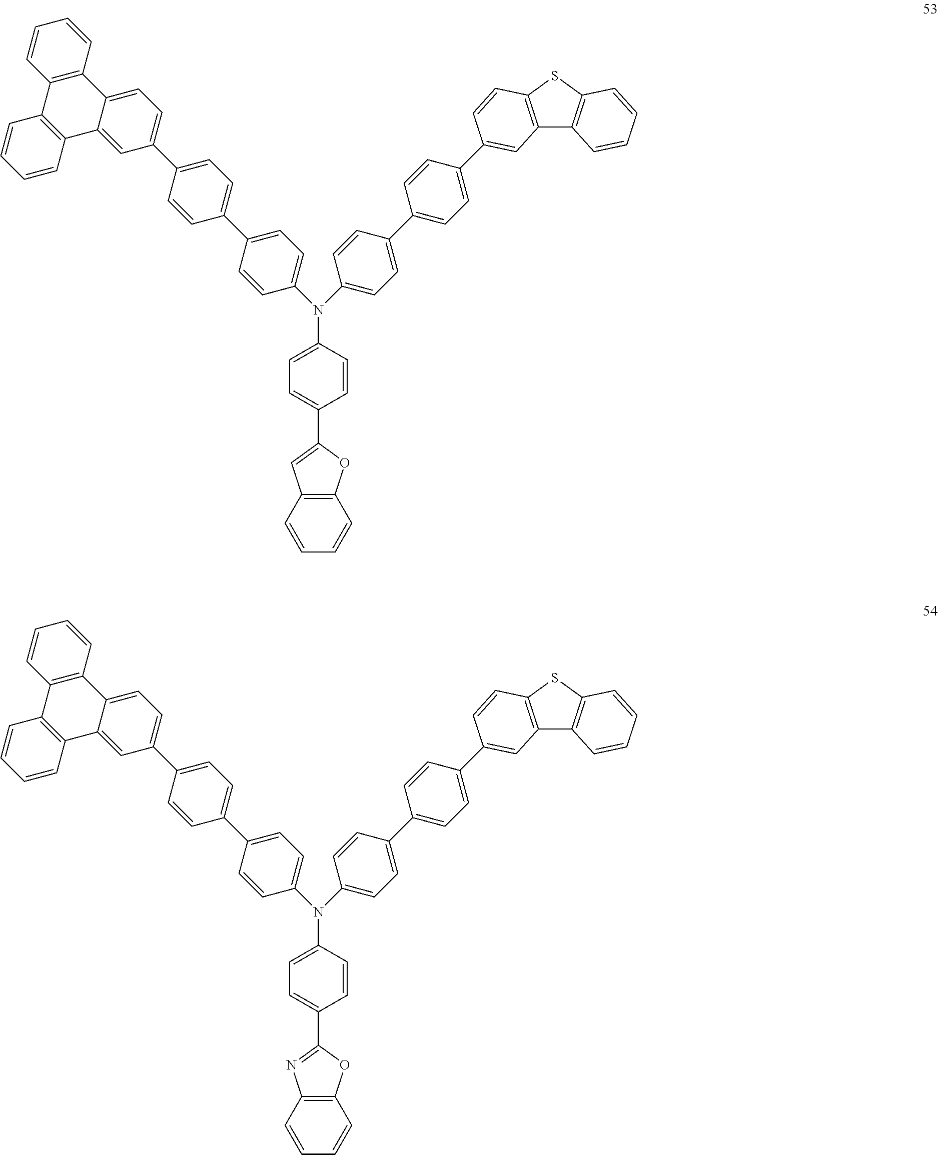 [SMILES: c1ccc2oc(-c3ccc(N(c4ccc(-c5ccc(-c6ccc7sc8ccccc8c7c6)cc5)cc4)c4ccc(-c5ccc(-c6ccc7c8ccccc8c8ccccc8c7c6)cc5)cc4)cc3)cc2c1 ; c1ccc2oc(-c3ccc(N(c4ccc(-c5ccc(-c6ccc7sc8ccccc8c7c6)cc5)cc4)c4ccc(-c5ccc(-c6ccc7c8ccccc8c8ccccc8c7c6)cc5)cc4)cc3)nc2c1]

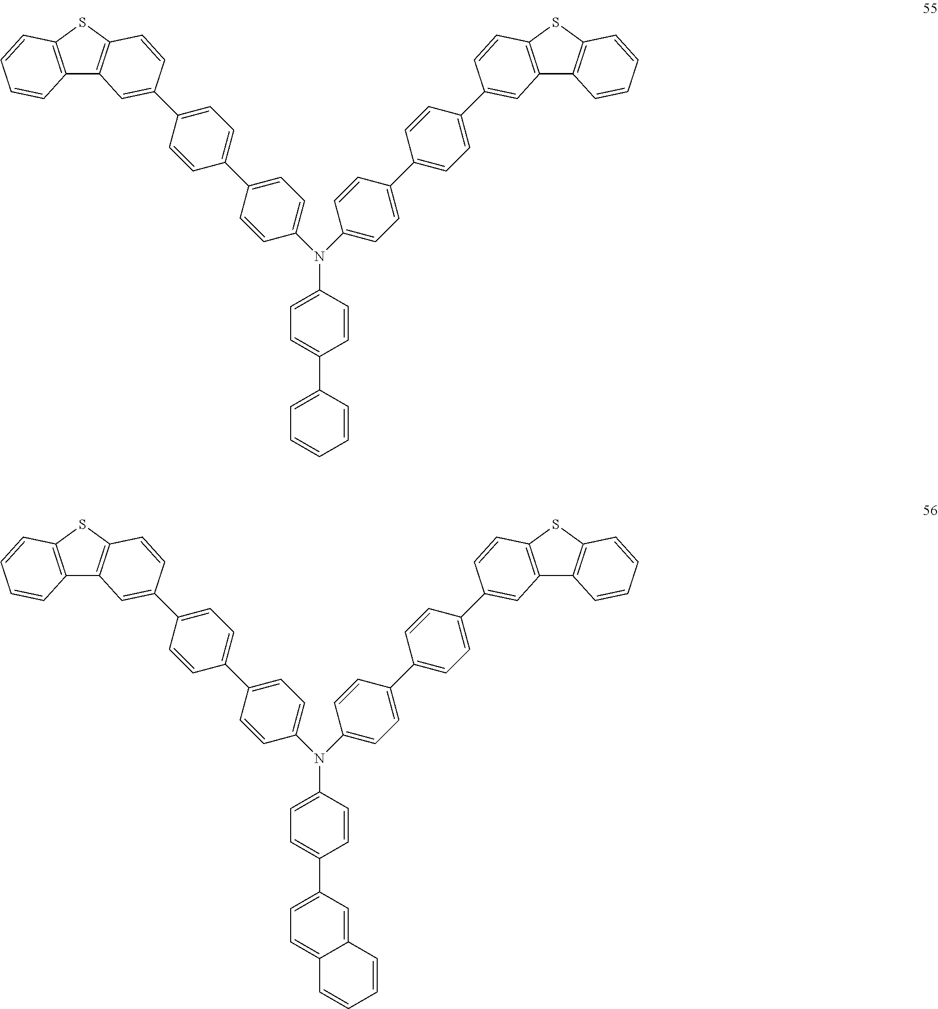 [SMILES: c1ccc(-c2ccc(N(c3ccc(-c4ccc(-c5ccc6sc7ccccc7c6c5)cc4)cc3)c3ccc(-c4ccc(-c5ccc6sc7ccccc7c6c5)cc4)cc3)cc2)cc1 ; c1ccc2cc(-c3ccc(N(c4ccc(-c5ccc(-c6ccc7sc8ccccc8c7c6)cc5)cc4)c4ccc(-c5ccc(-c6ccc7sc8ccccc8c7c6)cc5)cc4)cc3)ccc2c1]

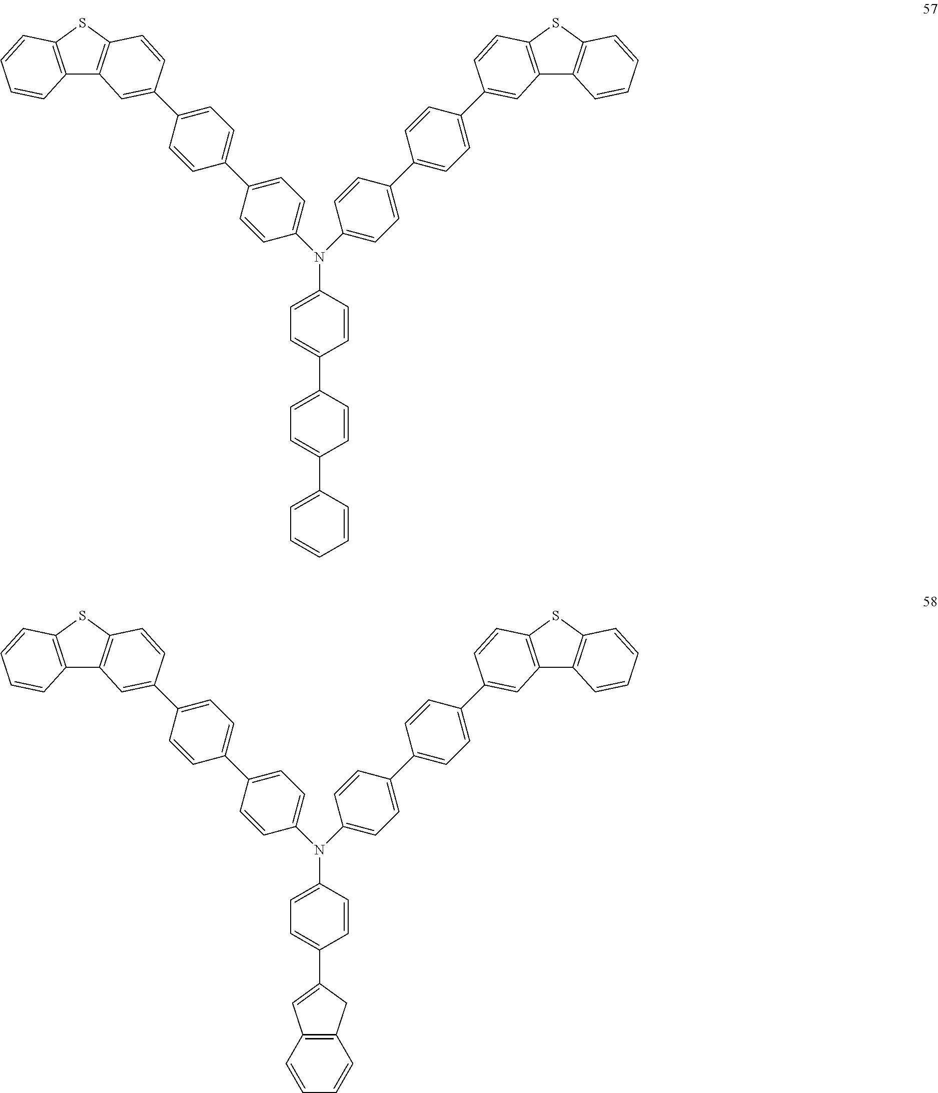 [SMILES: c1ccc(-c2ccc(-c3ccc(N(c4ccc(-c5ccc(-c6ccc7sc8ccccc8c7c6)cc5)cc4)c4ccc(-c5ccc(-c6ccc7sc8ccccc8c7c6)cc5)cc4)cc3)cc2)cc1 ; C1=C(c2ccc(N(c3ccc(-c4ccc(-c5ccc6sc7ccccc7c6c5)cc4)cc3)c3ccc(-c4ccc(-c5ccc6sc7ccccc7c6c5)cc4)cc3)cc2)Cc2ccccc21]

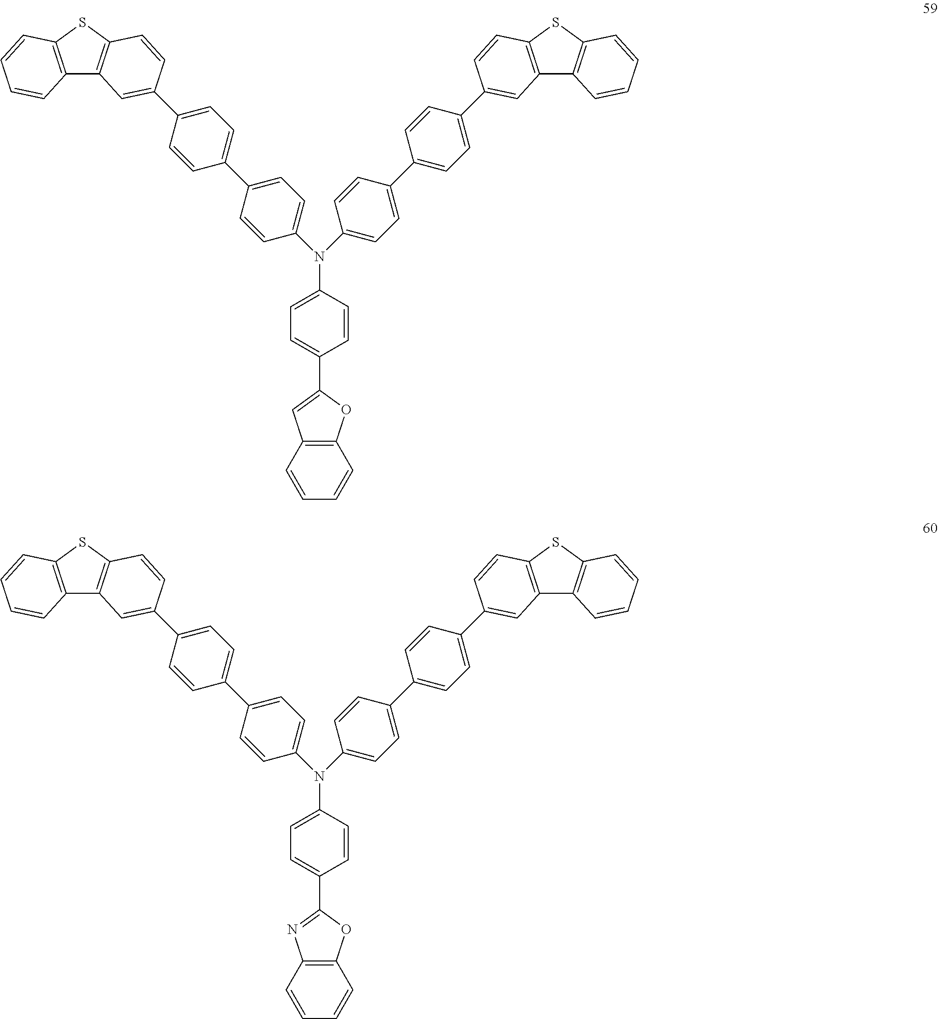 [SMILES: c1ccc2oc(-c3ccc(N(c4ccc(-c5ccc(-c6ccc7sc8ccccc8c7c6)cc5)cc4)c4ccc(-c5ccc(-c6ccc7sc8ccccc8c7c6)cc5)cc4)cc3)cc2c1 ; c1ccc2oc(-c3ccc(N(c4ccc(-c5ccc(-c6ccc7sc8ccccc8c7c6)cc5)cc4)c4ccc(-c5ccc(-c6ccc7sc8ccccc8c7c6)cc5)cc4)cc3)nc2c1]

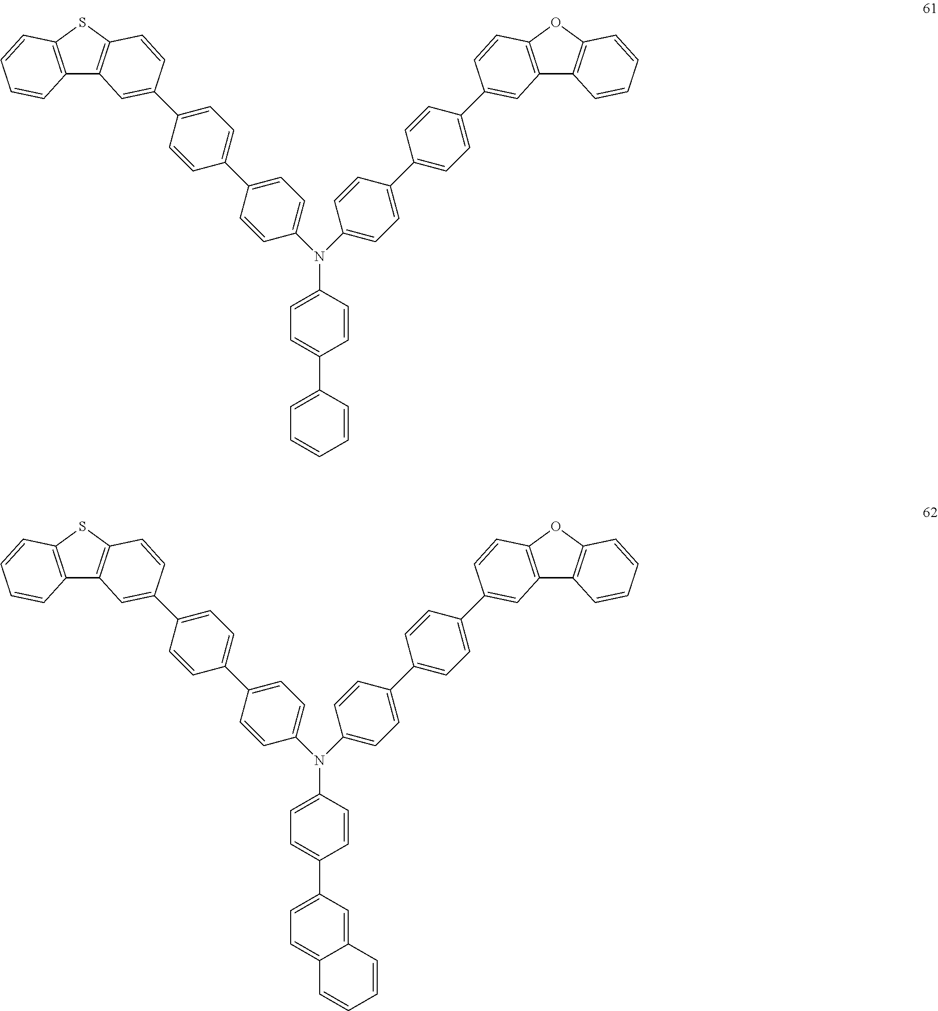 [SMILES: c1ccc(-c2ccc(N(c3ccc(-c4ccc(-c5ccc6oc7ccccc7c6c5)cc4)cc3)c3ccc(-c4ccc(-c5ccc6sc7ccccc7c6c5)cc4)cc3)cc2)cc1 ; c1ccc2cc(-c3ccc(N(c4ccc(-c5ccc(-c6ccc7oc8ccccc8c7c6)cc5)cc4)c4ccc(-c5ccc(-c6ccc7sc8ccccc8c7c6)cc5)cc4)cc3)ccc2c1]

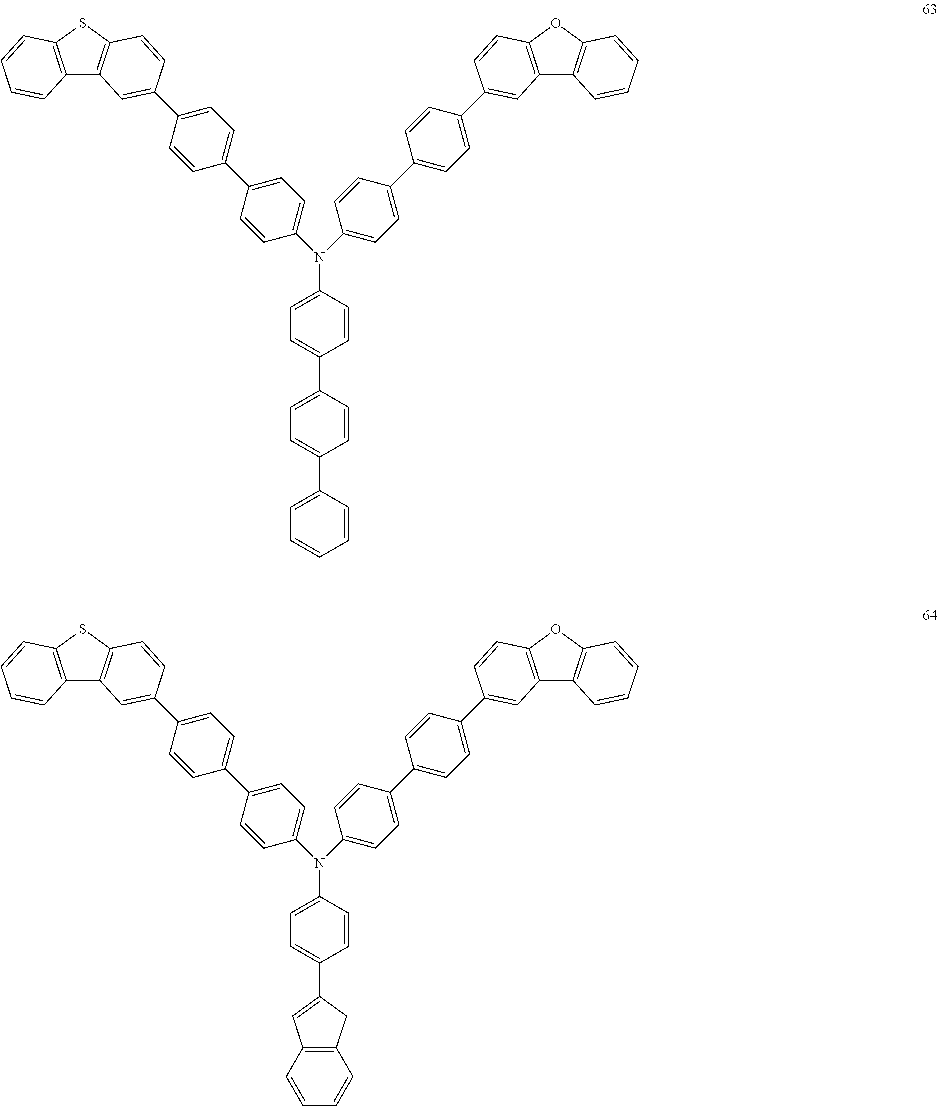 [SMILES: c1ccc(-c2ccc(-c3ccc(N(c4ccc(-c5ccc(-c6ccc7oc8ccccc8c7c6)cc5)cc4)c4ccc(-c5ccc(-c6ccc7sc8ccccc8c7c6)cc5)cc4)cc3)cc2)cc1 ; C1=C(c2ccc(N(c3ccc(-c4ccc(-c5ccc6oc7ccccc7c6c5)cc4)cc3)c3ccc(-c4ccc(-c5ccc6sc7ccccc7c6c5)cc4)cc3)cc2)Cc2ccccc21]

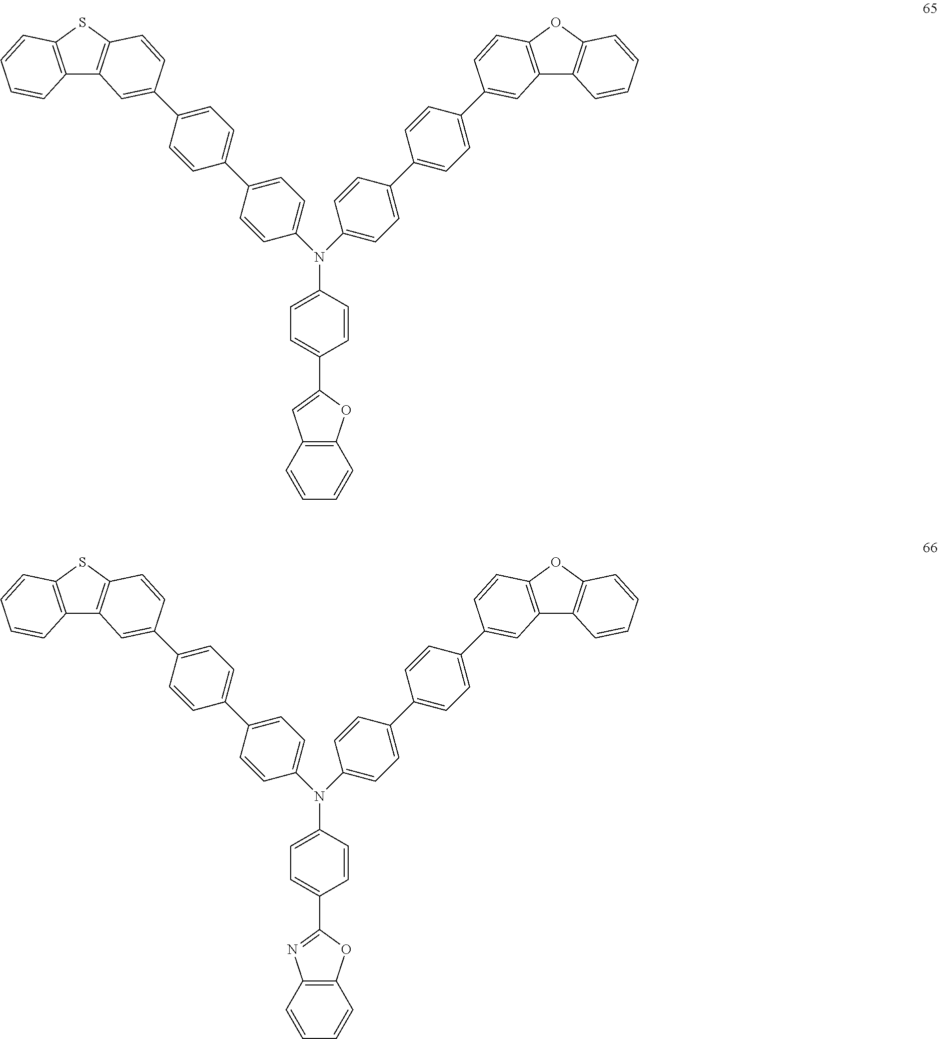 [SMILES: c1ccc2oc(-c3ccc(N(c4ccc(-c5ccc(-c6ccc7oc8ccccc8c7c6)cc5)cc4)c4ccc(-c5ccc(-c6ccc7sc8ccccc8c7c6)cc5)cc4)cc3)cc2c1 ; c1ccc2oc(-c3ccc(N(c4ccc(-c5ccc(-c6ccc7oc8ccccc8c7c6)cc5)cc4)c4ccc(-c5ccc(-c6ccc7sc8ccccc8c7c6)cc5)cc4)cc3)nc2c1]

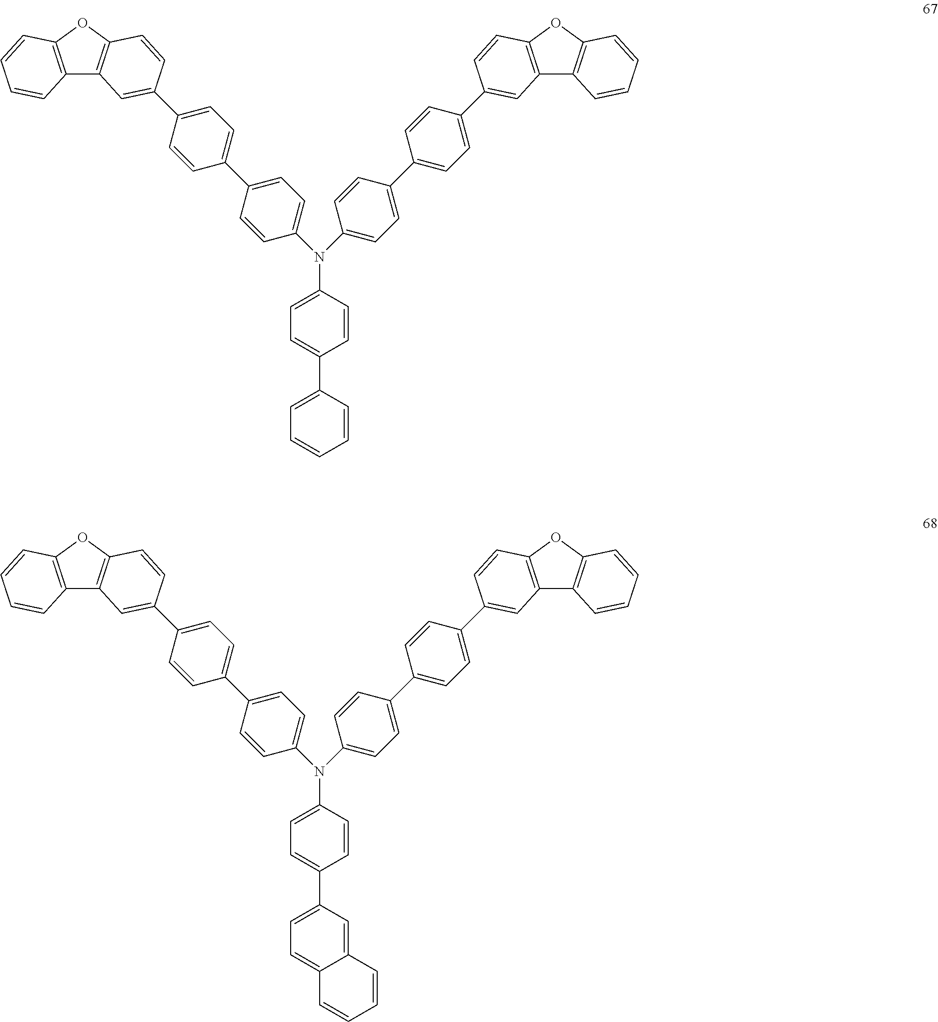 [SMILES: c1ccc(-c2ccc(N(c3ccc(-c4ccc(-c5ccc6oc7ccccc7c6c5)cc4)cc3)c3ccc(-c4ccc(-c5ccc6oc7ccccc7c6c5)cc4)cc3)cc2)cc1 ; c1ccc2cc(-c3ccc(N(c4ccc(-c5ccc(-c6ccc7oc8ccccc8c7c6)cc5)cc4)c4ccc(-c5ccc(-c6ccc7oc8ccccc8c7c6)cc5)cc4)cc3)ccc2c1]

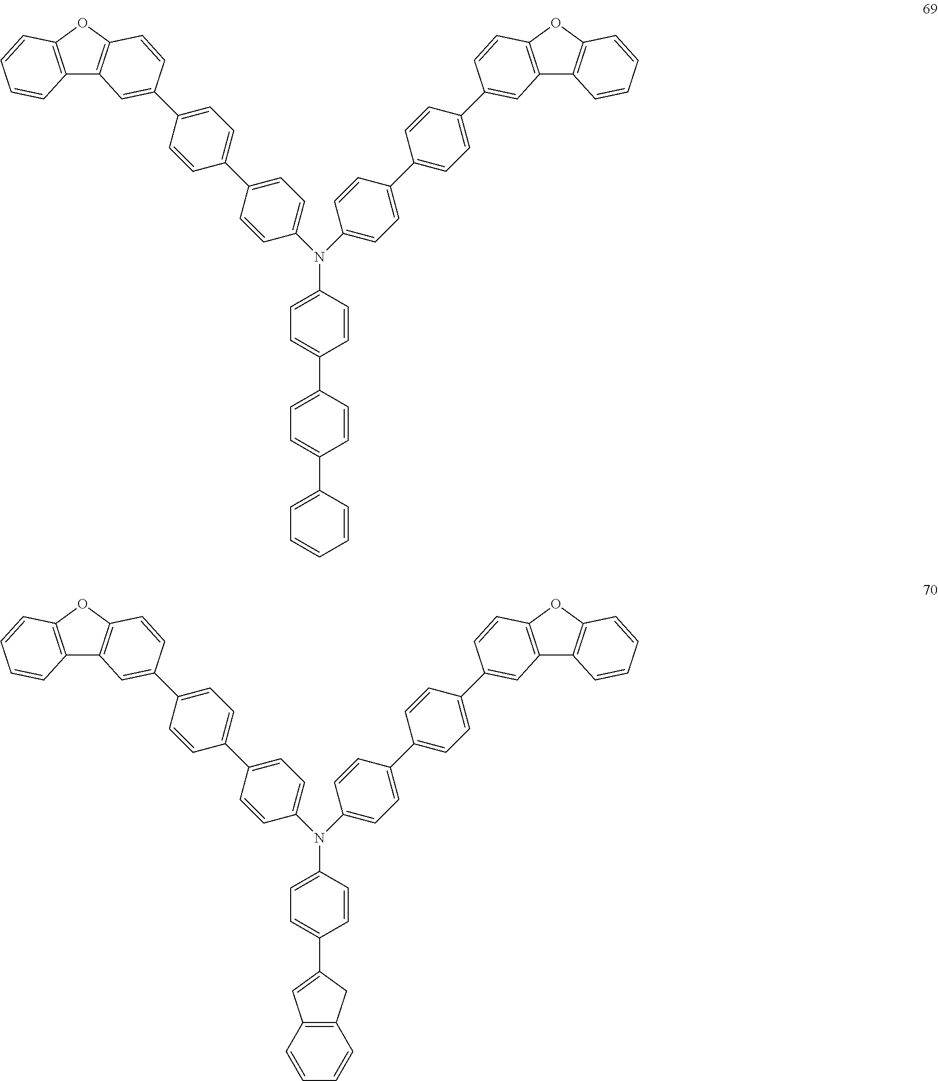 [SMILES: c1ccc(-c2ccc(-c3ccc(N(c4ccc(-c5ccc(-c6ccc7oc8ccccc8c7c6)cc5)cc4)c4ccc(-c5ccc(-c6ccc7oc8ccccc8c7c6)cc5)cc4)cc3)cc2)cc1 ; C1=C(c2ccc(N(c3ccc(-c4ccc(-c5ccc6oc7ccccc7c6c5)cc4)cc3)c3ccc(-c4ccc(-c5ccc6oc7ccccc7c6c5)cc4)cc3)cc2)Cc2ccccc21]

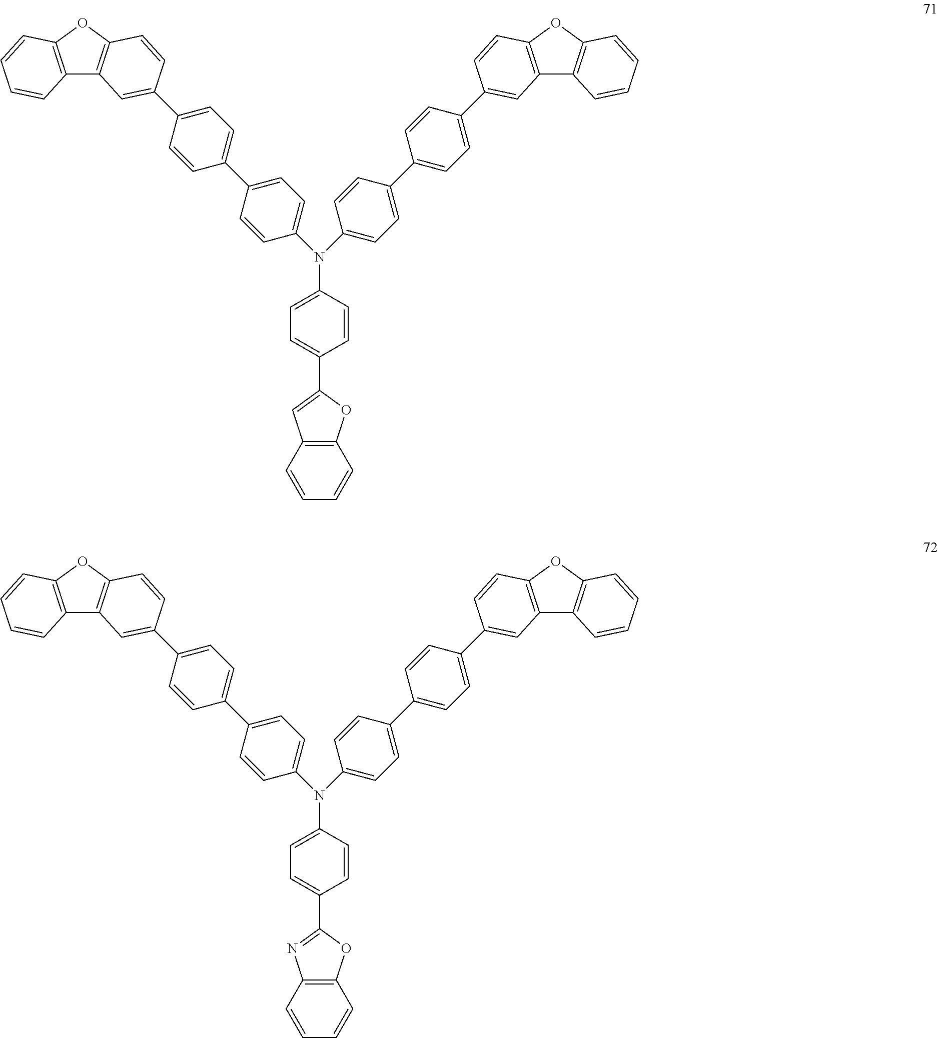 [SMILES: c1ccc2oc(-c3ccc(N(c4ccc(-c5ccc(-c6ccc7oc8ccccc8c7c6)cc5)cc4)c4ccc(-c5ccc(-c6ccc7oc8ccccc8c7c6)cc5)cc4)cc3)cc2c1 ; c1ccc2oc(-c3ccc(N(c4ccc(-c5ccc(-c6ccc7oc8ccccc8c7c6)cc5)cc4)c4ccc(-c5ccc(-c6ccc7oc8ccccc8c7c6)cc5)cc4)cc3)nc2c1]

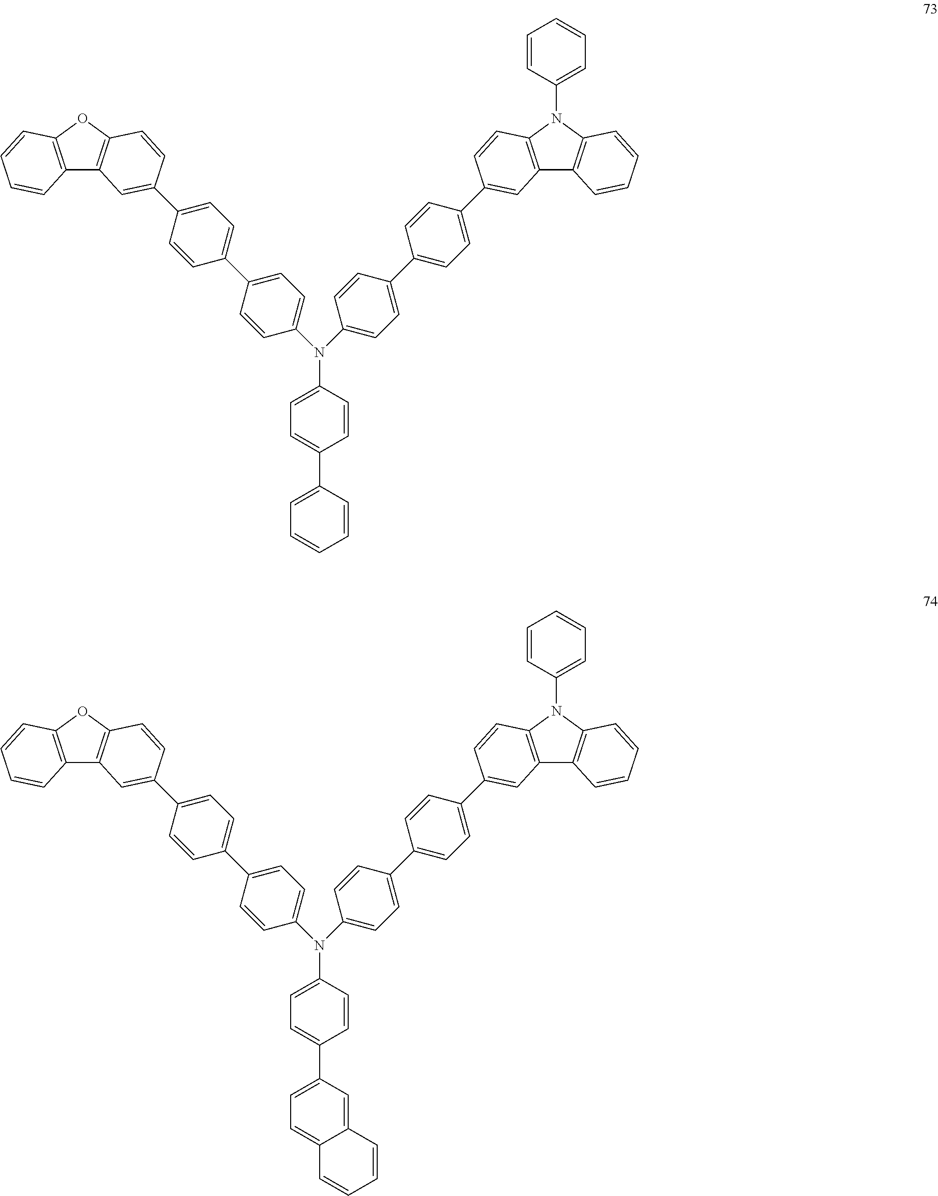 [SMILES: c1ccc(-c2ccc(N(c3ccc(-c4ccc(-c5ccc6oc7ccccc7c6c5)cc4)cc3)c3ccc(-c4ccc(-c5ccc6c(c5)c5ccccc5n6-c5ccccc5)cc4)cc3)cc2)cc1 ; c1ccc(-n2c3ccccc3c3cc(-c4ccc(-c5ccc(N(c6ccc(-c7ccc(-c8ccc9oc%10ccccc%10c9c8)cc7)cc6)c6ccc(-c7ccc8ccccc8c7)cc6)cc5)cc4)ccc32)cc1]

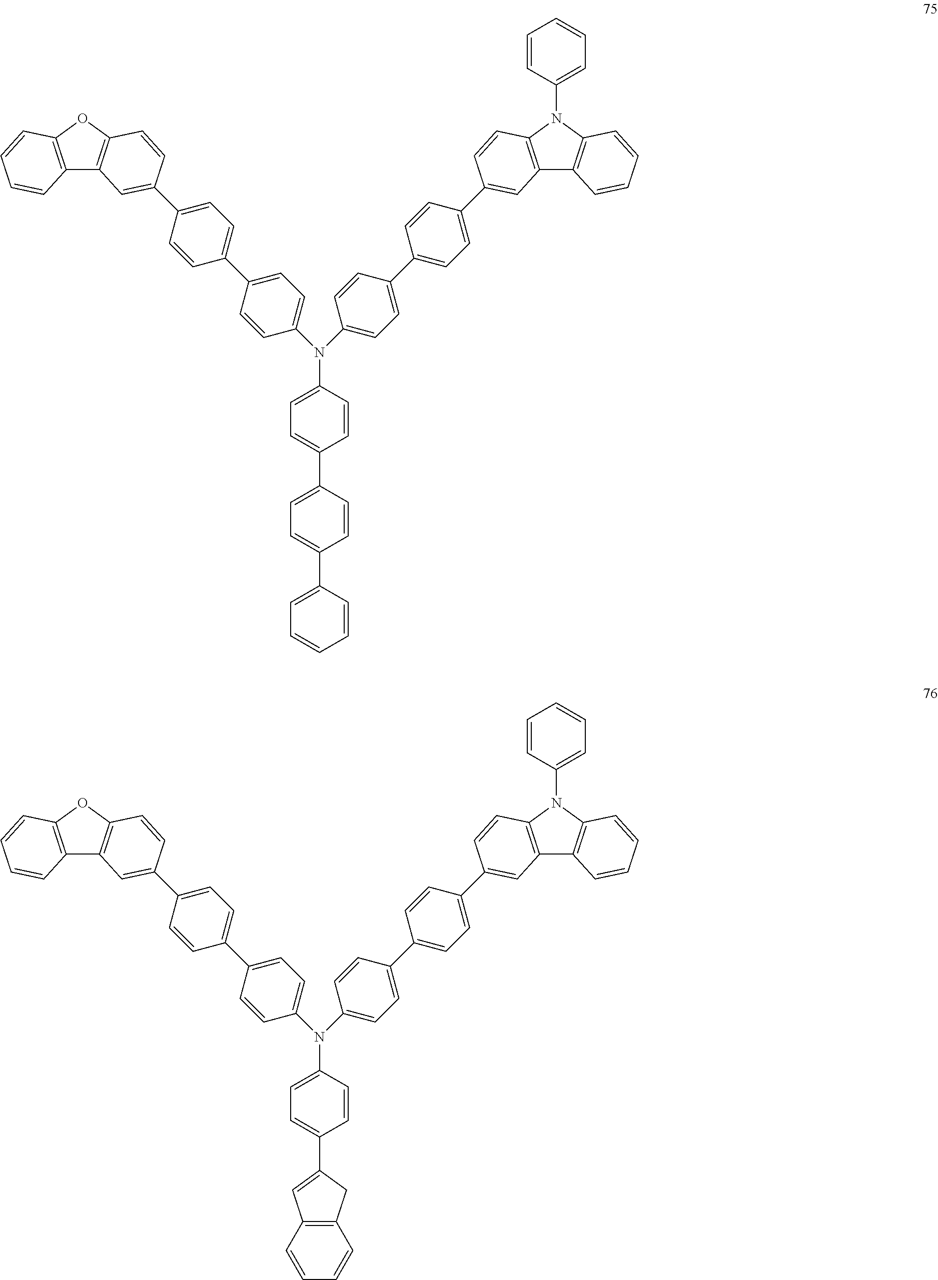 [SMILES: c1ccc(-c2ccc(-c3ccc(N(c4ccc(-c5ccc(-c6ccc7oc8ccccc8c7c6)cc5)cc4)c4ccc(-c5ccc(-c6ccc7c(c6)c6ccccc6n7-c6ccccc6)cc5)cc4)cc3)cc2)cc1 ; C1=C(c2ccc(N(c3ccc(-c4ccc(-c5ccc6oc7ccccc7c6c5)cc4)cc3)c3ccc(-c4ccc(-c5ccc6c(c5)c5ccccc5n6-c5ccccc5)cc4)cc3)cc2)Cc2ccccc21]

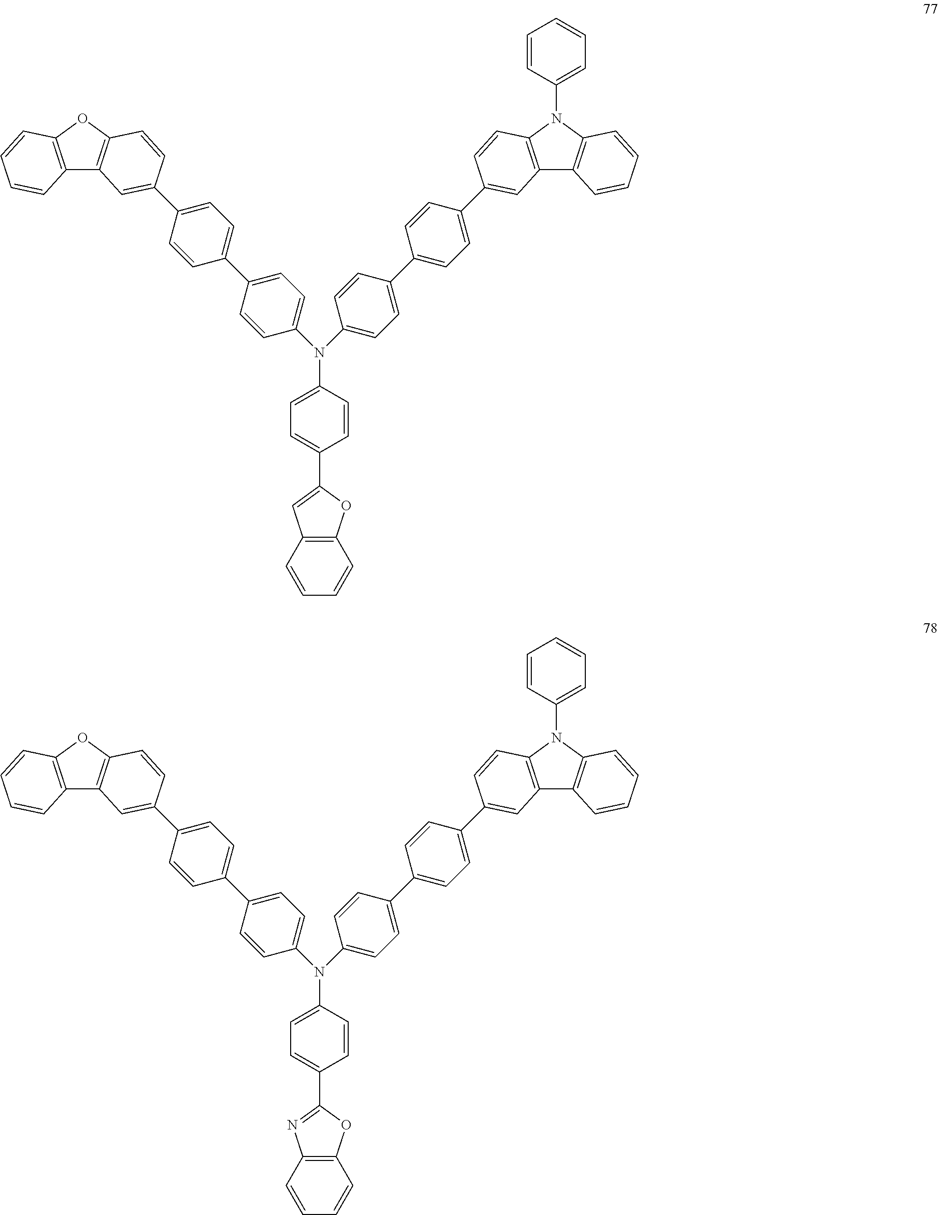 [SMILES: c1ccc(-n2c3ccccc3c3cc(-c4ccc(-c5ccc(N(c6ccc(-c7ccc(-c8ccc9oc%10ccccc%10c9c8)cc7)cc6)c6ccc(-c7cc8ccccc8o7)cc6)cc5)cc4)ccc32)cc1 ; c1ccc(-n2c3ccccc3c3cc(-c4ccc(-c5ccc(N(c6ccc(-c7ccc(-c8ccc9oc%10ccccc%10c9c8)cc7)cc6)c6ccc(-c7nc8ccccc8o7)cc6)cc5)cc4)ccc32)cc1]

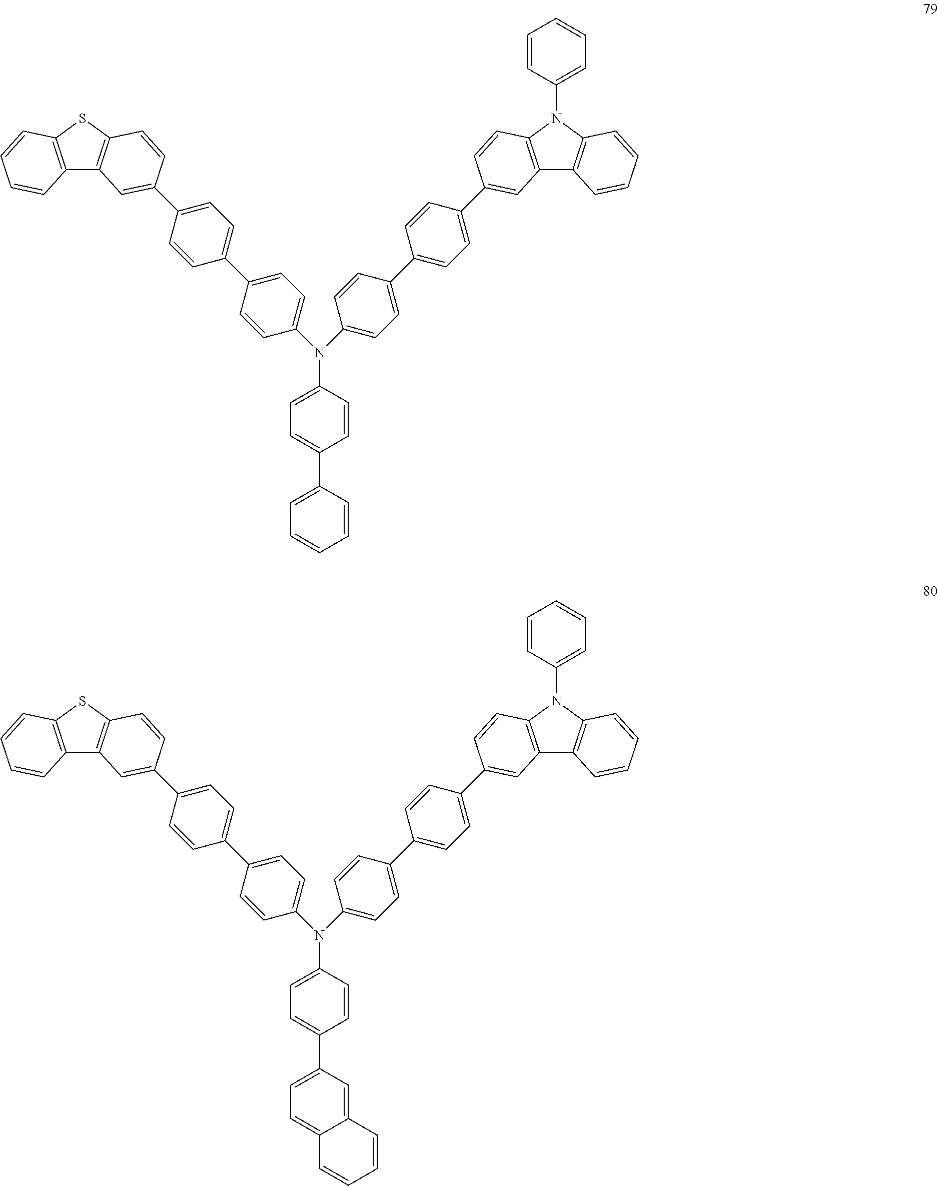 [SMILES: c1ccc(-c2ccc(N(c3ccc(-c4ccc(-c5ccc6sc7ccccc7c6c5)cc4)cc3)c3ccc(-c4ccc(-c5ccc6c(c5)c5ccccc5n6-c5ccccc5)cc4)cc3)cc2)cc1 ; c1ccc(-n2c3ccccc3c3cc(-c4ccc(-c5ccc(N(c6ccc(-c7ccc(-c8ccc9sc%10ccccc%10c9c8)cc7)cc6)c6ccc(-c7ccc8ccccc8c7)cc6)cc5)cc4)ccc32)cc1]

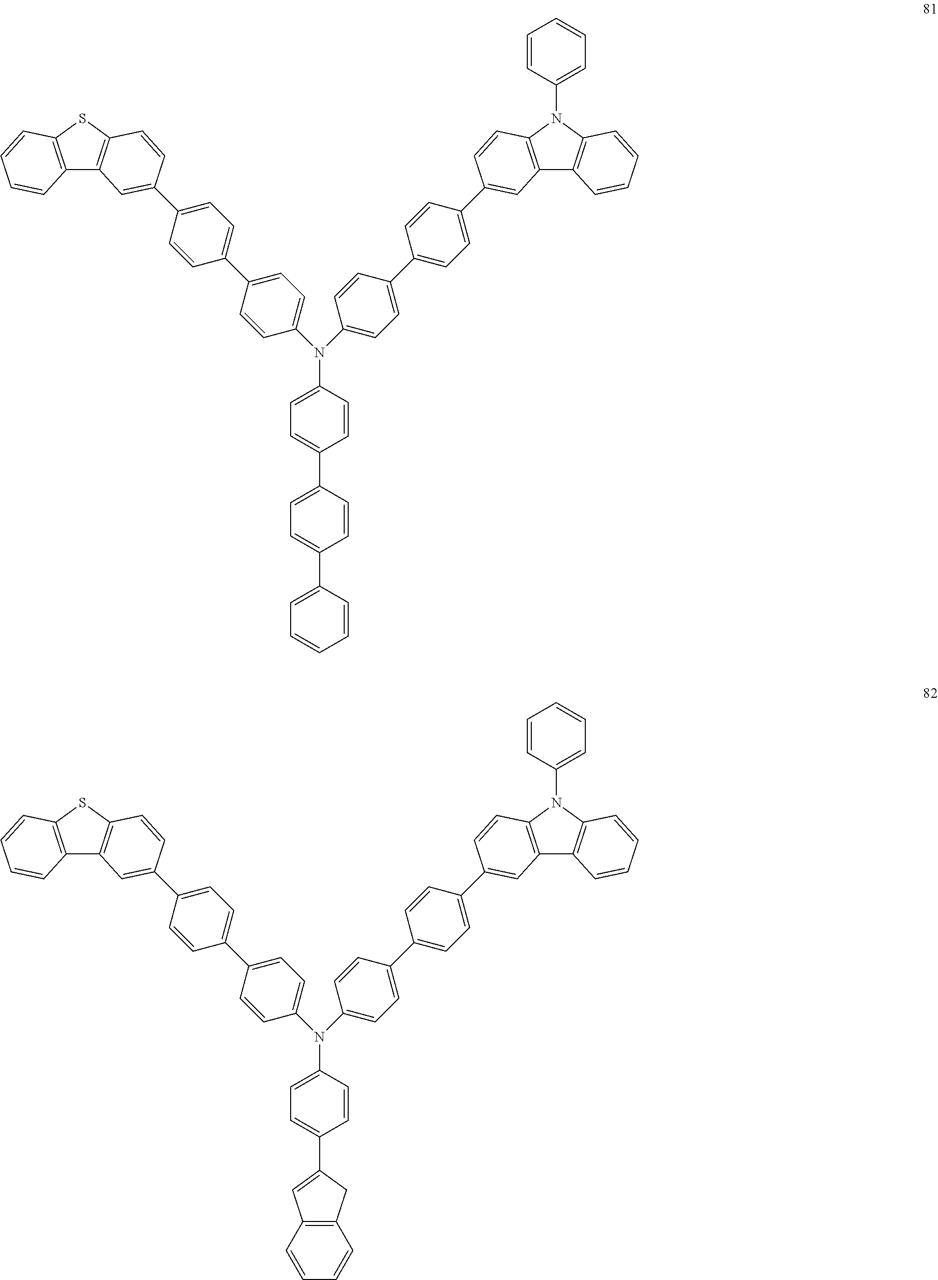 [SMILES: c1ccc(-c2ccc(-c3ccc(N(c4ccc(-c5ccc(-c6ccc7sc8ccccc8c7c6)cc5)cc4)c4ccc(-c5ccc(-c6ccc7c(c6)c6ccccc6n7-c6ccccc6)cc5)cc4)cc3)cc2)cc1 ; C1=C(c2ccc(N(c3ccc(-c4ccc(-c5ccc6sc7ccccc7c6c5)cc4)cc3)c3ccc(-c4ccc(-c5ccc6c(c5)c5ccccc5n6-c5ccccc5)cc4)cc3)cc2)Cc2ccccc21]

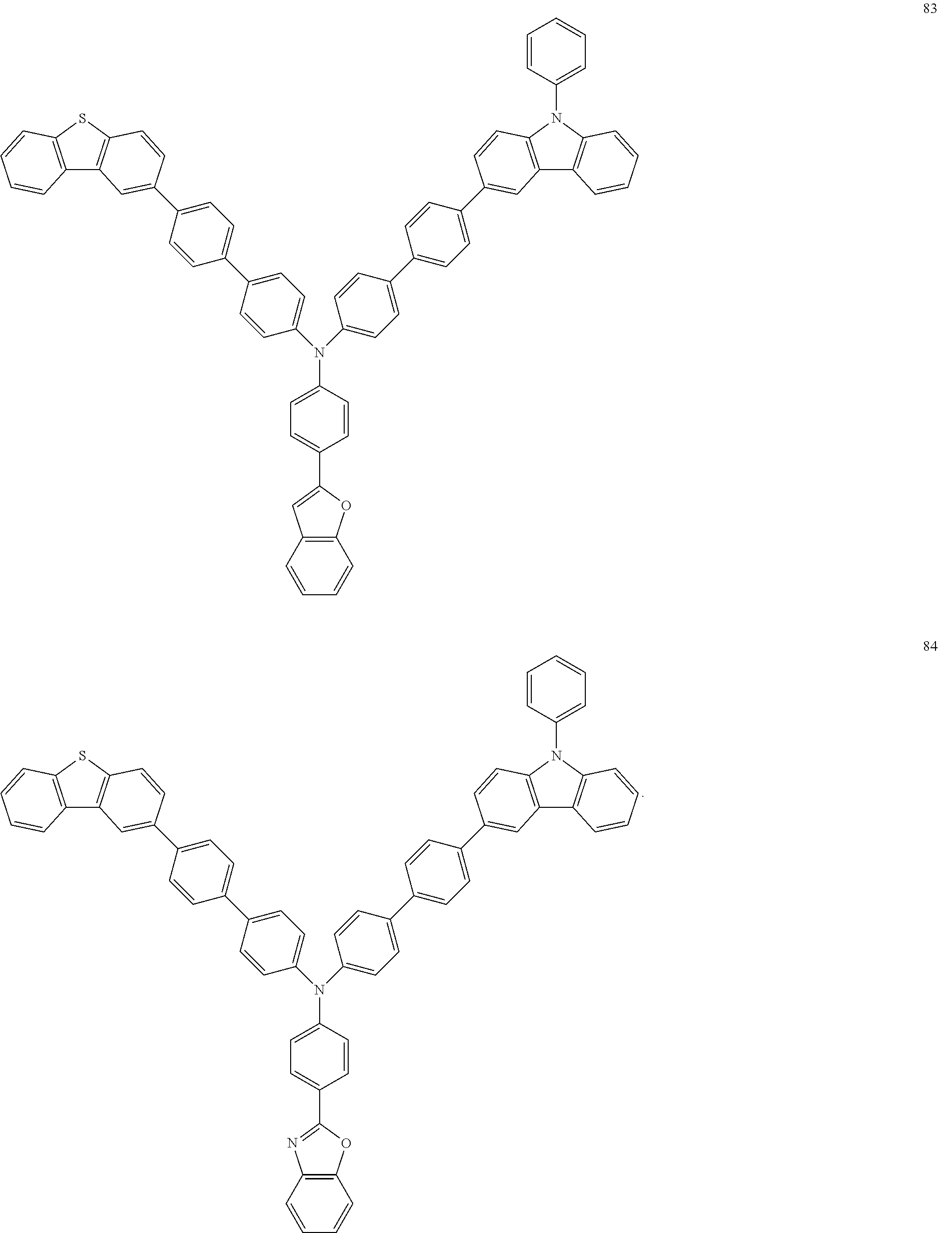 [SMILES: c1ccc(-n2c3ccccc3c3cc(-c4ccc(-c5ccc(N(c6ccc(-c7ccc(-c8ccc9sc%10ccccc%10c9c8)cc7)cc6)c6ccc(-c7cc8ccccc8o7)cc6)cc5)cc4)ccc32)cc1 ; c1ccc(-n2c3ccccc3c3cc(-c4ccc(-c5ccc(N(c6ccc(-c7ccc(-c8ccc9sc%10ccccc%10c9c8)cc7)cc6)c6ccc(-c7nc8ccccc8o7)cc6)cc5)cc4)ccc32)cc1]

In an embodiment, the refractive index of the compound may be in a range of about 2.2 and about 3.0. In an embodiment, the refractive index may be in a range of about 2.2 and about 2.5, but embodiments are not limited thereto. The refractive index may be a value measured at about 460 nm, and a method of measuring the refractive index may be the same as described in the specification.

In an embodiment, the organic photodetector may also include: a hole transport region arranged between the first electrode and the auxiliary layer; and an electron transport region arranged between the activation layer and the second electrode,

the hole transport region may include a hole injection layer, a hole transport layer, or an electron blocking layer, and

the electron transport region may include a buffer layer, a hole blocking layer, an electron transport layer, or an electron injection layer.

In an embodiment, the hole transport region in the organic photodetector may include the hole transport layer.

In an embodiment, a thickness of the hole transport layer may be in a range of about 80 nm and about 150 nm.

In an embodiment, the hole transport layer may be in contact (e.g., directly contact) with the auxiliary layer.

In an embodiment, the activation layer in the organic photodetector may be in contact (e.g., directly contact) with the auxiliary layer,

the hole transport layer may be arranged between the first electrode and the auxiliary layer, and the hole transport layer may be in contact (e.g., directly contact) with the auxiliary layer.

According to embodiments, provided is an electronic apparatus that may include the organic photodetector according to the specification.

In an embodiment, the electronic apparatus may also include a light-emitting device.

According to embodiments, provided is an electronic apparatus that may include:

a substrate including a light detection region and an emission region;

an organic photodetector arranged on the light detection region; and

a light-emitting device arranged on the emission region,

wherein the organic photodetector may include a first pixel electrode and a counter electrode facing the first pixel electrode. The organic photodetector may also include a first common layer, an auxiliary layer, an activation layer, and a second common layer, which may be sequentially arranged between the first pixel electrode and the counter electrode,

the light-emitting device may include a second pixel electrode and the counter electrode facing the second pixel electrode. The light-emitting device may also include the first common layer, an emission layer, and the second common layer, which may be sequentially arranged between the second pixel electrode and the counter electrode,

the first pixel electrode, the auxiliary layer, and the activation layer may be arranged in the light detection region,

the second pixel electrode and the emission layer may be arranged in the emission region, and

the first common layer, the second common layer, and the counter electrode may be arranged throughout the light detection region and the emission region.

In an embodiment, the counter electrode facing the first pixel electrode may be a first counter electrode, the counter electrode facing the second pixel electrode may be a second counter electrode, and the first counter electrode and the second counter electrode, as common layers, may be arranged throughout the light detection region and the emission region.

In an embodiment, the first common layer in the electronic apparatus may include a hole transport layer.

The organic photodetector may be implemented in the same device as the light-emitting device, and may use the activation layer instead of the emission layer in the light-emitting device. Therefore, since the organic photodetector and the light-emitting device use the same common layer (for example, a hole transport region, a hole injection layer, and/or a hole transport layer), there may be a limitation. Accordingly, in order to obtain optimal external quantum efficiency (optimal EQE) in the organic photodetector, it is necessary to adjust a thickness and resonance of the activation layer.

The organic photodetector may include an auxiliary layer arranged between the first electrode and the activation layer, and the auxiliary layer may include a compound having a refractive index of about 2.2 or more. Accordingly, since an optical distance that varies according to resonance may be compensated, the EQE of the organic photodetector may be improved. For example, in a case where the auxiliary layer does not include a compound having a refractive index of about 2.2 or more, it may be difficult to compensate an optical distance according to resonance, and the EQE may decrease.

Also, in case that the organic photodetector also includes a hole transport layer between the first electrode and the auxiliary layer, the auxiliary layer may be arranged between the hole transport layer and the activation layer, and thus, regardless of a thickness of the hole transport layer, an optical distance may be compensated by the auxiliary layer, such that the EQE of the organic photodetector may be further improved.

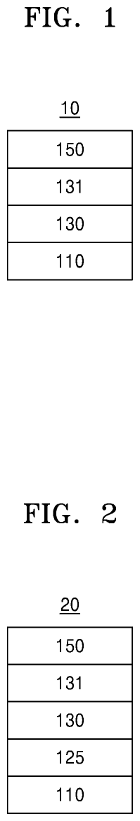

Therefore, in the electronic apparatus including the organic photodetector arranged on the light detection region and the light-emitting device arranged on the emission region, because the EQE of the organic photodetector is improved, characteristics of the photodetector may be improved, and because the light-emitting device does not include the auxiliary layer, and a thickness of the common layer (for example, a hole transport region, a hole injection layer, and/or a hole injection layer) that is commonly included in the organic photodetector and the light-emitting device is not changed, luminescence efficiency may be improved, and thus, the organic photodetector may be used to manufacture high-quality electronic apparatuses.

[Descriptions of FIGS. 1 and 2]

FIG. 1 is a schematic cross-sectional view of an organic photodetector 10 according to an embodiment.

Referring to FIG. 1, the organic photodetector 10 according to an embodiment may include a first electrode 110, a second electrode 150 facing the first electrode 110, an activation layer 131 arranged between the first electrode 110 and the second electrode 150, and an auxiliary layer 130 arranged between the first electrode 110 and the activation layer 131, and the auxiliary layer 130 may include a compound having a refractive index of about 2.2 or more.

One of the first electrode 110 and the second electrode 150 may be an anode, and the other one may be a cathode. In an embodiment, the first electrode 110 may be an anode, and the second electrode 150 may be a cathode.

FIG. 2 schematically shows a cross-sectional view of an organic photodetector 20 according to an embodiment.

Referring to FIG. 2, a hole transport layer 125 may be arranged between the first electrode 110 and the auxiliary layer 130. The hole transport layer may be the same as described in the specification.

In an embodiment, the activation layer 131 and the auxiliary layer 130 may be in contact (e.g., directly contact) with each other, and the auxiliary layer 130 and the hole transport layer 125 may be in contact (e.g., directly contact) with each other.

Although not shown in FIGS. 1 and 2, the photodetectors 10 and 20 may each include: a hole transport region arranged between the first electrode and the auxiliary layer; and an electron transport region arranged between the activation layer and the second electrode, wherein the hole transport region may include a hole injection layer, the hole transport layer 125, an electron blocking layer, or any combination thereof, and the electron transport region may include a buffer layer, a hole blocking layer, an electron transport layer, an electron injection layer, or any combination thereof.

In case that a reverse bias applied to the organic photodetector increases, a response rate may increase, whereas a dark current may increase, and thus, noise of the organic photodetector may increase. Accordingly, it may be difficult to ensure a high EQE and a low dark current at the same time by using an organic photodetector in the related art. However, in the organic photodetectors 10 and 20 according to an embodiment, the auxiliary layer 130 may be arranged between the first electrode and the activation layer, and thus, each of the organic photodetectors 10 and 20 may exhibit a low dark current and may have increased EQE at the same time, thereby having excellent light detection characteristics.

A dark current density of the organic photodetectors 10 and 20 according to an embodiment may be about 5×10⁻⁶ milliamperes per square centimeter (mA/cm²) or lower at a reverse bias of about −3 volts (V). For example, in case of applying a reverse bias, reverse injection of charges from an electrode to an activation layer may be prevented, and a low dark current and a high light detection efficiency may be maintained.

[First Electrode 110]

In FIGS. 1 and 2, a substrate may be additionally located under the first electrode 110 or above the second electrode 150. For the substrate, a glass substrate or a plastic substrate may be used. In an embodiment, the substrate may be a flexible substrate, and may include plastics with excellent heat resistance and durability, such as polyimide, polyethylene terephthalate (PET), polycarbonate, polyethylene napthalate, polyarylate (PAR), polyetherimide, or any combination thereof.

The first electrode 110 may be formed by, for example, depositing or sputtering a material for forming the first electrode 110 on the substrate. In case that the first electrode 110 is an anode, a material for forming the first electrode 110 may be a high work function material.

The first electrode 110 may be a reflective electrode, a semi-transmissive electrode, or a transmissive electrode. In case that the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In an embodiment, in case that the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used as a material for forming the first electrode 110.

The first electrode 110 may have a single-layered structure consisting of a single layer or a multilayer structure including multiple layers. In an embodiment, the first electrode 110 may have a three-layered structure of ITO/Ag/ITO.

[Charge Auxiliary Layer]

The organic photodetectors 10 and 20 according to an embodiment may each include a charge auxiliary layer that facilitates migration of holes and electrons separated from the activation layer 131. The charge auxiliary layer may include a hole injection layer and the hole transport layer 125, which facilitate migration of holes, and may include an electron transport layer and an electron injection layer, which facilitate migration of electrons.

[Hole Transport Region]

Charge auxiliary layers located between the first electrode 110 and the activation layer 131 may be collectively referred to as a hole transport region.

The hole transport region may also include, in addition to the hole transport layer 125, a hole injection layer and/or an electron blocking layer.

The hole transport region may include a hole transport material. In an embodiment, the hole transport material may include a compound represented by Formula 201 below, a compound represented by Formula 202 below, or any combination thereof:

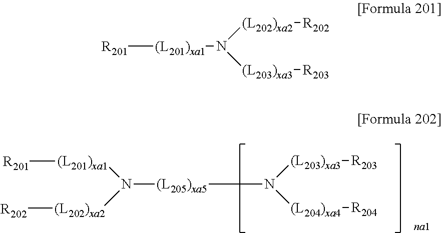

wherein, in Formulae 201 and 202,

L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,

L₂₀₅ may be *—O—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group that is unsubstituted or substituted with at least one R₁₀ₐ, or a C₁-C₆₀ heterocyclic group that is unsubstituted or substituted with at least one R₁₀ₐ,

R₂₀₁ and R₂₀₂ may optionally be linked to each other, via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group (for example, a carbazole group or the like) unsubstituted or substituted with at least one R₁₀ₐ (for example, Compound HT16),

R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group that is unsubstituted or substituted with at least one R₁₀ₐ, and

na1 may be an integer from 1 to 4.

In an embodiment, each of Formulae 201 and 202 may include at least one of groups represented by Formulae CY201 to CY217:

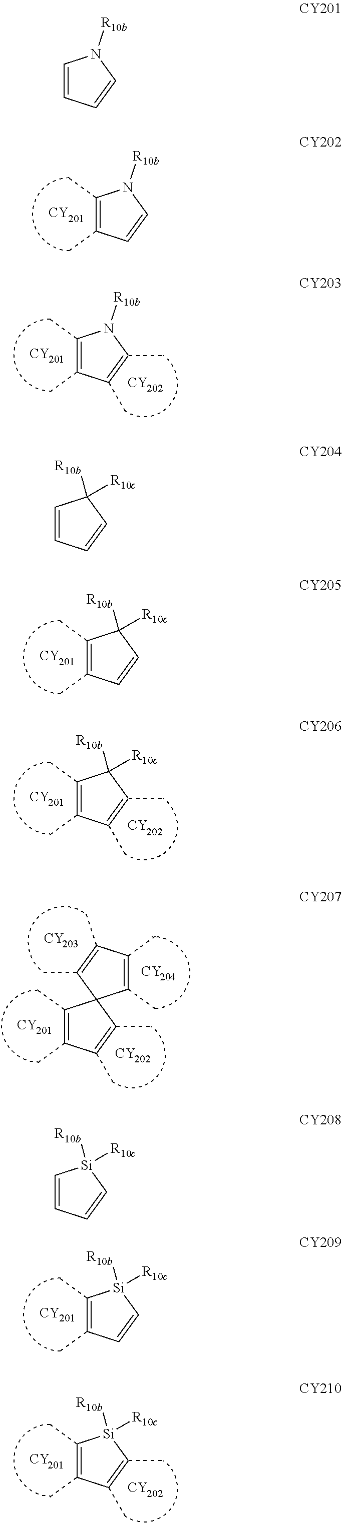

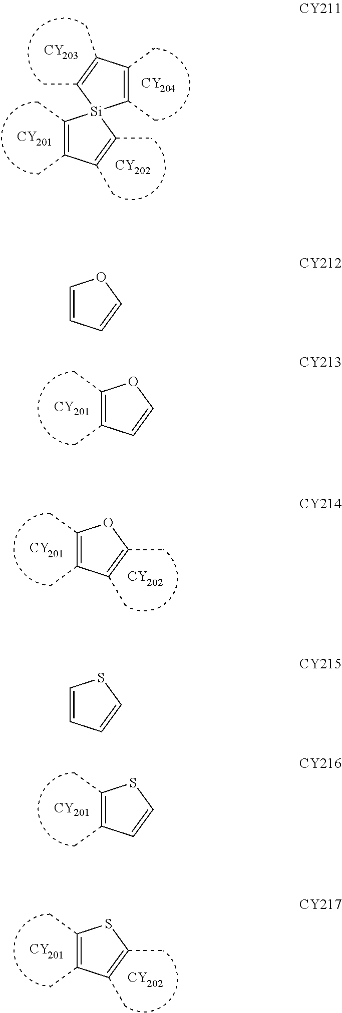

wherein in Formulae CY201 to CY217, R_{10b} and R_{10c} may each be the same as described with respect to R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, each of Formulae 201 and 202 may include at least one of groups represented by Formulae CY201 to CY203.

In an embodiment, Formula 201 may include at least one of groups represented by Formulae CY201 to CY203 and at least one of groups represented by Formulae CY204 to CY217.

In an embodiment, xa1 in Formula 201 may be 1, R₂₀₁ may be a group represented by one of Formulae CY201 to CY203, xa2 may be 0, and R₂₀₂ may be a group represented by one of Formulae CY204 to CY207.

In an embodiment, each of Formulae 201 and 202 may not include groups represented by Formulae CY201 to CY203.

In an embodiment, each of Formulae 201 and 202 may not include groups represented by Formulae CY201 to CY203, and may include at least one of groups represented by Formulae CY204 to CY217.

In an embodiment, each of Formulae 201 and 202 may not include groups represented by Formulae CY201 to CY217.

In an embodiment, the hole transport material may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

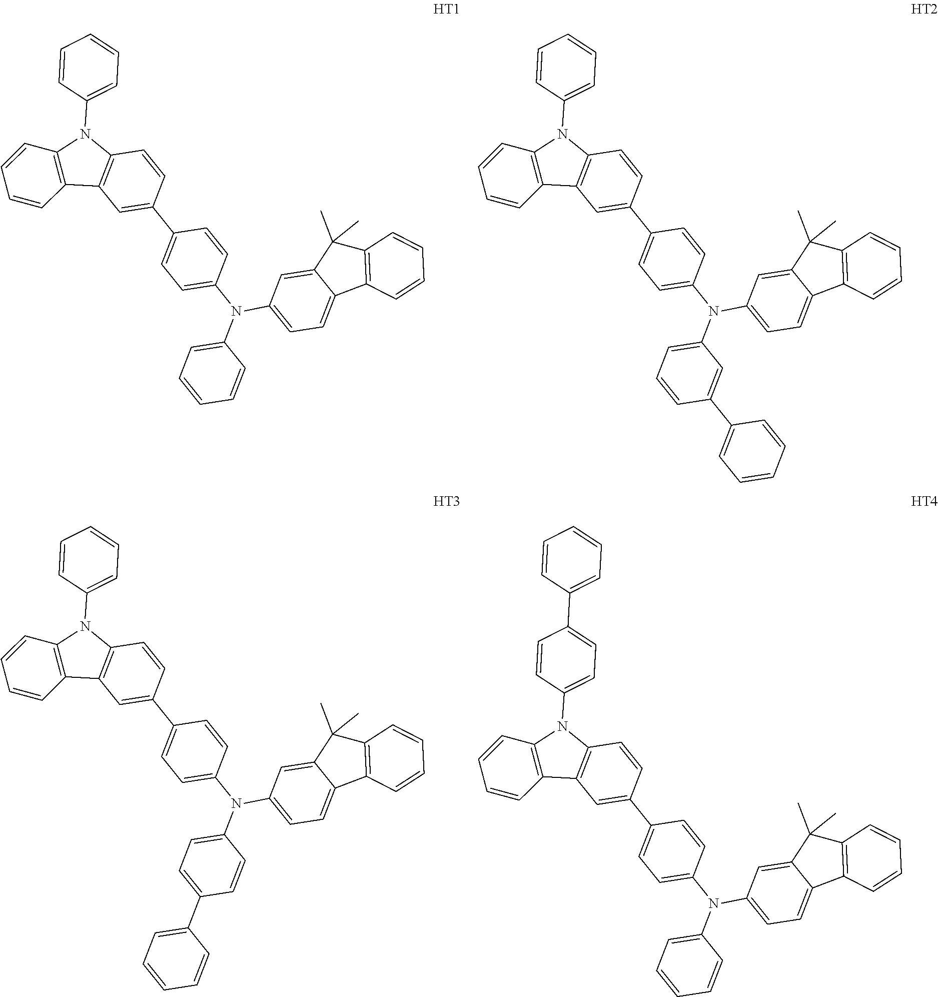 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

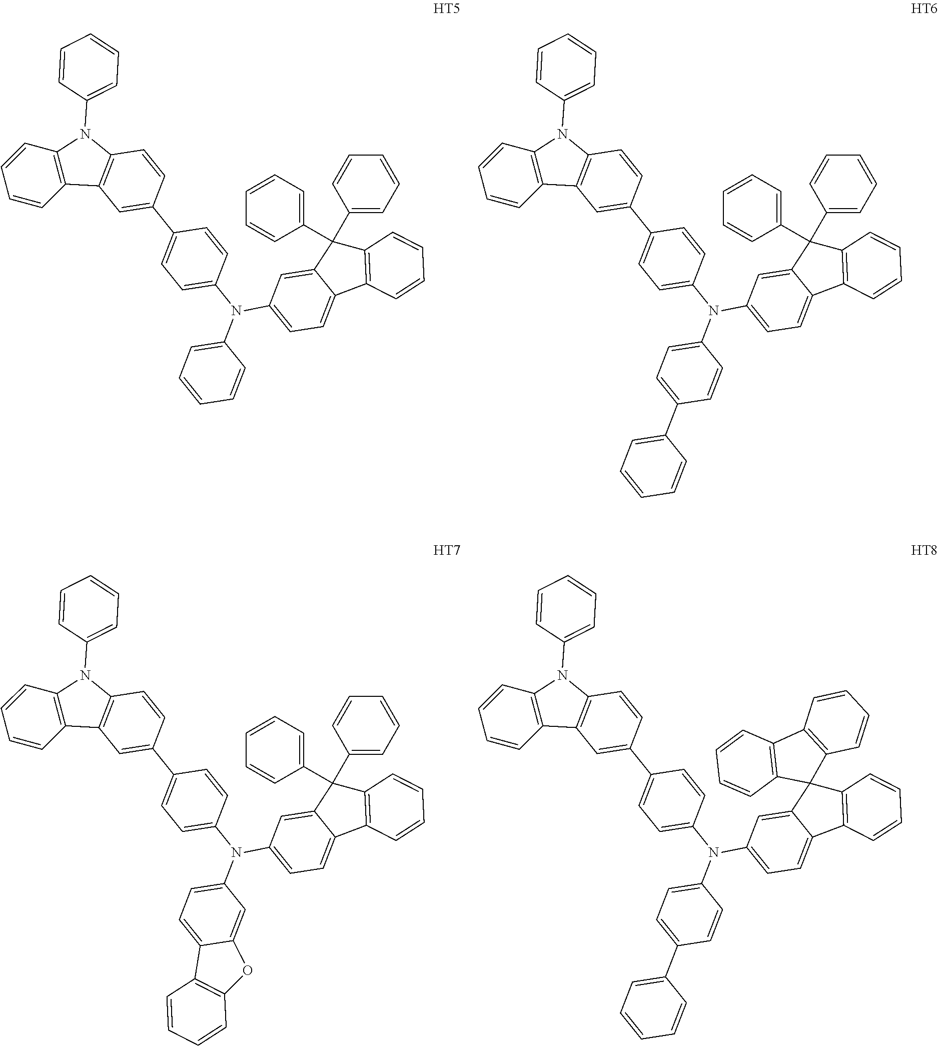 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

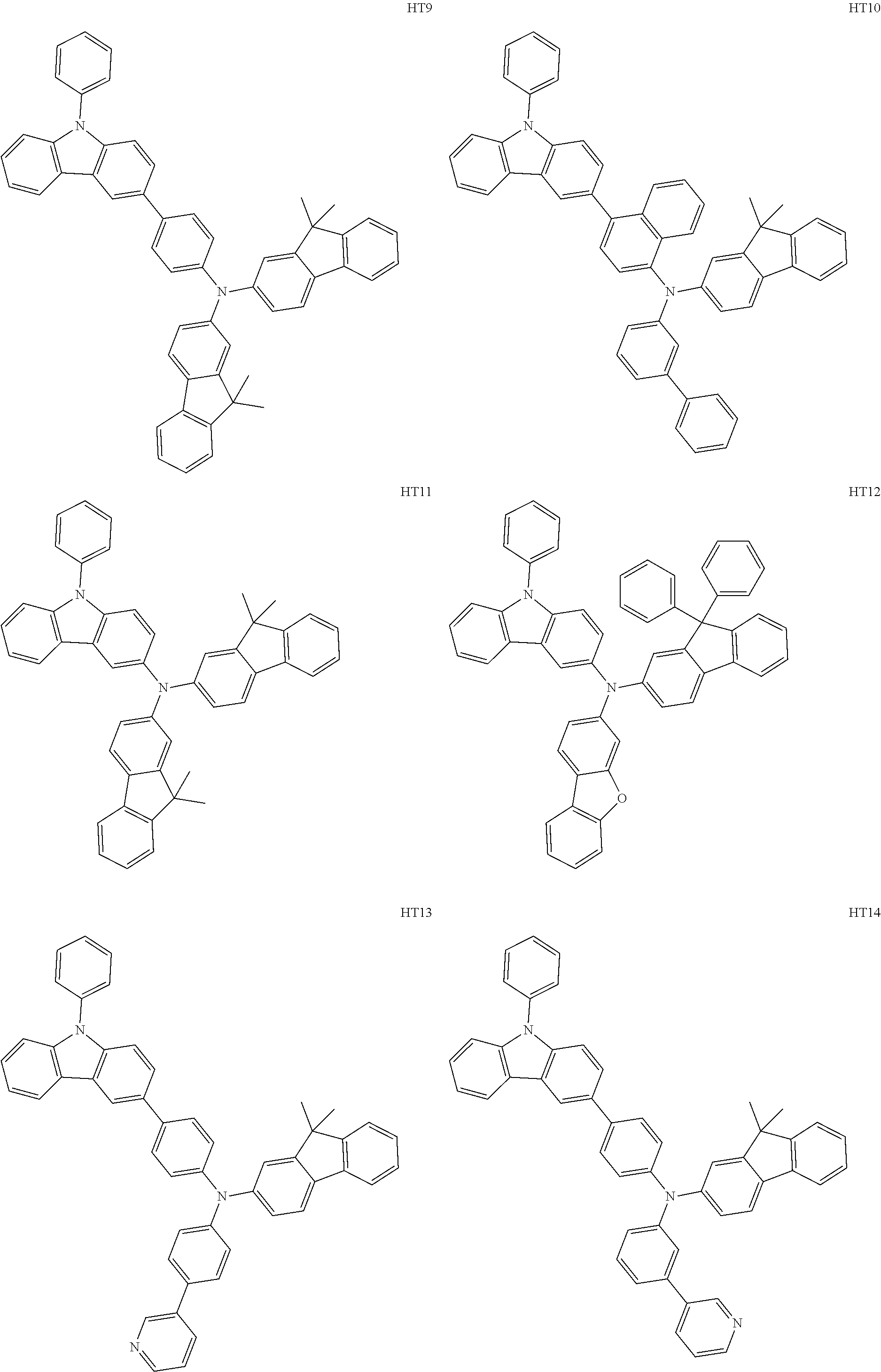

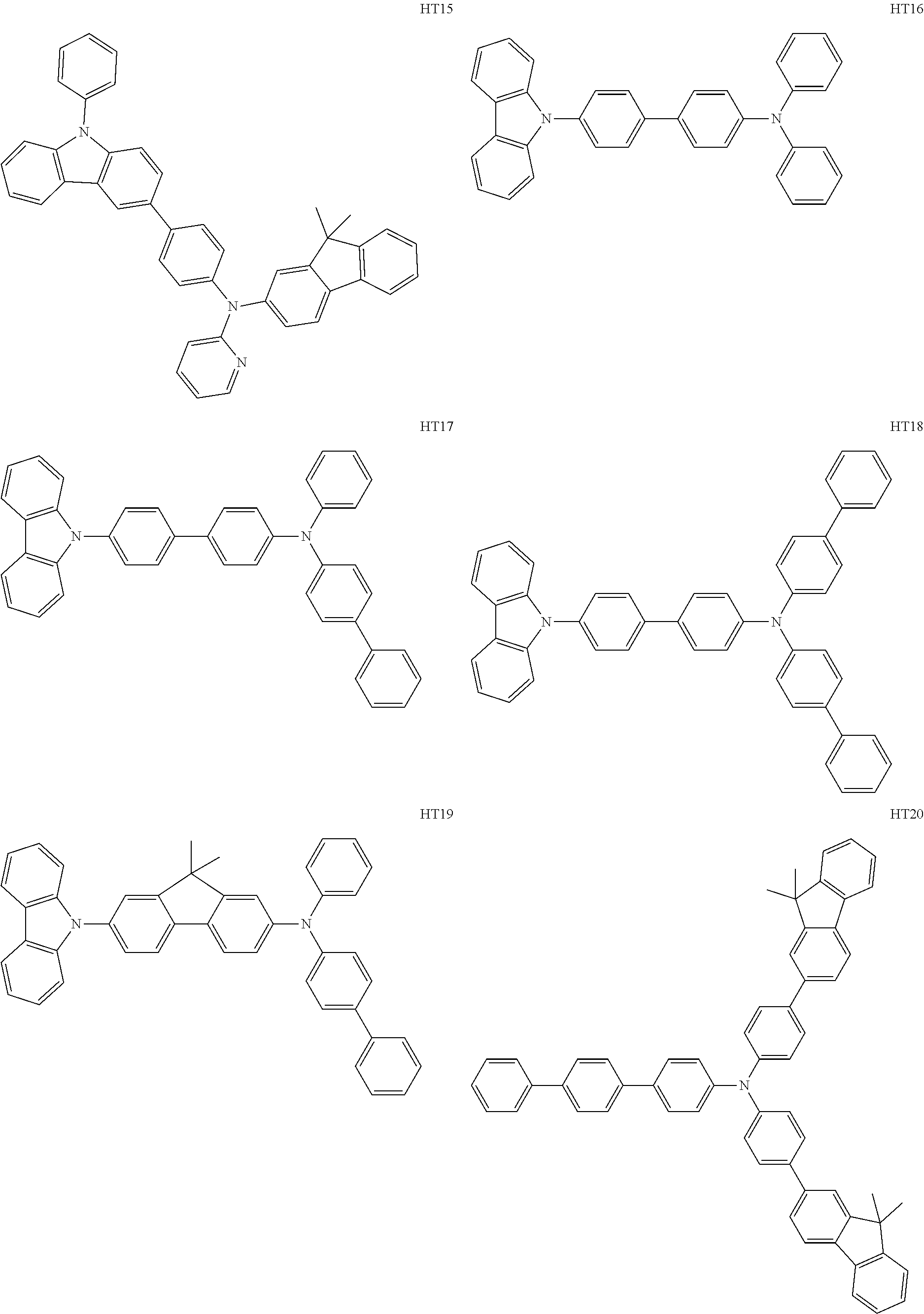 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

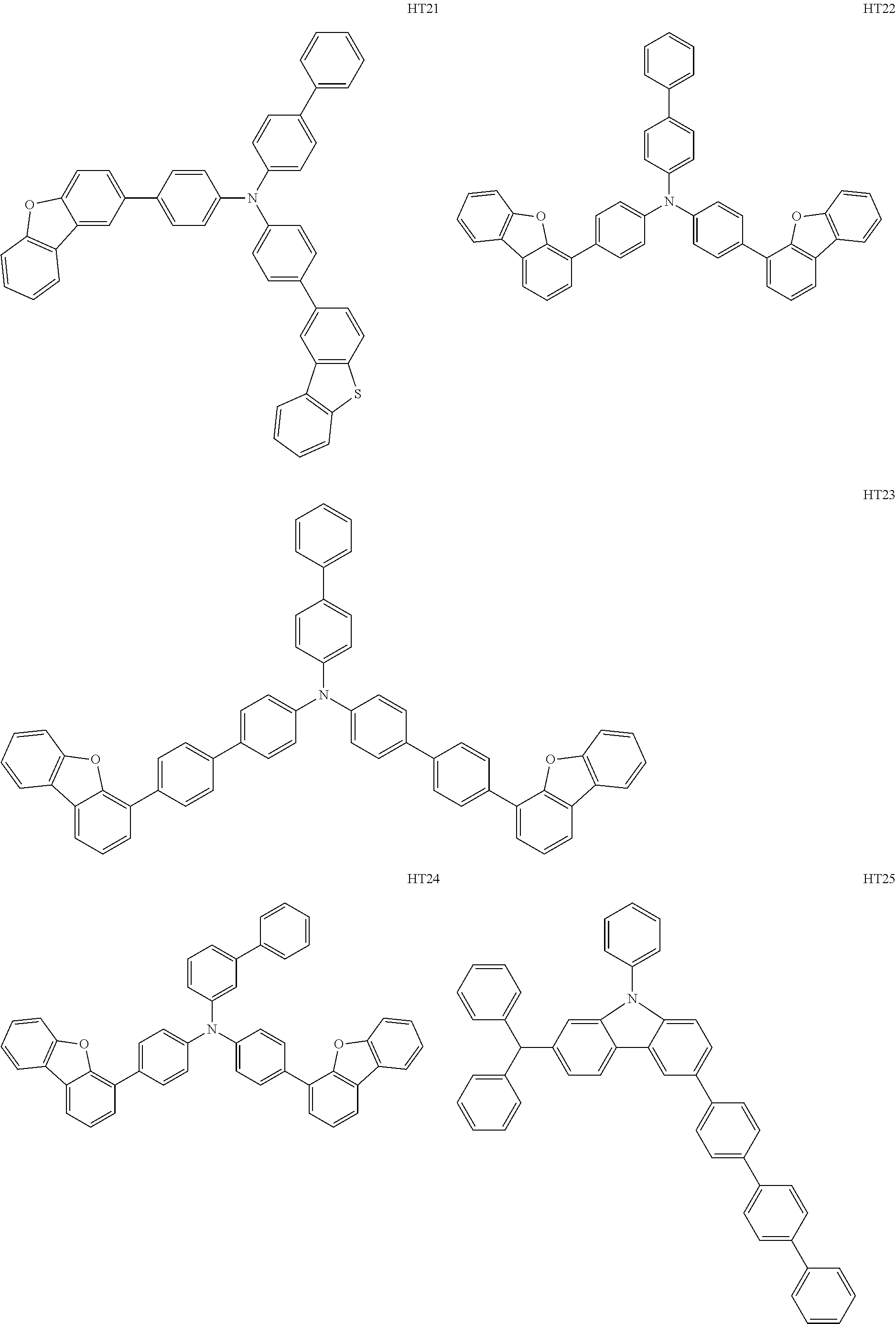 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(C(c6ccccc6)c6ccccc6)cc4n5-c4ccccc4)cc3)cc2)cc1]

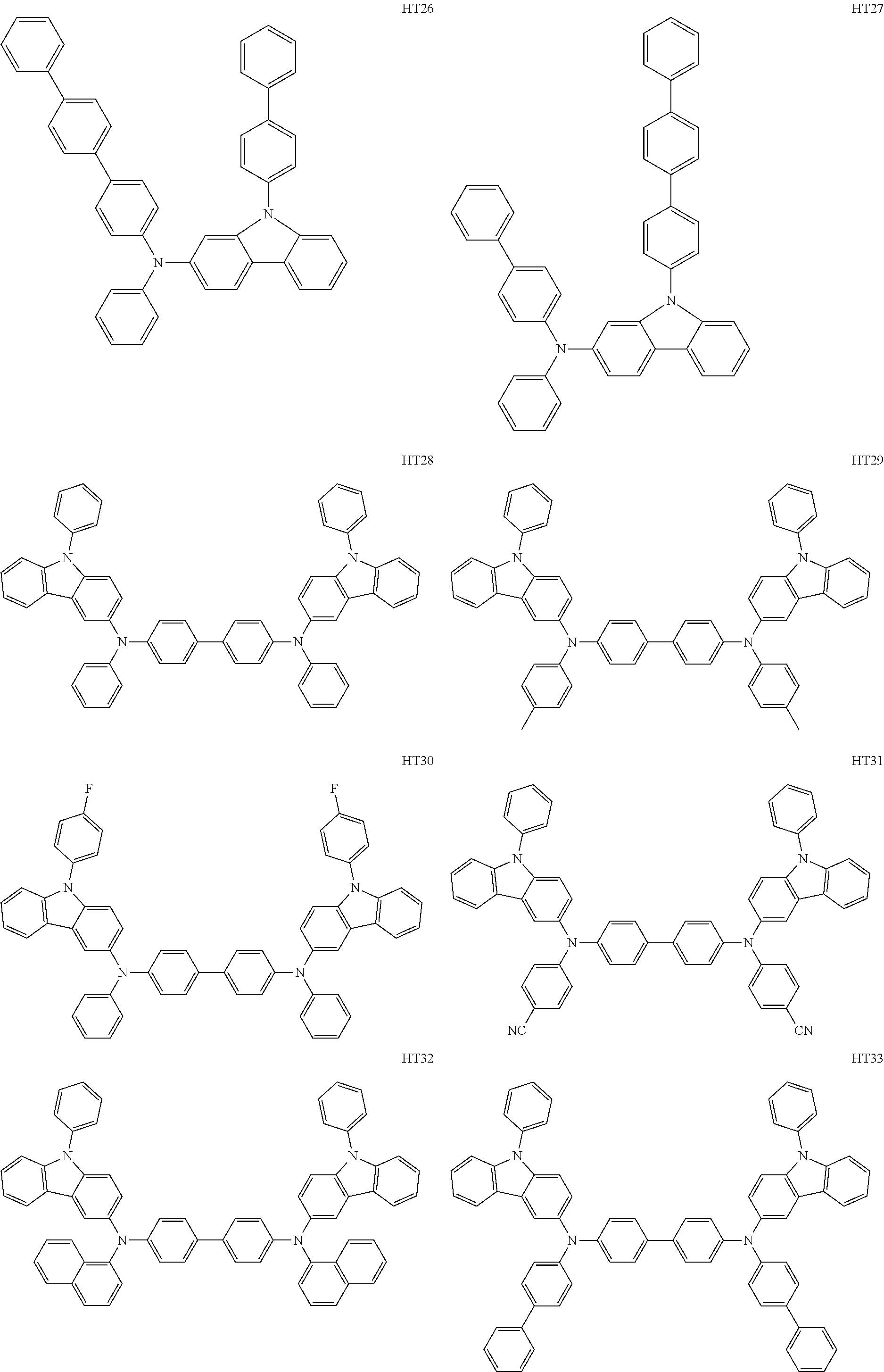

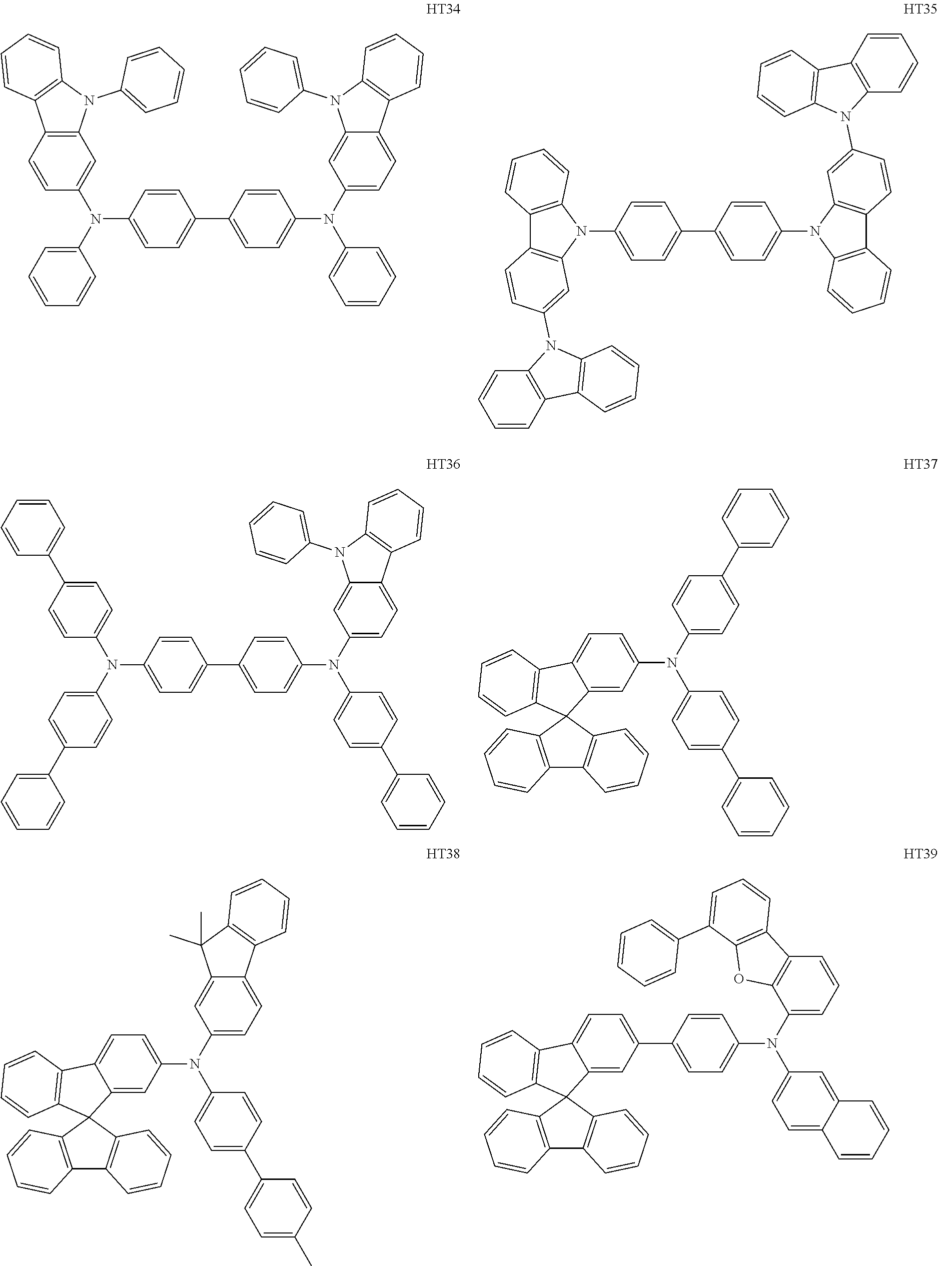

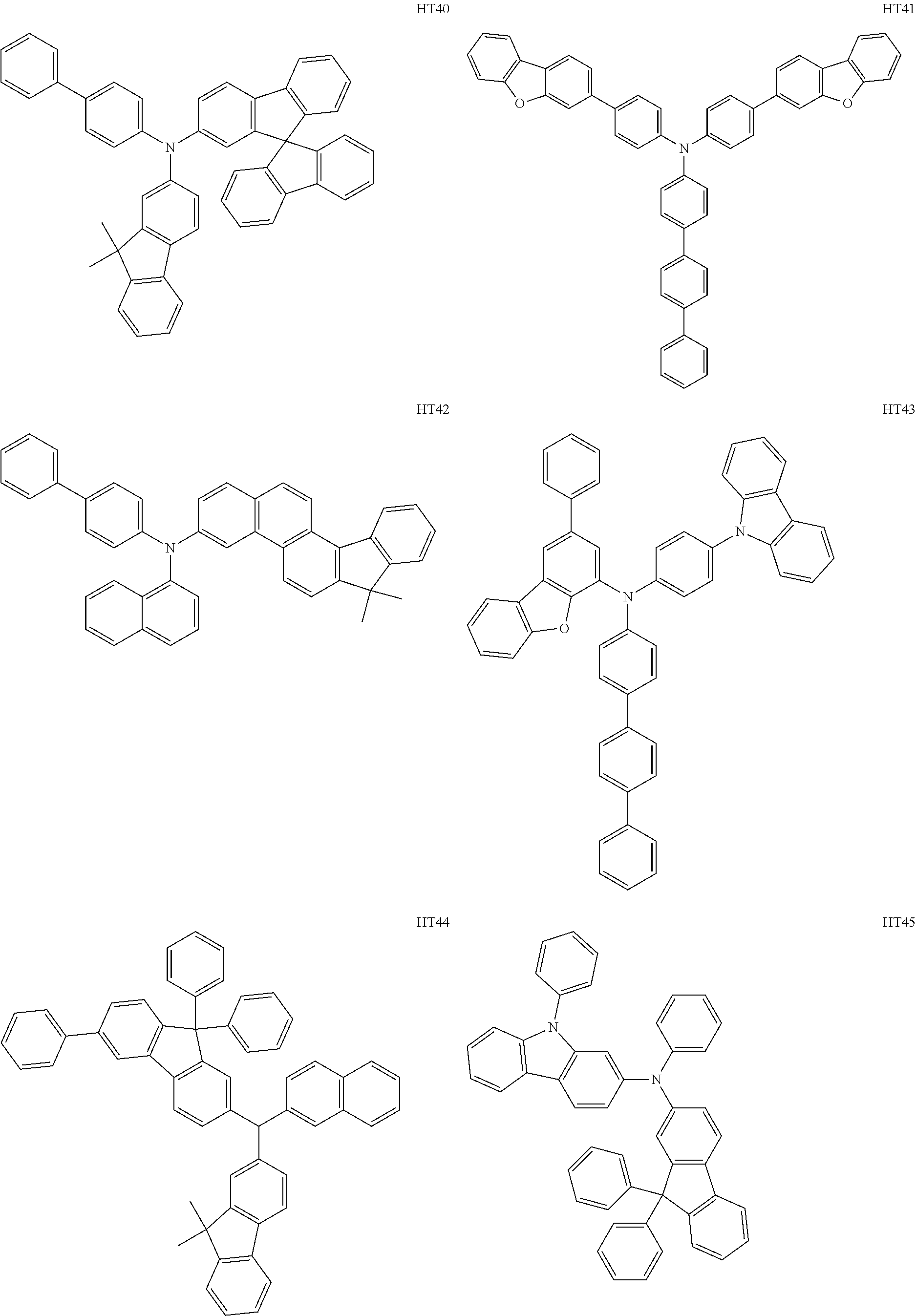

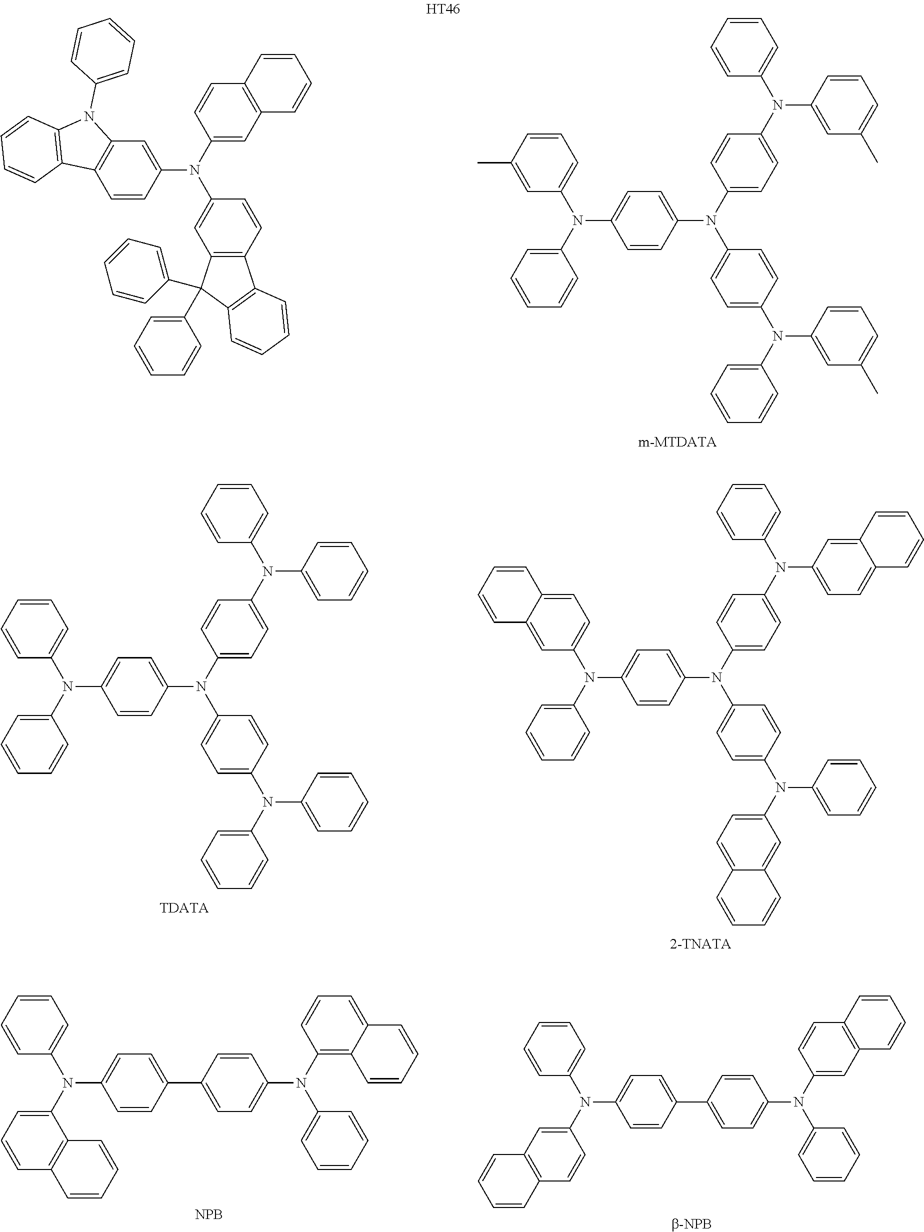

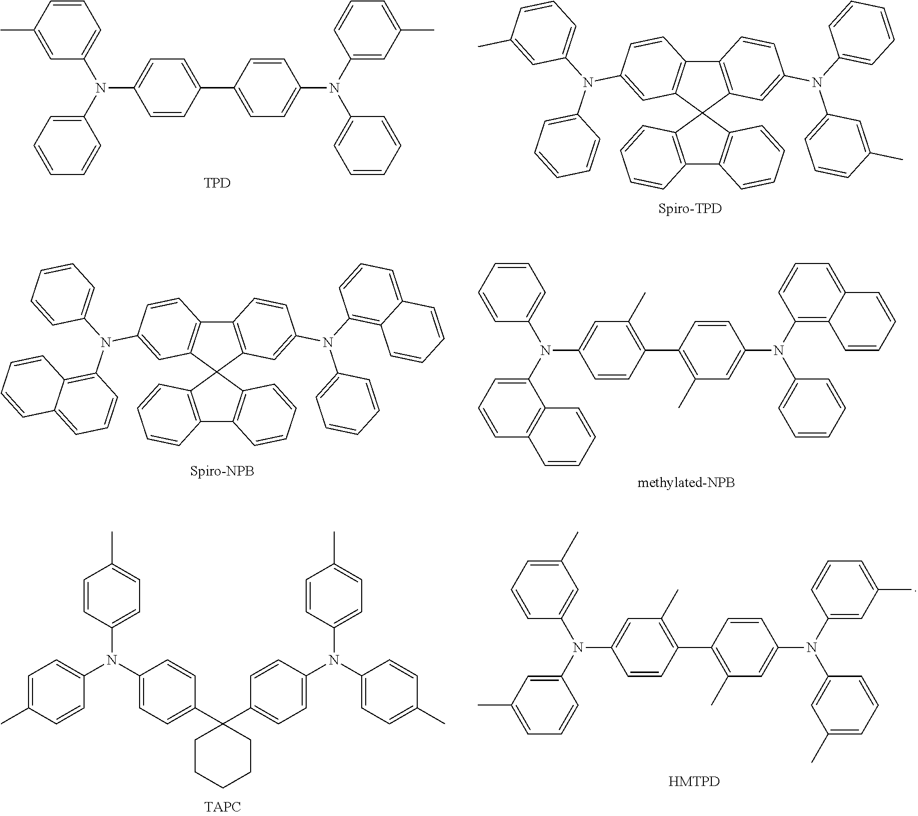

A thickness of the hole transport region may be in a range of about 50 Å to about 10,000 Å, for example, about 100 Å to about 4,000 Å. In case that the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer 125 may be in a range of about 100 Å to about 1,500 Å, for example, about 1,000 Å to about 2,050 Å, about 1,250 Å to about 2,050 Å, or about 800 Å to about 1,500 Å. In case that thicknesses of the hole transport region, the hole injection layer, and the hole transport layer 125 are within these ranges, satisfactory hole transporting characteristics may be obtained without a substantial increase in driving voltage.

The electron blocking layer may be a layer that prevents electron leakage from the activation layer 131 to the hole transport region. The hole transport material may be included in the electron blocking layer.

[p-Dopant]

The hole transport region may also include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

In an embodiment, a LUMO energy level of the p-dopant may be about −3.5 eV or less.

In an embodiment, the p-dopant may include a quinone derivative, a cyano group-containing compound, a compound containing element EL1 and element EL2, or any combination thereof.

Examples of the quinone derivative may include TCNQ, F4-TCNQ, and the like.

Examples of the cyano group-containing compound may include HAT-CN, a compound represented by Formula 221 below, and the like.

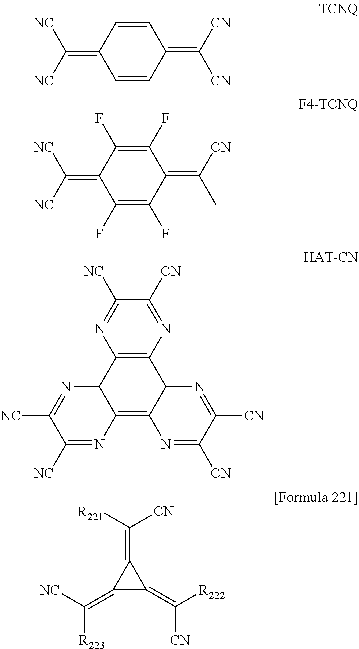

In Formula 221,

R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and

at least one of R₂₂₁ to R₂₂₃ may be a C₃-C₆₀ carbocyclic group or a C₁-C₆₀ heterocyclic group, substituted with: a cyano group; —F; —CI; —Br; —I; a C₁-C₂₀ alkyl group substituted with a cyano group, —F, —Cl, —Br, —I, or any combination thereof; or any combination thereof.

In the compound containing element EU and element EL2, element EL1 may be metal, metalloid, or a combination thereof, and element EL2 may be non-metal, metalloid, or a combination thereof.

Examples of the metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid may include silicon (Si), antimony (Sb), and tellurium (Te).

Examples of the non-metal may include oxygen (O) and halogen (for example, F, Cl, Br, I, etc.).

In an embodiment, examples of the compound containing element EL1 and element EL2 may include metal oxide, metal halide (for example, metal fluoride, metal chloride, metal bromide, or metal iodide), metalloid halide (for example, metalloid fluoride, metalloid chloride, metalloid bromide, or metalloid iodide), metal telluride, or any combination thereof.

Examples of the metal oxide may include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), and rhenium oxide (for example, ReO₃, etc.).

Examples of the metal halide may include alkali metal halide, alkaline earth metal halide, transition metal halide, post-transition metal halide, and lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide may include titanium halide (for example, TiF₄, TiCl₄, TiBr₄, TiI₄, etc.), zirconium halide (for example, ZrF₄, ZrCl₄, ZrBr₄, ZrI₄, etc.), hafnium halide (for example, HfF₄, HfCl₄, HfBr₄, HfI₄, etc.), vanadium halide (for example, VF₃, VCl₃, VBr₃, VI₃, etc.), niobium halide (for example, NbF₃, NbCl₃, NbBr₃, NbI₃, etc.), tantalum halide (for example, TaF₃, TaCl₃, TaBr₃, TaI₃, etc.), chromium halide (for example, CrF₃, CrCl₃, CrBr₃, CrI₃, etc.), molybdenum halide (for example, MoF₃, MoCl₃, MoBr₃, MoI₃, etc.), tungsten halide (for example, WF₃, WCl₃, WBr₃, WI₃, etc.), manganese halide (for example, MnF₂, MnCl₂, MnBr₂, MnI₂, etc.), technetium halide (for example, TcF₂, TcCl₂, TcBr₂, TcI₂, etc.), rhenium halide (for example, ReF₂, ReCl₂, ReBr₂, ReI₂, etc.), iron halide (for example, FeF₂, FeCl₂, FeBr₂, FeI₂, etc.), ruthenium halide (for example, RuF₂, RuC₁₂, RuBr₂, RuI₂, etc.), osmium halide (for example, OsF₂, OsCl₂, OsBr₂, OsI₂, etc.), cobalt halide (for example, CoF₂, CoCl₂, CoBr₂, CoI₂, etc.), rhodium halide (for example, RhF₂, RhCl₂, RhBr₂, RhI₂, etc.), iridium halide (for example, IrF₂, IrCl₂, IrBr₂, IrI₂, etc.), nickel halide (for example, NiF₂, NiCl₂, NiBr₂, NiI₂, etc.), palladium halide (for example, PdF₂, PdCl₂, PdBr₂, PdI₂, etc.), platinum halide (for example, PtF₂, PtCl₂, PtBr₂, PtI₂, etc.), copper halide (for example, CuF, CuCl, CuBr, CuI, etc.), silver halide (for example, AgF, AgCl, AgBr, AgI, etc.), and gold halide (for example, AuF, AuCl, AuBr, AuI, etc.).

Examples of the post-transition metal halide may include zinc halide (for example, ZnF₂, ZnCl₂, ZnBr₂, ZnI₂, etc.), indium halide (for example, InI₃, etc.), and tin halide (for example, SnI₂, etc.).

Examples of the lanthanide metal halide may include YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, and SmI₃

Examples of the metalloid halide may include antimony halide (for example, SbCl₅, etc.).

Examples of the metal telluride may include alkali metal telluride (for example, Li₂Te, Na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), and lanthanide metal telluride (for example, LaTe, CeTe, PrTe, NdTe, PmTe, EuTe, GdTe, TbTe, DyTe, HoTe, ErTe, TmTe, YbTe, LuTe, etc.).

[Electron Transport Region]

Charge auxiliary layers between the activation layer 131 and the second electrode 150 may be referred to as an electron transport region.

The electron transport region may have: i) a single-layered structure consisting of a single layer consisting of a single material, ii) a single-layered structure consisting of a single layer consisting of different materials, or iii) a multi-layered structure including multiple layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, the constituting layers of each structure being sequentially stacked from an emission layer.

In an embodiment, the electron transport region (for example, the buffer layer, the hole-blocking layer, the electron control layer, or the electron transport layer in the electron transport region) may include a metal-free compound including at least one π electron-deficient nitrogen-containing C₁-C₆₀ cyclic group.

In an embodiment, the electron transport region may include a compound represented by Formula 601 below:

[Ar₆₀₁]ₓₑ₁₁-[(L₆₀₁)ₓₑ₁-R₆₀₁]ₓₑ₂₁ [Formula 601]

wherein, in Formula 601,

Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ are the same as described in connection with Qi,

xe21 may be 1, 2, 3, 4, or 5, and

at least one of Ar₆₀₁, L₆₀₁, and R₆₀₁ may be a π electron-deficient nitrogen-containing C₁-C₆₀ cyclic group that is unsubstituted or substituted with at least one R₁₀ₐ.

In an embodiment, in case that xe11 in Formula 601 is 2 or more, two or more of Ar₆₀₁(s) may be linked via a single bond.

In an embodiment, Ar₆₀₁ in Formula 601 may be a substituted or unsubstituted anthracene group.

In an embodiment, the electron transport region may include a compound represented by Formula 601-1:

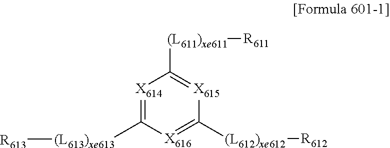

wherein, in Formula 601-1,

X₆₁₄ may be N or C(R₆₁₄), X₆₁₅ may be N or C(R₆₁₆), X₆₁₆ may be N or C(R₆₁₆), at least one of X₆₁₄ to X₆₁₆ may be N,

L₆₁₁ to L₆₁₃ may be respectively the same as those described in connection with L₆₀₁,

xe611 to xe613 may be respectively the same as those described in connection with xe1₇

R₆₁₁ to 8613 may be respectively the same as those described in connection with R₆₀₁, and

R₆₁₄ to 8616 may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq3, BAlq, TAZ, NTAZ, or any combination thereof:

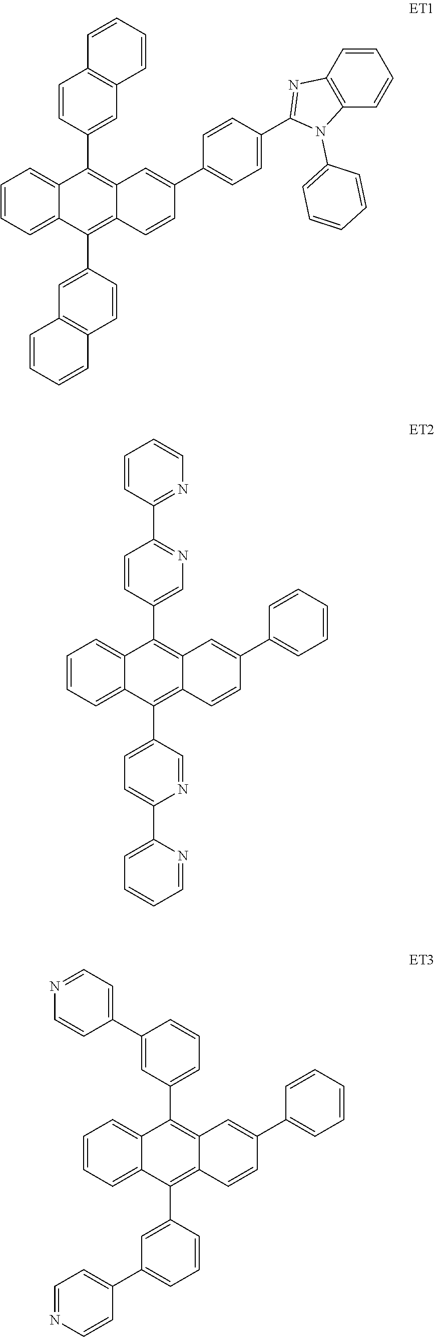 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

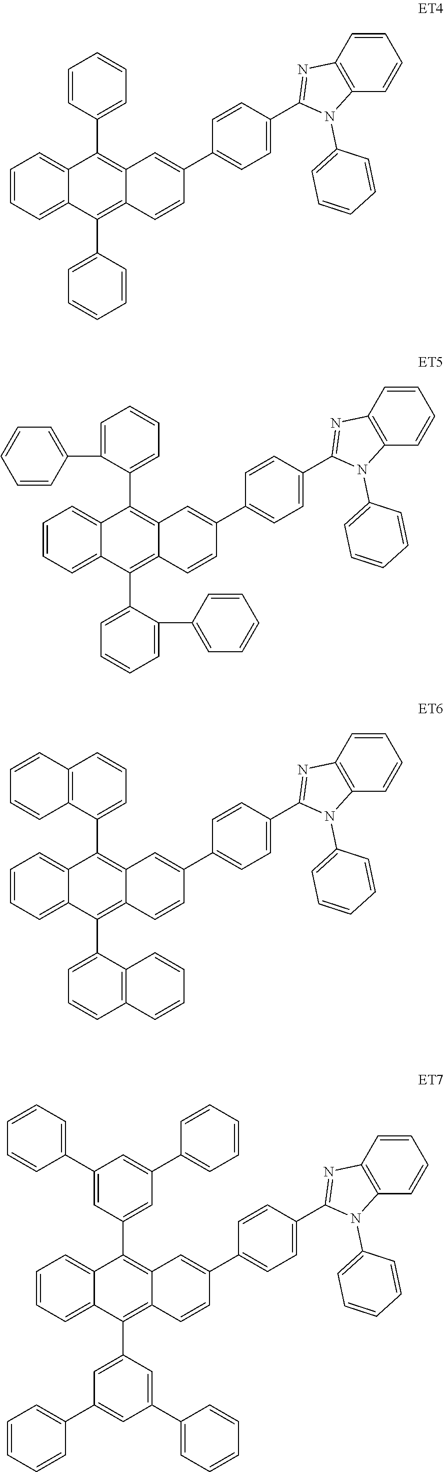 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

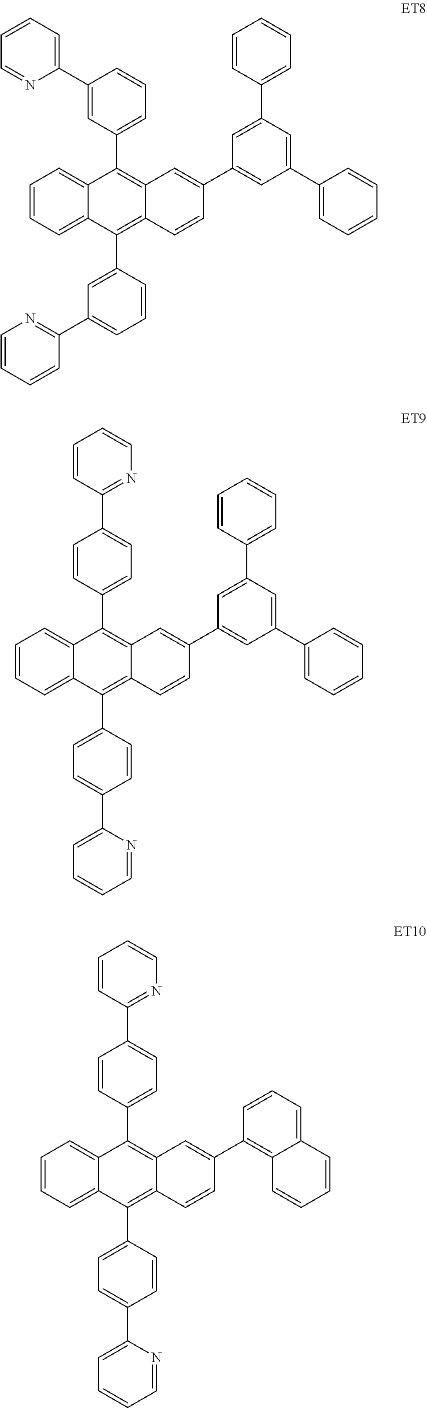 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

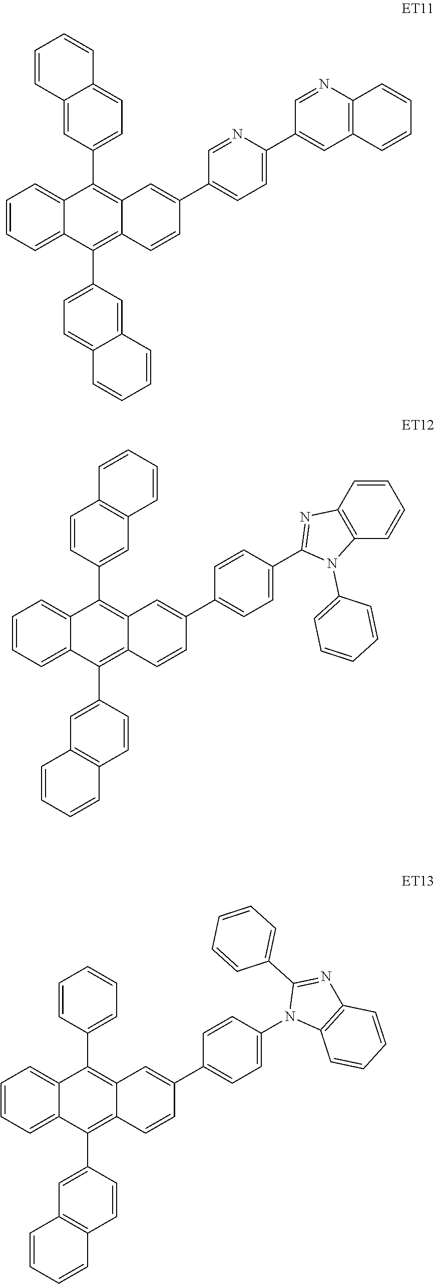 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

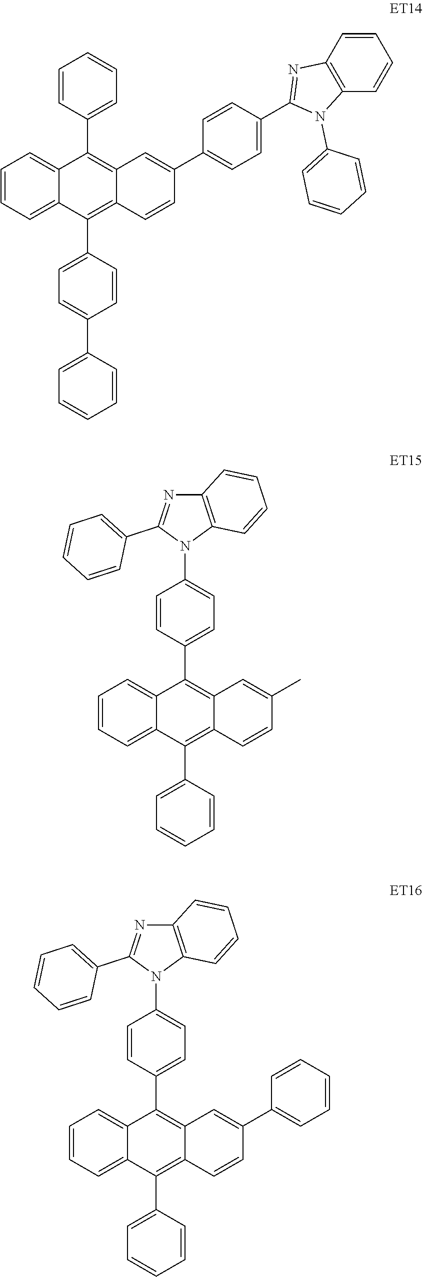 [SMILES: c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

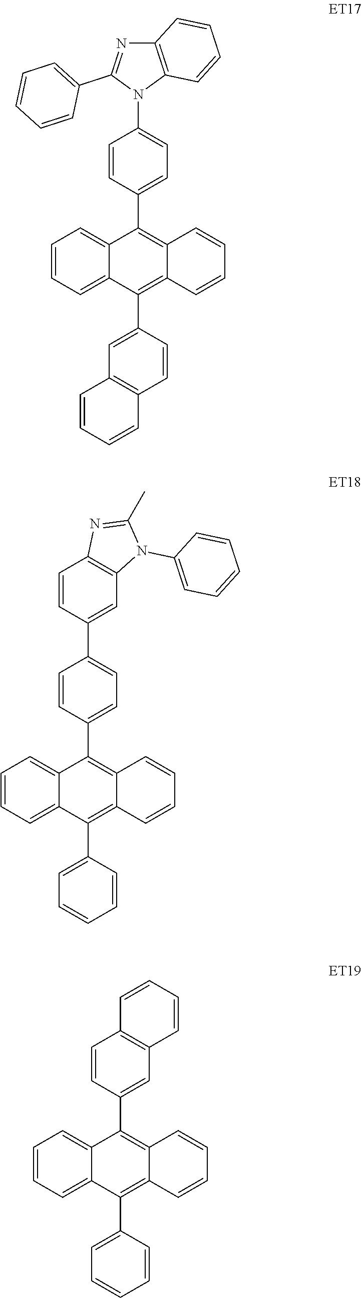

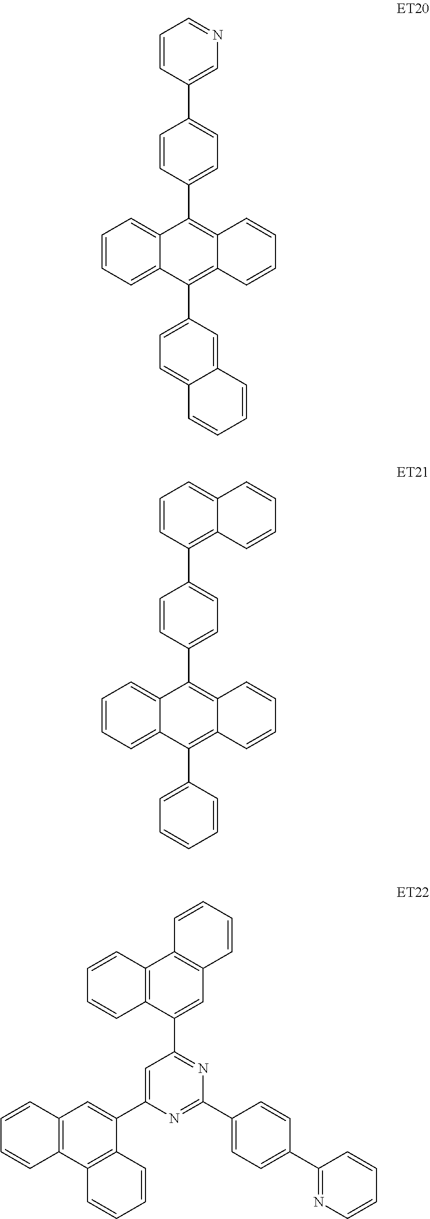

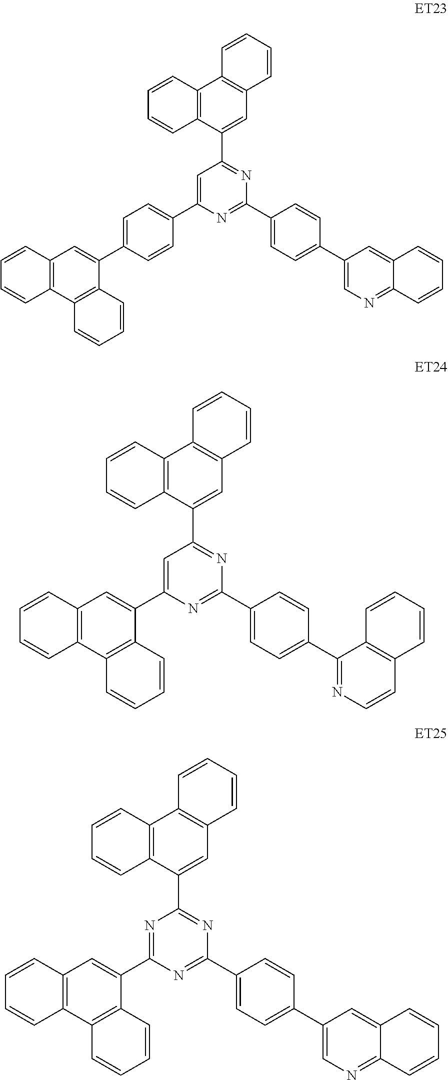 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

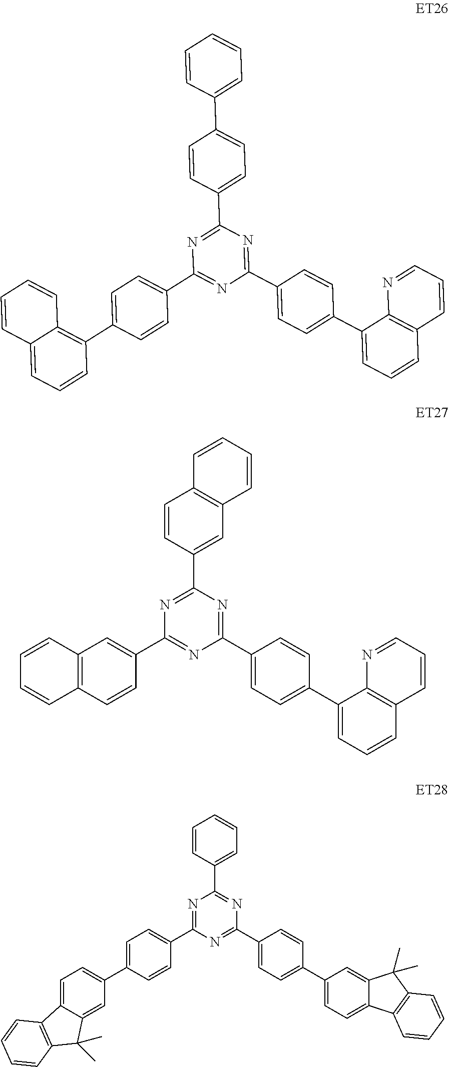 [SMILES: c1ccc(-c2ccc(-c3nc(-c4ccc(-c5cccc6ccccc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

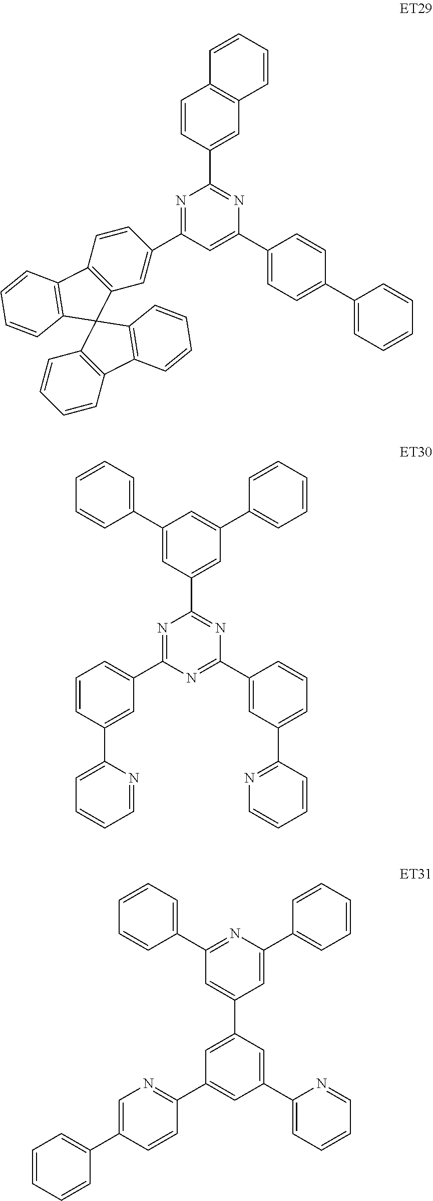 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

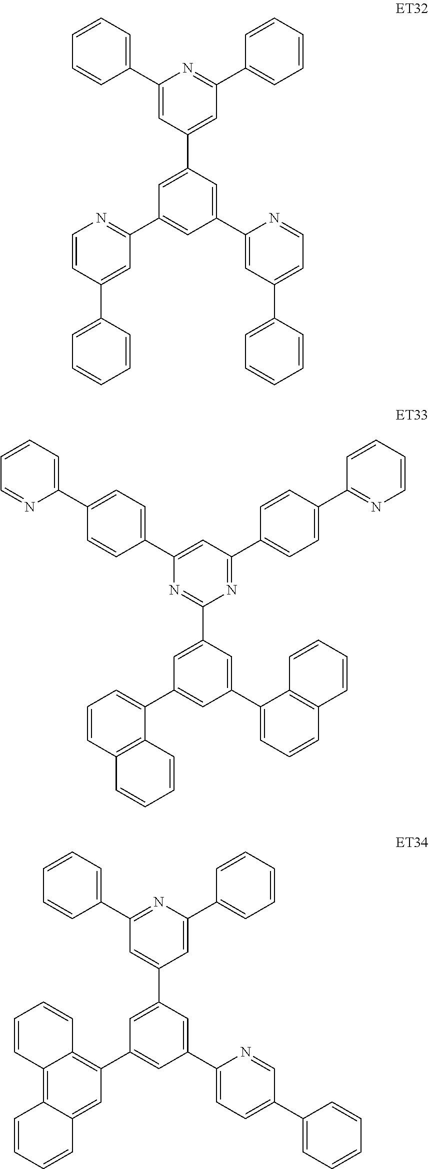 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

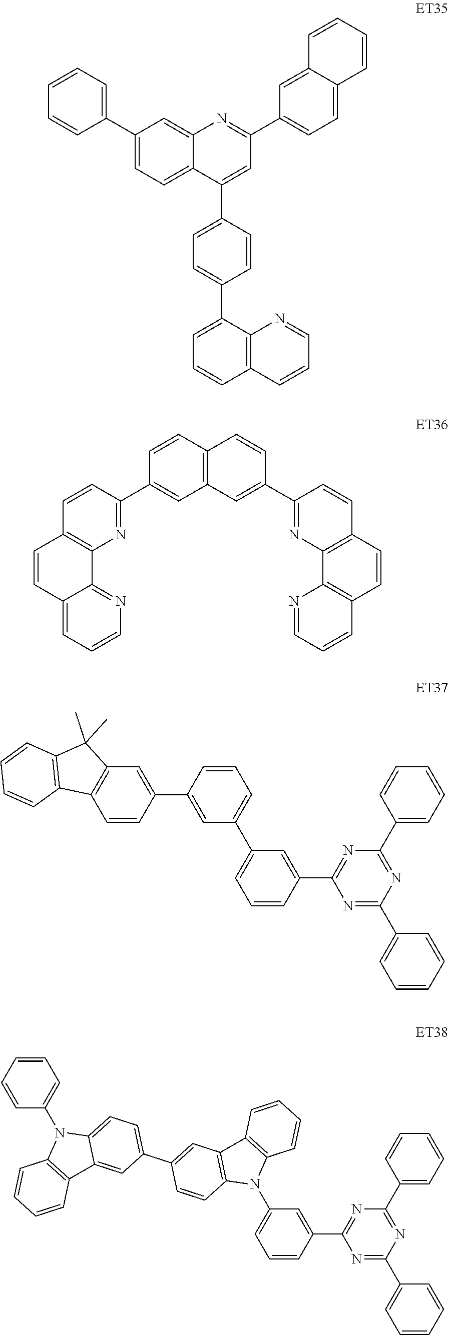 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

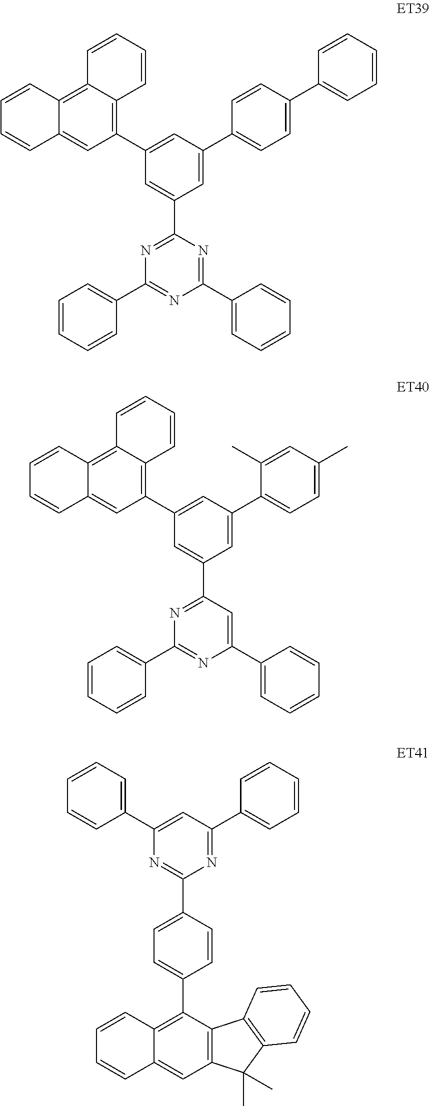 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

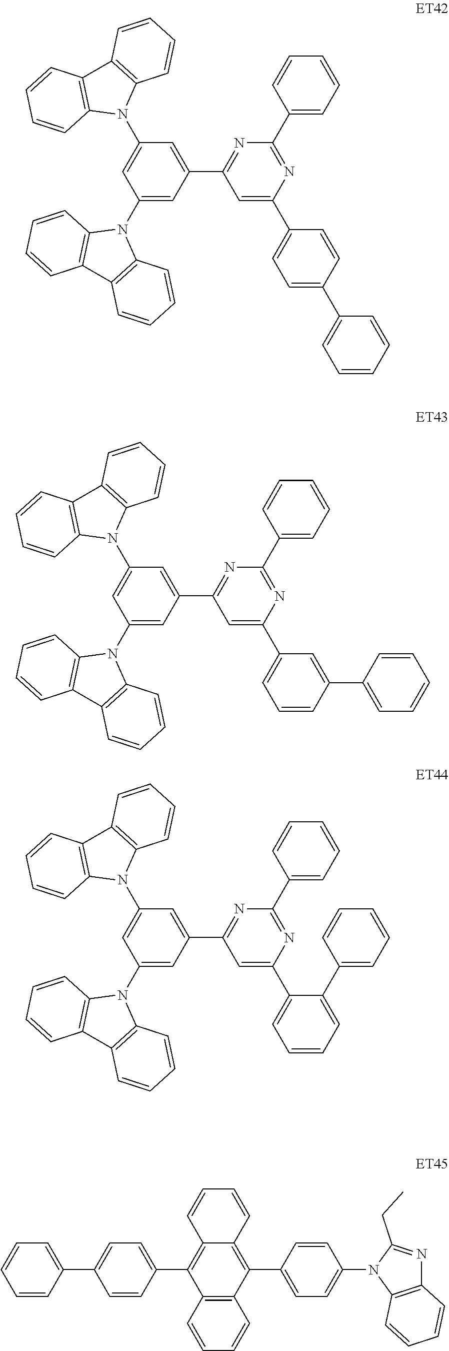

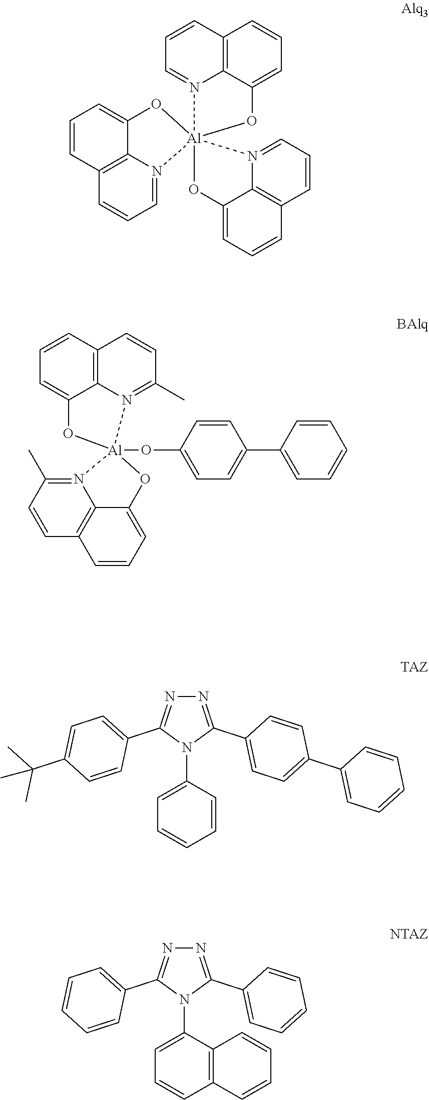

A thickness of the electron transport region may be from about 100 Å to about 5,000 Å, for example, about 160 Å to about 4,000 Å. In case that the electron transport region includes a buffer layer, a hole blocking layer, an electron control layer, an electron transport layer, or any combination thereof, the thickness of the buffer layer, the hole blocking layer, or the electron control layer may each independently be from about 20 Å to about 1000 Å, for example, about 30 Å to about 300 Å, and the thickness of the electron transport layer may be from about 100 Å to about 1,000 Å, for example, about 150 Å to about 500 Å. In case that the thickness of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

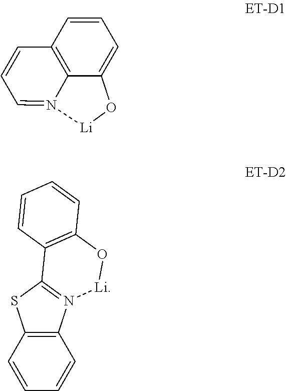

The electron transport region may include an electron injection layer that facilitates the injection of electrons from the second electrode 150. The electron injection layer may be in contact (e.g., directly contact) with the second electrode 150.

The electron injection layer may have: i) a single-layered structure consisting of a single layer consisting of a single material, ii) a single-layered structure consisting of a single layer consisting of different materials, or iii) a multi-layered structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or any combination thereof.

The alkali metal-containing compound may include alkali metal oxides, such as Li₂O, Cs₂O, or K₂O, alkali metal halides, such as LiF, NaF, CsF, KF, LiI, NaI, CsI, or KI, or any combination thereof. The alkaline earth metal-containing compound may include an alkaline earth metal compound, such as BaO, SrO, CaO, BaₓSr₁₋ₓO (x is a real number satisfying the condition of 0<x<1), BaₓCa₁₋ₓO (x is a real number satisfying the condition of 0<x<1), or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of ions of the alkali metal, the alkaline earth metal, and the rare earth metal and ii), a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may also include an organic material (for example, a compound represented by Formula 601).

In an embodiment, the electron injection layer may consist of i) an alkali metal-containing compound (for example, an alkali metal halide), ii) a) an alkali metal-containing compound (for example, an alkali metal halide); and b) an alkali metal, an alkaline earth metal, a rare earth metal, or any combination thereof. For example, the electron injection layer may be a KI:Yb co-deposited layer, a RbI:Yb co-deposited layer, a LiF:Yb co-deposited, or the like.

In case that the electron injection layer further includes an organic material, alkali metal, alkaline earth metal, rare earth metal, an alkali metal-containing compound, an alkaline earth metal-containing compound, a rare earth metal-containing compound, alkali metal complex, alkaline earth-metal complex, rare earth metal complex, or any combination thereof may be homogeneously or non-homogeneously dispersed in a matrix including the organic material.

A thickness of the electron injection layer may be in a range of about 1 Å to about 100 Å, and, for example, about 3 Å to about 90 Å. In case that the thickness of the electron injection layer is within the range described above, satisfactory electron injection characteristics may be obtained without a substantial increase in driving voltage.

[Second Electrode 150]

The second electrode 150 may be arranged on the activation layer 131 as described above. The second electrode 150 may be a cathode, which is an electron injection electrode, and as the material for the second electrode 150, a metal, an alloy, an electrically conductive compound, or any combination thereof, each having a low work function, may be used.

In an embodiment, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layered structure or a multi-layered structure including two or more layers.

[Capping Layer]

A first capping layer may be located outside of the first electrode 110, and/or a second capping layer may be located outside of the second electrode 150.

The first capping layer and/or the second capping layer may prevent penetration of impurities, such as water or oxygen, to the organic photodetectors 10 and 20 to thereby improve reliability of the organic photodetectors 10 and 20.

Each of the first capping layer and second capping layer may include a material having a refractive index of about 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may include carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may be optionally substituted with a substituent containing O, N, S, Se, Si, F, Cl, Br, I, or any combination thereof. In an embodiment, at least one of the first capping layer and the second capping layer may include an amine group-containing compound.

In an embodiment, at least one of the first capping layer and the second capping layer may include a compound represented by Formula 201, a compound represented by Formula 202, or any combination thereof.

In an embodiment, at least one of the first capping layer and the second capping layer may include one of Compounds HT28 to HT33, one of Compounds CP1 to CP6, β-NPB, or any combination thereof:

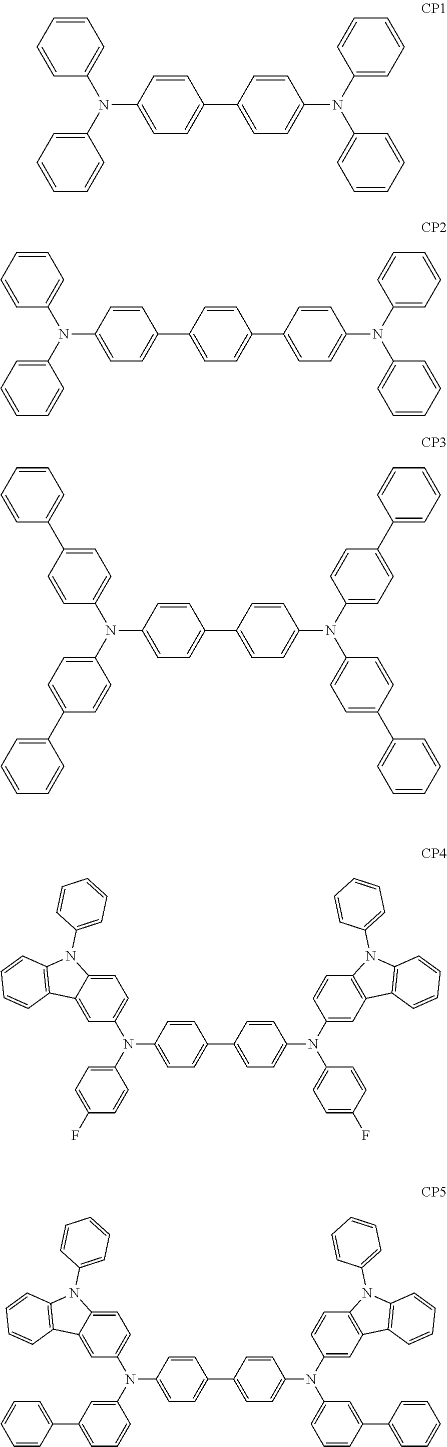 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

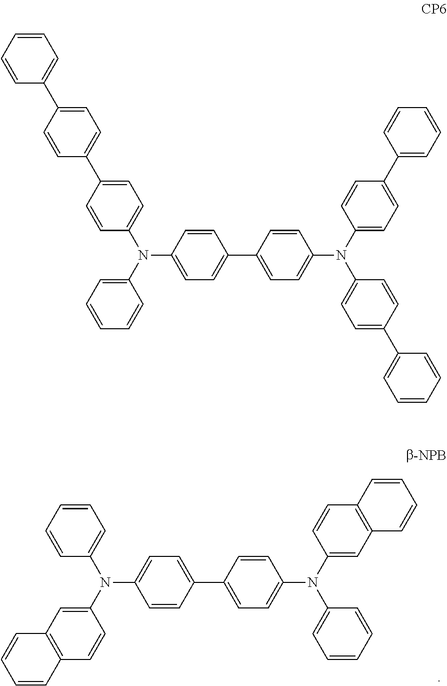 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

[Electronic Apparatus]

Provided is an electronic apparatus including the organic photodetector as described above. In an embodiment, the electronic apparatus may also include a light-emitting device.

Accordingly, the electronic apparatus may include: a substrate including a light detection region and an emission region;

an organic photodetector arranged on the light detection region; and

a light-emitting device arranged on the emission region,

wherein the organic photodetector may include a first pixel electrode, a counter electrode facing the first pixel electrode, and an auxiliary layer and an activation layer, which are sequentially arranged between the first pixel electrode and the counter electrode,

the light-emitting device may include a second pixel electrode, the counter electrode facing the second pixel electrode, and an emission layer arranged between the second pixel electrode and the counter electrode,

the first pixel electrode, the auxiliary layer, and the activation layer may be arranged in correspondence with the light detection region,

the second pixel electrode and the emission layer may be arranged in correspondence with the emission region, and

the light-emitting device may not include the auxiliary layer.

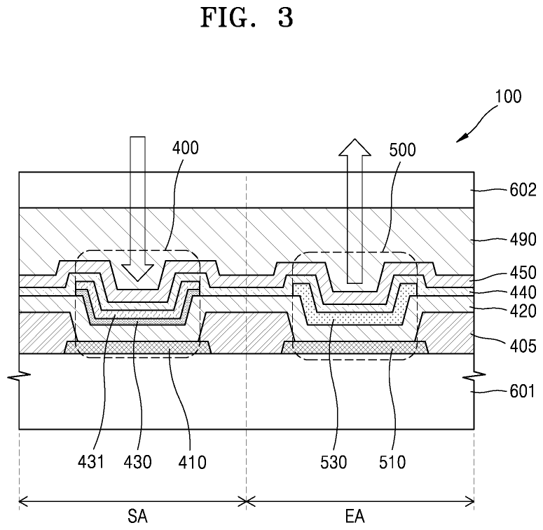

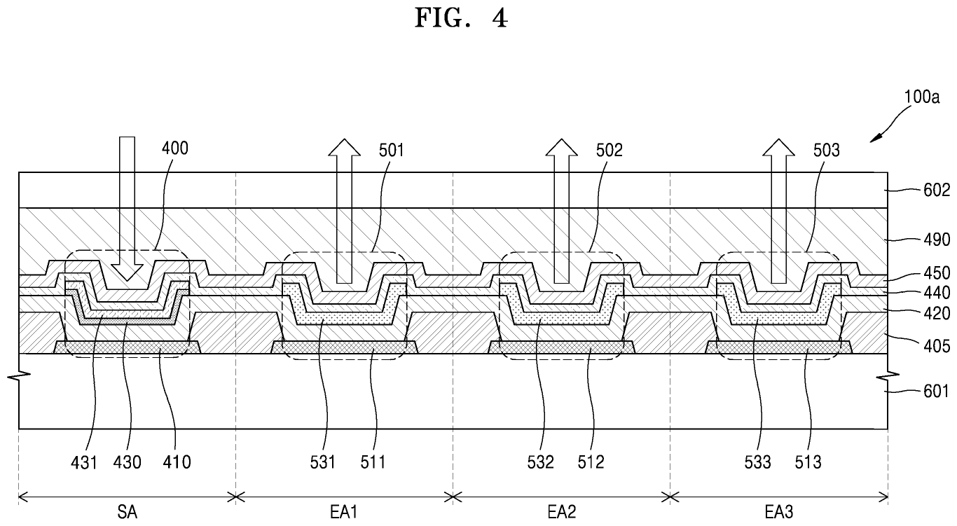

The electronic apparatus may be applied to various displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

[Description of FIGS. 3 and 4]

FIG. 3 is a schematic cross-sectional view of an electronic apparatus 100 according to an embodiment.

Referring to FIG. 3, the electronic apparatus 100 may include an organic photodetector 400 and a light-emitting device 500, which are arranged between a first substrate 601 and a second substrate 602.

The substrates 601 and 602 may each independently be a flexible substrate, a glass substrate, or a metal substrate. A buffer layer (not shown) and a thin-film transistor (not shown) may be arranged on the first substrate 601.

The buffer layer may prevent penetration of impurities through the first substrate 601 and may provide a flat surface on the first substrate 601. The thin-film transistor may be arranged on the buffer layer and may include an activation layer, a gate electrode, a source electrode, and a drain electrode.

Such a thin-film transistor may be electrically connected to the light-emitting device 500 to drive the light-emitting device 500. One of the source electrode and drain electrode may be electrically connected to a second pixel electrode 510 of the light-emitting device 500.

Another thin-film transistor may be electrically connected to the organic photodetector 400. One of the source electrode and drain electrode may be electrically connected to a first pixel electrode 410 of the organic photodetector 400.

The organic photodetector 400 may include the first pixel electrode 410, a first common layer 420, an auxiliary layer 430, an activation layer 431, a second common layer 440, and a counter electrode 450.

In embodiments, the first pixel electrode 410 may be an anode, and the counter electrode 450 may be a cathode. For example, by applying a reverse bias to a place between the first pixel electrode 410 and the counter electrode 450 to drive the organic photodetector 400, the electronic apparatus 100 may detect light incident on the organic photodetector 400, generate charges, and extract a current.

The light-emitting device 500 may include the second pixel electrode 510, the first common layer 420, an emission layer 530, the second common layer 440, and the counter electrode 450.

In embodiments, the second pixel electrode 510 may be an anode, and the counter electrode 450 may be a cathode. For example, in the light-emitting device 500, holes injected from the second pixel electrode 510 and the electrons injected from the counter electrode 450 may combine in the emission layer 530 to form excitons, and the excitons may transition from an excited state to a ground, thereby generating light.

Descriptions of the first pixel electrode 410 and the second pixel electrode 510 may each be understood by referring to the description of the first electrode 110 provided in the specification.

Pixel-defining films 405 may be formed on an edge of the first pixel electrode 410 and on an edge of the second pixel electrode 510. The pixel-defining film 405 may define a pixel region and may electrically insulate between the first pixel electrode 410 and the second pixel electrode 510. The pixel-defining film 405 may include, for example, one or more suitable organic insulating materials (e.g., a silicon-based material), inorganic insulating materials, or organic/inorganic composite insulating materials. The pixel-defining film 405 may be a transmissive film that may transmit visible light or a blocking film that may block visible light.

The first common layer 420 and the second common layer 440 may each be arranged throughout a light detection region SA and an emission region EA. The first common layer 420 may include, for example, a hole injection layer, a hole transport layer, an electron blocking layer, or any combination thereof, and the second common layer 440 may include, for example, a buffer layer, a hole blocking layer, an electron transport layer, an electron injection layer, or any combination thereof.

In an embodiment, at least one of each layer included in the first common layer 420 and each layer included in the second common layer 440 may be arranged to be corresponding to the light detection region SA and the emission region EA.

As such, in the electronic apparatus 100, by arranging a common layer over the organic photodetector 400 and the light-emitting device 500, a manufacturing process may be reduced, and a functional layer material used in the light-emitting device 500 may also be used in the organic photodetector 400. Thus, the organic photodetector 400 may be arranged in-pixel in the electronic apparatus 100.

The auxiliary layer 430 may be arranged to be corresponding to the light detection region SA on the first common layer 420. The activation layer 431 may be arranged to be corresponding to the light detection region SA on the auxiliary layer 430. The auxiliary layer 430 and the activation layer 431 may be understood by referring to the description of the activation layer provided in the specification.

The emission layer 530 may be arranged to be corresponding to the emission region EA on the first common layer 420. The emission layer 530 may be formed by using one or more light-emitting materials. For example, for the light-emitting material, an organic material, an inorganic material, or a quantum dot may be used. In an embodiment, the light-emitting device 500 may also include an electron blocking layer (not shown), between the second pixel electrode 510 and the emission layer 530, corresponding to the emission region EA.

The second common layer 440 and the counter electrode 450, each formed as a common layer throughout the light detection region SA and emission region EA, may be sequentially formed on the activation layer 431 and emission layer 530. The counter electrode 450 may be understood by referring to the description of the second electrode 150 provided in the specification.

A capping layer (not shown) may be arranged on the counter electrode 450. A material for forming the capping layer may include the organic material and/or the inorganic material described herein. The capping layer may serve to protect the organic photodetector 400 and the light-emitting device 500 and to assist effective light emission from the light-emitting device 500.

An encapsulation layer 490 may be on the capping layer or the counter electrode 450. The encapsulation layer 490 may be arranged on the organic photodetector 400 and the light-emitting device 500 to thereby protect the organic photodetector 400 and the light-emitting device 500 from water or oxygen. The encapsulation layer 490 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxy methylene, poly aryllate, hexamethyl disiloxane, an acrylic resin (e.g., polymethyl methacrylate, polyacrylic acid, and the like), an epoxy resin (e.g., aliphatic glycidyl ether (AGE) and the like), or any combination thereof; or a combination of the inorganic film and the organic film.

The electronic apparatus 100 may be, for example, a display apparatus. As the electronic apparatus 100 includes the organic photodetector 400 and the light-emitting device 500, the electronic apparatus 100 may be a display apparatus having a light detection function.

In FIG. 3, the electronic apparatus 100 is illustrated as including one light-emitting device 500, however, as shown in FIG. 4, an electronic apparatus 100a according to an embodiment may include the organic photodetector 400, a first light-emitting device 501, a second light-emitting device 502, and a third light-emitting device 503.

Components illustrated in FIG. 3 may be understood by referring to the descriptions of the components described in the electronic apparatus 100.

The first light-emitting device 501 may include a second pixel electrode 511, the first common layer 420, a first emission layer 531, the second common layer 440, and a counter electrode 450.

The second light-emitting device 502 may include a third pixel electrode 512, the first common layer 420, a second emission layer 532, the second common layer 440, and the counter electrode 450.

The third light-emitting device 503 may include a fourth pixel electrode 513, the first common layer 420, a third emission layer 533, the second common layer 440, and the counter electrode 450.

The second pixel electrode 511, the third pixel electrode 512, and the fourth pixel electrode 513 may respectively be arranged to correspond to a first emission region EA1, a second emission region EA2, and a third emission region EA3. The second pixel electrode 511, the third pixel electrode 512, and the fourth pixel electrode 513 may each be understood by referring to the description of the first electrode 110.

The first emission layer 531 may be arranged to correspond to the first emission region EA1 and emit first color light, the second emission layer 532 may be arranged to correspond to the second emission region EA2 and emit second color light, and the third emission layer 533 may be arranged to correspond to the third emission region EA3 and emit third color light.

A maximum emission wavelength of the first color light, a maximum emission wavelength of the second color light, and a maximum emission wavelength of the third color light may be identical to or different from each other. In an embodiment, a maximum emission wavelength of the first color light and a maximum emission wavelength of the second color light may each be longer than a maximum emission wavelength of the third color light.

In some embodiments, the first color light may be red light, the second color light may be green light, and the third color light may be blue light, but embodiments are not limited thereto. Thus, the electronic apparatus 100a may be capable of full color emission. In case that a mixed light of the first color light, the second color light, and the third color light is white light, the first color light, the second color light, and the third color light may not be limited to the red light, green light, and blue light.

The first emission layer 531, the second emission layer 532, and the third emission layer 533 may each be formed by using one or more suitable light-emitting materials. For example, as the light-emitting material, an organic material, an inorganic material, or a quantum dot may be used.

The organic photodetector 400, the first light-emitting device 501, the second light-emitting device 502, and the third light-emitting device 503 may each be a sub-pixel, each forming a pixel. In an embodiment, one pixel may include at least one organic photodetector 400.

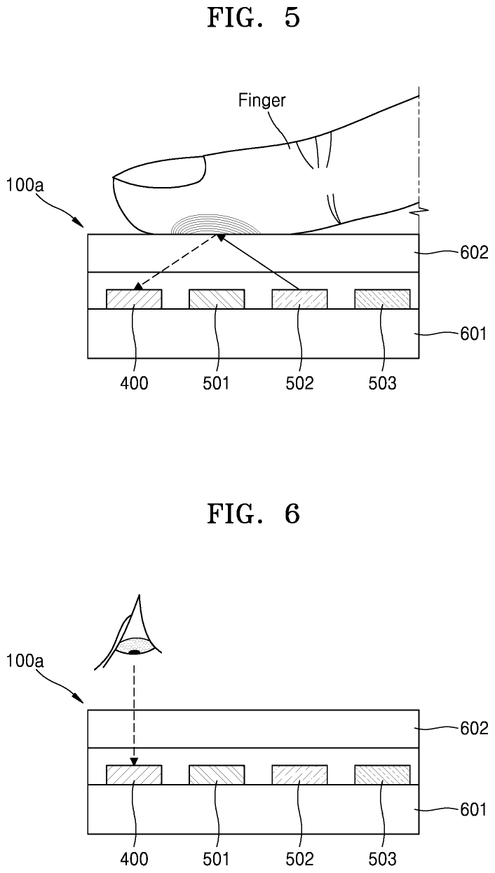

The electronic apparatus 100a may be a display apparatus. As the electronic apparatus 100a may include the organic photodetector 400, the first light-emitting device 501, the second light-emitting device 502, and the third light-emitting device 503, the electronic apparatus 100a may be a full-color display apparatus having a light detection function.

[Descriptions of FIGS. 5 and 6]

In the electronic apparatus 100a shown in FIG. 5, the organic photodetector 400 and the light-emitting devices 501, 502, and 503 may be arranged between the first substrate 601 and the second substrate 602.

In an embodiment, red light, green light, and blue light may respectively be emitted from the light-emitting device 501, the light-emitting device 502, and the light-emitting device 503.

The electronic apparatus 100a according to an embodiment may be capable of detecting an object in contact with the electronic apparatus 100a, e.g., a fingerprint of a finger of a user. For example, as shown in FIG. 5, at least some light emitted from the light-emitting device 502 and reflected by a fingerprint of a finger may be re-incident on the organic photodetector 400, and thus, the organic photodetector 400 may detect the reflected light. A ridge in a fingerprint pattern of a finger may adhere to the second substrate 602, and thus, the organic photodetector 400 may selectively obtain the fingerprint pattern of a finger, e.g., image information of the ridge. Although FIG. 5 shows an embodiment in which information of an object in contact with the electronic apparatus 100a is obtained by using light emitted from the light-emitting device 502, light emitted from the light-emitting device 501 and/or light emitted from the light-emitting device 503 may also be used in the same manner as obtaining information by using emitted light.

As shown in FIG. 6, the electronic apparatus 100a according to an embodiment may detect an object that is not in contact with the electronic apparatus 100a.

[Manufacture Method]

The layers constituting the hole transport region, the active layer, and the layers constituting the electron transport region may be formed in a specific region by using one or more suitable methods such as vacuum deposition, spin coating, casting, Langmuir-Blodgett (LB) deposition, ink-jet printing, laser printing, and laser-induced thermal imaging.

In case that layers constituting the hole transport region, an active layer, and layers constituting the electron transport region are each independently formed by vacuum-deposition, the vacuum-deposition may be performed at a deposition temperature in a range of about 100° C. to about 500° C., at a vacuum degree in a range of about 10⁻⁸ torr to about 10⁻³ torr, and at a deposition rate in a range of about 0.01 Angstroms per second (A/sec) to about 100 Å/sec, depending on the material to be included in each layer and the structure of each layer to be formed.

### Definition of Terms

The term “C₃-C₆₀ carbocyclic group” as used herein may refer to a cyclic group consisting of carbon only as a ring-forming atom and having three to sixty carbon atoms, and the term “C₁-C₆₀ heterocyclic group” as used herein may refer to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In an embodiment, the C₁-C₆₀ heterocyclic group may have 3 to 61 ring-forming atoms.

The “cyclic group” as used herein may include the C₃-C₆₀ carbocyclic group and the C₁-C₆₀ heterocyclic group.

The term “π electron-rich C₃-C₆₀ cyclic group” as used herein may refer to a cyclic group that has three to sixty carbon atoms and does not include *—N=*′ as a ring-forming moiety, and the term “π electron-deficient nitrogen-containing C₁-C₆₀ cyclic group” as used herein may refer to a heterocyclic group that has one to sixty carbon atoms and includes *—N=*′ as a ring-forming moiety.

In an embodiment,

the C₃-C₆₀ carbocyclic group may be i) group T1 or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) group T2, ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the π electron-rich C₃-C₆₀ cyclic group may be i) group T1, ii) a condensed cyclic group in which two or more groups T1 are condensed with each other, iii) group T3, iv) a condensed cyclic group in which two or more groups T3 are condensed with each other, or v) a condensed cyclic group in which at least one group T3 and at least one group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

the π electron-deficient nitrogen-containing C₁-C₆₀ cyclic group may be i) group T4, ii) a condensed cyclic group in which two or more group T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

group T3 may be a furan group, a thiophene group, a 1H-pyrrole group, a silole group, or a borole group, and

group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may refer to a group condensed to any cyclic group or a polyvalent group (for example, a divalent group, a trivalent group, a tetravalent group, etc.), depending on the structure of a formula in connection with which the terms are used. In an embodiment, “a benzene group” may be a benzo group, a phenyl group, a phenylene group, or the like, which may be understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the monovalent C₁-Coo heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₁₀ alkylene group” as used herein may refer to a divalent group having the same structure as the C₁-C₁₀ alkyl group.

The term “C₂-C₆₀ alkenyl group” as used herein may refer to a monovalent hydrocarbon group having at least one carbon-carbon double bond in the middle or at the terminus of the C₂-C₆₀ alkyl group, and examples thereof may include an ethenyl group, a propenyl group, and a butenyl group. The term “C₂-C₆₀ alkenylene group” as used herein may refer to a divalent group having the same structure as the C₂-C₆₀ alkenyl group.

The term “C₂-C₆₀ alkynyl group” as used herein may refer to a monovalent hydrocarbon group having at least one carbon-carbon triple bond in the middle or at the terminus of the C₂-C₆₀ alkyl group, and examples thereof may include an ethynyl group and a propynyl group. The term “C₂-C₆₀ alkynylene group” as used herein may refer to a divalent group having the same structure as the C₂-C₆₀ alkynyl group.

The term “C₁-C₆₀ alkoxy group” as used herein may refer to a monovalent group represented by —OA₁₀₁ (wherein A₁₀₁ is the C₁-C₆₀ alkyl group), and examples thereof may include a methoxy group, an ethoxy group, and an isopropyloxy group.

The term “C₃-C₁₀ cycloalkyl group” as used herein may refer to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein may refer to a divalent group having the same structure as the C₃-C₁₀ cycloalkyl group.

The term “C₁-C₁₀ heterocycloalkyl group” as used herein may refer to a monovalent cyclic group that further includes, in addition to a carbon atom, at least one heteroatom as a ring-forming atom and has 1 to 10 carbon atoms, and examples thereof may include a 1,2,3,4-oxatriazolidinyl group, a tetrahydrofuranyl group, and a tetrahydrothiophenyl group. The term “C₁-C₁₀ heterocycloalkylene group” as used herein may refer to a divalent group having the same structure as the C₁-C₁₀ heterocycloalkyl group.

The term “C₃-C₁₀ cycloalkenyl group” used herein may refer to a monovalent cyclic group that has three to ten carbon atoms and at least one carbon-carbon double bond in the ring thereof and no aromaticity, and examples thereof may include a cyclopentenyl group, a cyclohexenyl group, and a cycloheptenyl group. The term “C₃-C₁₀ cycloalkenylene group” as used herein may refer to a divalent group having the same structure as the C₃-C₁₀ cycloalkenyl group.

The term “C₁-C₁₀ heterocycloalkenyl group” as used herein may refer to a monovalent cyclic group that has, in addition to a carbon atom, at least one heteroatom as a ring-forming atom, 1 to 10 carbon atoms, and at least one carbon-carbon double bond in the cyclic structure thereof. Examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein may refer to a divalent group having the same structure as the C₁-C₁₀ heterocycloalkenyl group.

The term “C₆-C₆₀ aryl group” as used herein may refer to a monovalent group having a carbocyclic aromatic system having six to sixty carbon atoms, and the term “C₆-C₆₀ arylene group” as used herein may refer to a divalent group having a carbocyclic aromatic system having six to sixty carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. In case that the C₆-C₆₀ aryl group and the C₆-C₆₀ arylene group each include two or more rings, the rings may be condensed with each other.

The term “C₁-C₆₀ heteroaryl group” as used herein may refer to a monovalent group having a heterocyclic aromatic system that has, in addition to a carbon atom, at least one heteroatom as a ring-forming atom, and 1 to 60 carbon atoms. The term “C₁-C₆₀ heteroarylene group” as used herein may refer to a divalent group having a heterocyclic aromatic system that has, in addition to a carbon atom, at least one heteroatom as a ring-forming atom, and 1 to 60 carbon atoms. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. In case that the C₁-C₆₀ heteroaryl group and the C₁-C₆₀ heteroarylene group each include two or more rings, the rings may be condensed with each other.

The term “monovalent non-aromatic condensed polycyclic group” as used herein may refer to a monovalent group having two or more rings condensed to each other, only carbon atoms (for example, having 8 to 60 carbon atoms) as ring-forming atoms, and non-aromaticity in its molecular structure in case that considered as a whole. Examples of the monovalent non-aromatic condensed polycyclic group may include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein may refer to a divalent group having the same structure as a monovalent non-aromatic condensed polycyclic group.

The term “monovalent non-aromatic condensed heteropolycyclic group” as used herein may refer to a monovalent group having two or more rings condensed to each other, at least one heteroatom other than carbon atoms (for example, having 1 to 60 carbon atoms), as a ring-forming atom, and non-aromaticity in its molecular structure in case that considered as a whole. Examples of the monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein may refer to a divalent group having the same structure as a monovalent non-aromatic condensed heteropolycyclic group.

The term “C₆-C₆₀ aryloxy group” as used herein may indicate —OA₁₀₂ (wherein A₁₀₂ is the C₆-C₆₀ aryl group), and the term “C₆-C₆₀ arylthio group” as used herein may indicate —SA₁₀₃ (wherein A₁₀₃ is the C₆-C₆₀ aryl group).

The term “C₇-C₆₀ aryl alkyl group” used herein may refer to -A₁₀₄A₁₀₅ (where A₁₀₄ may be a C₁-C₅₄ alkylene group, and A₁₀₅ may be a C₆-C₅₉ aryl group), and the term “C₂-C₆₀ heteroaryl alkyl group” used herein may refer to -A₁₀₆A₁₀₇ (where A₁₀₆ may be a C₁-C₅₉ alkylene group, and A₁₀₇ may be a C₁-C₅₉ heteroaryl group).

R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(C₂₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a alkoxy group; a C₃-C₆₀ carbocyclic group or a C₁-C₆₀ heterocyclic group, each unsubstituted or substituted with deuterium, —F, a cyano group, a C₁-C₆₀ alkyl group, a alkoxy group, a phenyl group, a biphenyl group, or any combination thereof; a C₇-C₆₀ aryl alkyl group; or a C₂-C₆₀ heteroaryl alkyl group.

The term “hetero atom” as used herein may refer to any atom other than a carbon atom. Examples of the heteroatom may include O, S, N, P, Si, B, Ge, Se, or any combination thereof.

The term “the third-row transition metal” used herein may include hafnium (Hf), tantalum (Ta), tungsten (W), rhenium (Re), osmium (Os), iridium (Ir), platinum (Pt), gold (Au), and the like.

“Ph” as used herein may refer to a phenyl group, “Me” as used herein may refer to a methyl group, “Et” as used herein may refer to an ethyl group, “tert-Bu” or “But” as used herein may refer to a tert-butyl group, and “OMe” as used herein may refer to a methoxy group.

The term “biphenyl group” as used herein may refer to “a phenyl group substituted with a phenyl group.” In other words, the “biphenyl group” may be a substituted phenyl group having a C₆-C₆₀ aryl group as a substituent.

The term “terphenyl group” as used herein may refer to “a phenyl group substituted with a biphenyl group”. The “terphenyl group” may be a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

### EXAMPLES

### Evaluation Example 1: Measurement of Refractive Index

With respect to Compounds 1 to 4 and A to G, a refractive index at a wavelength of 460 nm was measured by using Ellipsometer (K-MAC, Korea), and is shown in Table 1 below.

TABLE 1

| Compound | Refractive index (@ 460 nm) |
|---|---|
| 1 | 2.26 |
| 2 | 2.33 |
| 3 | 2.42 |
| 4 | 2.35 |
| A | 1.95 |
| B | 2.07 |
| C | 1.88 |
| D | 2.01 |
| E | 2.07 |
| F | 1.92 |
| G | 2.04 |

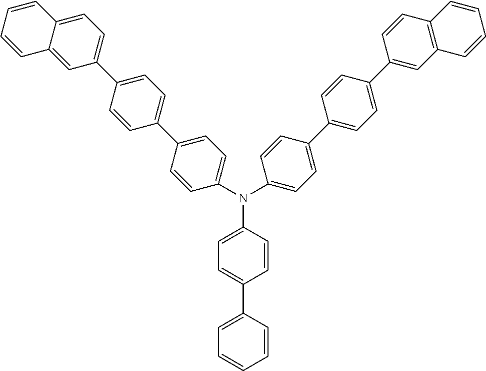 [SMILES: c1ccc(-c2ccc(N(c3ccc(-c4ccc(-c5ccc6ccccc6c5)cc4)cc3)c3ccc(-c4ccc(-c5ccc6ccccc6c5)cc4)cc3)cc2)cc1]

1 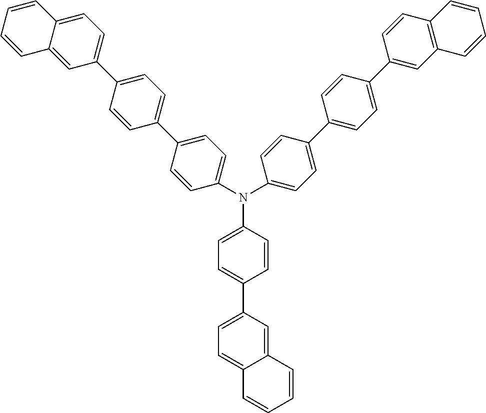 [SMILES: c1ccc2cc(-c3ccc(-c4ccc(N(c5ccc(-c6ccc(-c7ccc8ccccc8c7)cc6)cc5)c5ccc(-c6ccc7ccccc7c6)cc5)cc4)cc3)ccc2c1]
2 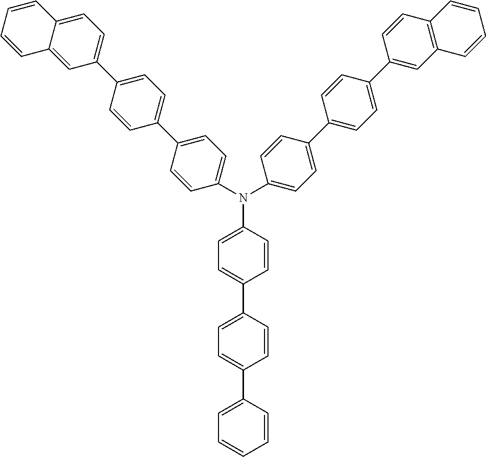 [SMILES: c1ccc(-c2ccc(-c3ccc(N(c4ccc(-c5ccc(-c6ccc7ccccc7c6)cc5)cc4)c4ccc(-c5ccc(-c6ccc7ccccc7c6)cc5)cc4)cc3)cc2)cc1]
3 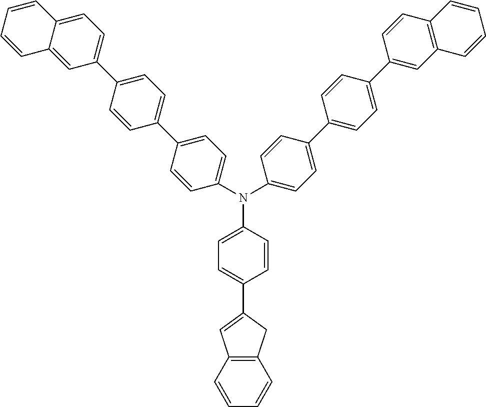 [SMILES: C1=C(c2ccc(N(c3ccc(-c4ccc(-c5ccc6ccccc6c5)cc4)cc3)c3ccc(-c4ccc(-c5ccc6ccccc6c5)cc4)cc3)cc2)Cc2ccccc21]
4 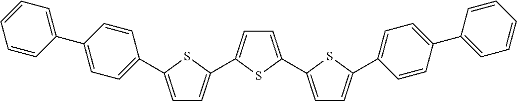 [SMILES: c1ccc(-c2ccc(-c3ccc(-c4ccc(-c5ccc(-c6ccc(-c7ccccc7)cc6)s5)s4)s3)cc2)cc1]
A 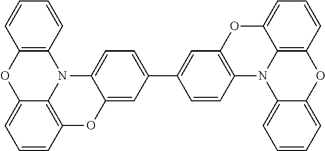 [SMILES: c1ccc2c(c1)Oc1cccc3c1N2c1ccc(-c2ccc4c(c2)Oc2cccc5c2N4c2ccccc2O5)cc1O3]
B 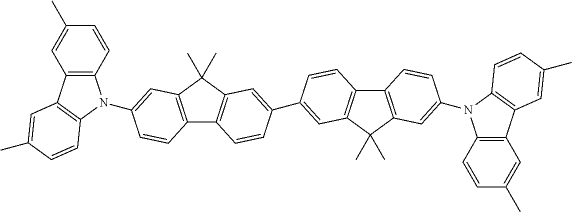
C 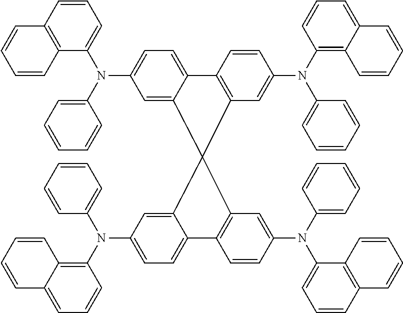 [SMILES: c1ccc(N(c2ccc3c(c2)C2(c4cc(N(c5ccccc5)c5cccc6ccccc56)ccc4-3)c3cc(N(c4ccccc4)c4cccc5ccccc45)ccc3-c3ccc(N(c4ccccc4)c4cccc5ccccc45)cc32)c2cccc3ccccc23)cc1]
D 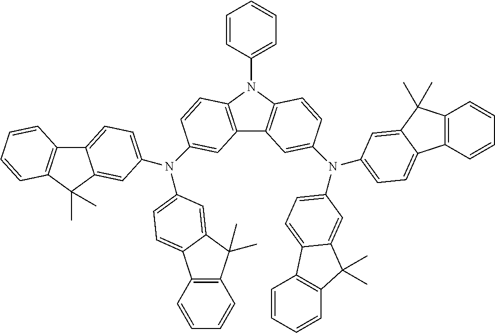 [SMILES: CC1(C)c2ccccc2-c2ccc(N(c3ccc4c(c3)C(C)(C)c3ccccc3-4)c3ccc4c(c3)c3cc(N(c5ccc6c(c5)C(C)(C)c5ccccc5-6)c5ccc6c(c5)C(C)(C)c5ccccc5-6)ccc3n4-c3ccccc3)cc21]
E 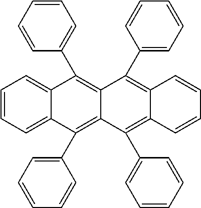 [SMILES: c1ccc(-c2c3ccccc3c(-c3ccccc3)c3c(-c4ccccc4)c4ccccc4c(-c4ccccc4)c23)cc1]
F 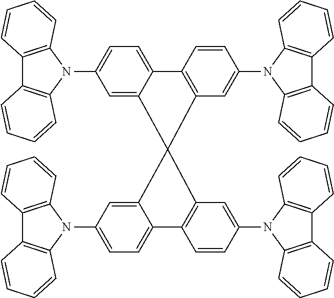 [SMILES: c1ccc2c(c1)c1ccccc1n2-c1ccc2c(c1)C1(c3cc(-n4c5ccccc5c5ccccc54)ccc3-2)c2cc(-n3c4ccccc4c4ccccc43)ccc2-c2ccc(-n3c4ccccc4c4ccccc43)cc21]
G

From Table 1, it was confirmed that a refractive index at a wavelength of 460 nm of each of Compounds 1 to 4 was 2.2 or more, whereas a refractive index of each of Compounds A to D was less than 2.2.

### Example 1

An ITO glass substrate was cut to a size of about 50 mm×50 mm×0.5 mm, sonicated in isopropyl alcohol and pure water for 10 minutes in each solvent, and cleaned by irradiation of ultraviolet rays and exposure of ozone thereto for 10 minutes to use the glass substrate as an anode. The glass substrate was mounted to a vacuum-deposition apparatus. HAT-CN was vacuum-deposited on the anode to form a hole injection layer having a thickness of about 100 Å, and HT3 was vacuum-deposited on the hole injection layer to form a hole transport layer having a thickness of about 1250 Å.

Compound 1 was vacuum-deposited on the hole transport layer to form an auxiliary layer having a thickness of about 50 Å.

SubPC having a thickness of about 200 Å and C₆₀ fullerene having a thickness of about 250 Å were sequentially deposited on the auxiliary layer to form an activation layer.

Subsequently, BAlq was vacuum-deposited thereon to form a hole blocking layer having a thickness of about 50 Å, and ET1 was vacuum-deposited on the hole blocking layer to form an electron transport layer having a thickness of about 300 Å.

Liq having a thickness of about 10 Å and MgAg having a thickness of about 100 Å were deposited sequentially on the electron transport layer to form a cathode, thereby manufacturing an organic photodetector.

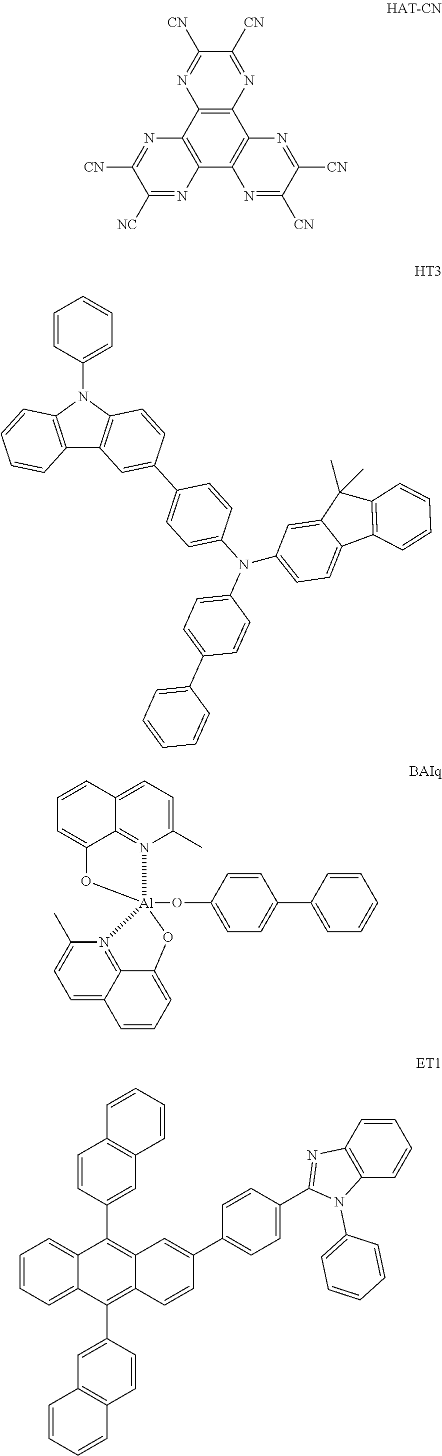

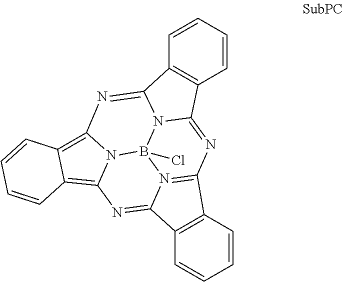

### Examples 2 to 4 and Comparative Examples 1 to 5

Organic photodetectors were manufactured in the same manner as in Example 1, except that, in forming the auxiliary layer, compounds shown in Table 2 below were used instead of Compound 1.

### Evaluation Example 2: Measurement of Organic Photodetector Characteristics

With respect to the organic photodetectors manufactured in Examples 1 to 4 and Comparative Examples 1 to 5, by using an EQE measurement system (K3100, McScience, Korea), current values were measured by using a current meter (Keithley, Tektronix, U.S.A.) in case that light is incident (530 nm) on an organic photodetector, and the current values were calculated and represented as EQE values. In order to measure a dark current density at a reverse bias of −3 V, by using an electro-optical characteristic evaluation facility (K3100, McScience, Korea), a voltage was applied to the anode, the current was measured (Keithley, Tektronix, U.S.A.), and results thereof are shown in Table 2.

TABLE 2

| | | EQE (%) | Dark current density |
|---|---|---|---|
| Example | Compound | @530 nm | (mA/cm²) |
| Example 1 | 1 | 25% | 3.28 × 10⁻⁶ mA/cm² |
| Example 2 | 2 | 38% | 2.69 × 10⁻⁶ mA/cm² |
| Example 3 | 3 | 43% | 4.14 × 10⁻⁶ mA/cm² |
| Example 4 | 4 | 29% | 1.87 × 10⁻⁶ mA/cm² |
| Comparative | A | 17% | 2.16 × 10⁻⁶ mA/cm² |
| Example 1 | | | |
| Comparative | B | 18% | 2.75 × 10⁻⁶ mA/cm² |
| Example 2 | | | |
| Comparative | C | 20% | 4.22 × 10⁻⁶ mA/cm² |
| Example 3 | | | |
| Comparative | D | 14% | 3.48 × 10⁻⁶ mA/cm² |
| Example 4 | | | |
| Comparative | G | 11% | 3.31 × 10⁻⁶ mA/cm² |
| Example 5 | | | |

From Table 2, it was confirmed that as compared with that of the organic photodetectors of Comparative Examples 1 to 5, the organic photodetectors of Examples 1 to 4 exhibited a dark current density of 5×10⁻⁶ mA/cm² or less and had improved EQEs, and thus, had excellent light detection efficiencies.

While the disclosure has been described with reference to example embodiments illustrated in the drawings, these embodiments are provided herein for illustrative purpose only, and one of ordinary skill in the art may understand that the embodiments include various modifications and equivalent embodiments thereof. Accordingly, the true scope of the disclosure should be determined by the technical idea of the appended claims.

The organic photodetector according to an embodiment has improved EQE and has excellent light detection performance, and thus, may be used to manufacture high-quality electronic apparatuses.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. An organic photodetector comprising:
a first electrode;
a second electrode facing the first electrode;
an activation layer arranged between the first electrode and the second electrode; and
an auxiliary layer arranged between the first electrode and the activation layer, wherein
the auxiliary layer comprises a compound having a refractive index of about 2.2 or more.

2. The organic photodetector of claim 1, wherein
the activation layer comprises:
a p-type semiconductor layer; and
an n-type semiconductor layer,
the p-type semiconductor layer comprises a p-type semiconductor,
the n-type semiconductor layer comprises a n-type semiconductor, and
the p-type semiconductor layer and the n-type semiconductor layer form a PN junction.

3. The organic photodetector of claim 1, wherein
the activation layer comprises a p-type semiconductor and an n-type semiconductor, and
the activation layer is a mixed layer in which the p-type semiconductor and the n-type semiconductor are mixed.

4. The organic photodetector of claim 2, wherein the p-type semiconductor comprises boron subphthalocyanine chloride (SubPc), copper(II) phthalocyanine (CuPc), tetraphenyldibenzoperiflanthene (DBP), or a combination thereof.

5. The organic photodetector of claim 2, wherein the n-type semiconductor comprises C60 fullerene, C70 fullerene, or a combination thereof.

6. The organic photodetector of claim 1, wherein a thickness of the activation layer is in a range of about 20 nm and about 100 nm.

7. The organic photodetector of claim 1, wherein the activation layer directly contacts the auxiliary layer.

8. The organic photodetector of claim 1, wherein a thickness of the auxiliary layer is in a range of about 1 nm and about 20 nm.

9. The organic photodetector of claim 1, wherein the compound includes an organic material.

10. The organic photodetector of claim 1, wherein the compound includes an amine group-containing compound.

11. The organic photodetector of claim 1, wherein the refractive index is in a range of about 2.2 and about 3.0.

12. The organic photodetector of claim 1, further comprising:
a hole transport region between the first electrode and the auxiliary layer; and
an electron transport region between the activation layer and the second electrode, wherein
the hole transport region comprises a hole injection layer, a hole transport layer, an electron blocking layer, or a combination thereof, and
the electron transport region comprises a buffer layer, a hole blocking layer, an electron transport layer, an electron injection layer, or a combination thereof.

13. The organic photodetector of claim 12, wherein the hole transport region comprises the hole transport layer.

14. The organic photodetector of claim 13, wherein a thickness of the hole transport layer is in a range of about 80 nm and about 150 nm.

15. The organic photodetector of claim 13, wherein the hole transport layer directly contacts the auxiliary layer.

16. The organic photodetector of claim 13, wherein each of the activation layer and the hole transport layer directly contacts the auxiliary layer.

17. An electronic apparatus comprising the organic photodetector of claim 1.

18. The electronic apparatus of claim 17, further comprising a light-emitting device.

19. An electronic apparatus comprising:
a substrate comprising a light detection region and an emission region;
an organic photodetector arranged on the light detection region; and
a light-emitting device arranged on the emission region, wherein
the organic photodetector comprises:
a first pixel electrode;
a counter electrode facing the first pixel electrode; and
a first common layer, an auxiliary layer, an activation layer, and a second common layer, which are sequentially arranged between the first pixel electrode and the counter electrode,
the light-emitting device comprises:
a second pixel electrode;
the counter electrode, facing the second pixel electrode; and
the first common layer, an emission layer, and the second common layer, which are sequentially arranged between the second pixel electrode and the counter electrode,
the first pixel electrode, the auxiliary layer, and the activation layer are arranged in correspondence with the light detection region,
the second pixel electrode and the emission layer are arranged in correspondence with the emission region, and
the first common layer, the second common layer, and the counter electrode are arranged throughout the light detection region and the emission region.

20. The electronic apparatus of claim 19, wherein the first common layer comprises a hole transport layer.
